(19) United States
(12) Patent Application Publication
(10) Pub. No.: US 2025/0294991 A1
(43) Pub. Date: Sep. 18, 2025

(54) DISPLAY PANEL AND DISPLAY DEVICE

(71) Applicant: Wuhan Tianma Microelectronics Co., Ltd., Wuhan (CN)

(72) Inventors: Qin Yue, Wuhan (CN); Yangzhao Ma, Wuhan (CN); Wei Huang, Wuhan (CN); Enxia Wang, Wuhan (CN); Shengxiong Chen, Wuhan (CN); Ming Tang, Wuhan (CN); You Gao, Wuhan (CN); Gaojun Huang, Wuhan (CN); Zhongjie Zhang, Wuhan (CN)

(73) Assignee: Wuhan Tianma Microelectronics Co., Ltd., Wuhan (CN)

(21) Appl. No.: 19/003,227

(22) Filed: Dec. 27, 2024

(30) Foreign Application Priority Data
Dec. 29, 2023 (CN) 202311872813.5

(51) Int. Cl. H10K 59/35; H10K 59/121; H10K 59/122

(52) U.S. Cl. CPC H10K 59/353; H10K 59/121; H10K 59/122

(57) ABSTRACT

A display panel includes a plurality of first sub-pixels, a plurality of second sub-pixels, and a plurality of third sub-pixels. Multiple first sub-pixels and multiple second sub-pixels constitute a first virtual quadrangle. The center of a first sub-pixel is located at a first vertex of the first virtual quadrangle. The center of a second sub-pixel is located at a second vertex of the first virtual quadrangle. A third sub-pixel is located inside the first virtual quadrangle. Multiple third sub-pixels constitute a second virtual quadrangle. Centers of the multiple third sub-pixels are each located at a vertex of the second virtual quadrangle. A first sub-pixel or a second sub-pixel is located inside the second virtual quadrangle. A first sub-pixel or a second sub-pixel includes a main portion and a protrusion portion. The protrusion portion is located on one side of the main portion in a first direction.

### CROSS-REFERENCE TO RELATED APPLICATION

This application claims priority to Chinese Patent Application No. 202311872813.5, filed on Dec. 29, 2023, the disclosure of which is incorporated herein by reference in its entirety.

### TECHNICAL FIELD

Embodiments of the present application relate to the field of display technology and, in particular, to a display panel and a display device.

### BACKGROUND

Organic light-emitting diodes (OLEDs) have the characteristics of self-luminescence, low power consumption, high brightness, and fast response, thereby attracting wide attention. Organic self-luminous display technology has become the research focus in the display field in the related art. To achieve the full-color display of an OLED display panel, multiple sub-pixels with different light-emitting colors, such as a red sub-pixel R, a green sub-pixel G, and a blue sub-pixel B, are disposed in the display panel. The arrangement of the pixels in the display panel directly affects the organic light-emitting display performance. How to arrange sub-pixels in the display panel to make the display effect of the display panel better has become the research focus of related technicians.

### SUMMARY

Embodiments of the present application provide a display panel and a display device to improve the display effect of the display panel.

In a first aspect, embodiments of the present application provide a display panel.

The display panel includes a plurality of first sub-pixels, a plurality of second sub-pixels, and a plurality of third sub-pixels.

Multiple first sub-pixels among the plurality of first sub-pixels and multiple second sub-pixels among the plurality of second sub-pixels constitute a first virtual quadrangle. A center of one of the multiple first sub-pixels is located at a first vertex of the first virtual quadrangle. A center of one of the multiple second sub-pixels is located at a second vertex of the first virtual quadrangle. The first vertex and the second vertex alternate and are spaced apart. One third sub-pixel among the plurality of third sub-pixels is located inside the first virtual quadrangle.

Multiple third sub-pixels among the plurality of third sub-pixels constitute a second virtual quadrangle. Centers of the multiple third sub-pixels are each located at a vertex of the second virtual quadrangle. One of the plurality of first sub-pixels or one of the plurality of second sub-pixels is located inside the second virtual quadrangle.

A first sub-pixel among the plurality of first sub-pixels or a second sub-pixel among the plurality of second sub-pixels includes a main portion and a protrusion portion, and the protrusion portion is located on one side of the main portion in a first direction.

A length of the protrusion portion is X1 in the first direction, and a length of the main portion and a length of the protrusion portion are each X2 in a second direction, where 0<X1<X2/2, and the second direction intersects the first direction.

In a second aspect, embodiments of the present application further provide a display device including the display panel provided in the first aspect.

### BRIEF DESCRIPTION OF DRAWINGS

FIG. 1 is a structural diagram of a pixel arrangement structure in the related art.

FIG. 2 is a first structural diagram of a display panel according to an embodiment of the present application.

FIG. 3 is a first structural diagram of a sub-pixel including a protrusion portion according to an embodiment of the present application.

FIG. 4 is a first structural diagram of a first sub-pixel and a second sub-pixel according to an embodiment of the present application.

FIG. 5 is a second structural diagram of a sub-pixel including a protrusion portion according to an embodiment of the present application.

FIG. 6 is a third structural diagram of a sub-pixel including a protrusion portion according to an embodiment of the present application.

FIG. 7 is a fourth structural diagram of a sub-pixel including a protrusion portion according to an embodiment of the present application.

FIG. 8 is a fifth structural diagram of a sub-pixel including a protrusion portion according to an embodiment of the present application.

FIG. 9 is a sixth structural diagram of a sub-pixel including a protrusion portion according to an embodiment of the present application.

FIG. 10 is a second structural diagram of a display panel according to an embodiment of the present application.

FIG. 11 is a diagram illustrating a relative positional relationship between a sub-pixel including a protrusion portion and a touch grid line according to an embodiment of the present application.

FIG. 12 is a seventh structural diagram of a sub-pixel including a protrusion portion according to an embodiment of the present application.

FIG. 13 is a third structural diagram of a display panel according to an embodiment of the present application.

FIG. 14 is a structural diagram of a repetition unit according to an embodiment of the present application.

FIG. 15 is a first structural diagram of a first virtual quadrangle according to an embodiment of the present application.

FIG. 16 is a fourth structural diagram of a display panel according to an embodiment of the present application.

FIG. 17 is a first structural diagram of a first sub-pixel group according to an embodiment of the present application.

FIG. 18 is a fifth structural diagram of a display panel according to an embodiment of the present application.

FIG. 19 is a second structural diagram of a first sub-pixel group according to an embodiment of the present application.

FIG. 20 is a sixth structural diagram of a display panel according to an embodiment of the present application.

FIG. 21 is a structural diagram of a second sub-pixel group according to an embodiment of the present application.

FIG. 22 is a seventh structural diagram of a display panel according to an embodiment of the present application.

FIG. 23 is a first structural diagram of a third sub-pixel group according to an embodiment of the present application.

FIG. 24 is an eighth structural diagram of a display panel according to an embodiment of the present application.

FIG. 25 is a second structural diagram of a third sub-pixel group according to an embodiment of the present application.

FIG. 26 is a ninth structural diagram of a display panel according to an embodiment of the present application.

FIG. 27 is a structural diagram of a fourth sub-pixel group according to an embodiment of the present application.

FIG. 28 is a second structural diagram of a first sub-pixel and a second sub-pixel according to an embodiment of the present application.

FIG. 29 is a third structural diagram of a first sub-pixel and a second sub-pixel according to an embodiment of the present application.

FIG. 30 is a fourth structural diagram of a first sub-pixel and a second sub-pixel according to an embodiment of the present application.

FIG. 31 is a structural diagram of a first sub-pixel and a third sub-pixel according to an embodiment of the present application.

FIG. 32 is a structural diagram of a first sub-pixel according to an embodiment of the present application.

FIG. 33 is a tenth structural diagram of a display panel according to an embodiment of the present application.

FIG. 34 is an eleventh structural diagram of a display panel according to an embodiment of the present application.

FIG. 35 is a twelfth structural diagram of a display panel according to an embodiment of the present application.

FIG. 36 is a thirteenth structural diagram of a display panel according to an embodiment of the present application.

FIG. 37 is a first sectional view of the display panel shown in FIG. 2 taken along section line A-A′.

FIG. 38 is a first diagram illustrating the arrangement manner of anode structures, pixel openings, and a light emission layer according to an embodiment of the present application.

FIG. 39 is a second diagram illustrating the arrangement manner of anode structures, pixel openings, and a light emission layer according to an embodiment of the present application.

FIG. 40 is a third diagram illustrating the arrangement manner of anode structures, pixel openings, and a light emission layer according to an embodiment of the present application.

FIG. 41 is a fourth diagram illustrating the arrangement manner of anode structures, pixel openings, and a light emission layer according to an embodiment of the present application.

FIG. 42 is a second sectional view of the display panel shown in FIG. 2 taken along section line A-A′.

FIG. 43 is a fourteenth structural diagram of a display panel according to an embodiment of the present application.

FIG. 44 is a fifteenth structural diagram of a display panel according to an embodiment of the present application.

FIG. 45 is a structural diagram of a display device according to an embodiment of the present application.

### DETAILED DESCRIPTION

To make the objects, technical solutions, and advantages of the present application clearer, the technical solutions of the present application will be completely described below through embodiments and in conjunction with drawings in embodiments of the present application. Apparently, the embodiments described below are part, not all, of the embodiments of the present application. It is apparent for those skilled in the art that various modifications and variations may be made in the present application without departing from the spirit or scope of the present application. Accordingly, the present application is intended to cover modifications and variations of the present application that fall within the scope of the appended claims (the claimed technical solutions) and their equivalents.

The term “first”, “second” and the like in embodiments of the present disclosure are used to distinguish different components but not used to describe any order, quantity or significance. Similarly, the term “one”, “a”, “the” or the like does not mean a quantitative limit, but indicates the existence of at least one. The term “including”, “containing” or the like means that the elements or objects in front of the term cover elements or objects and their equivalents listed in the back of the term, but does not exclude other elements or objects. The term “connect”, “connected to” or the like are not limited to physical or mechanical connections, but may include electrical connections, whether it is direct or indirect. “On”, “below”, “left”, “right” and the like are merely utilized to indicate the relative positional relationship, and when the absolute position of the described object is changed, the relative positional relationship may also change accordingly. Additionally, descriptions including being identical and equal referred to in embodiments of the present disclosure do not mean that two objects are totally equal in size and totally identical in shape but mean that the two objects are allowed to be approximately identical and equal within a certain error range.

It is to be noted that embodiments of the present application, if not in collision, may be combined with one another.

The pixel arrangement manners of the OLED display panels in the related art include “RGBG” arrangement, “delta” arrangement, and “diamond” arrangement. Through “RGBG” arrangement, text is fuzzy, strokes are relatively thick, and picture display is relatively fuzzy. Through “delta” arrangement, displayed text fonts have relatively apparent jaggedness. Through “diamond” arrangement, the displayed text is clear, strokes are relatively thin, and jaggedness is relatively slight. However, there are still some technical problems in “diamond” arrangement that need to be solved.

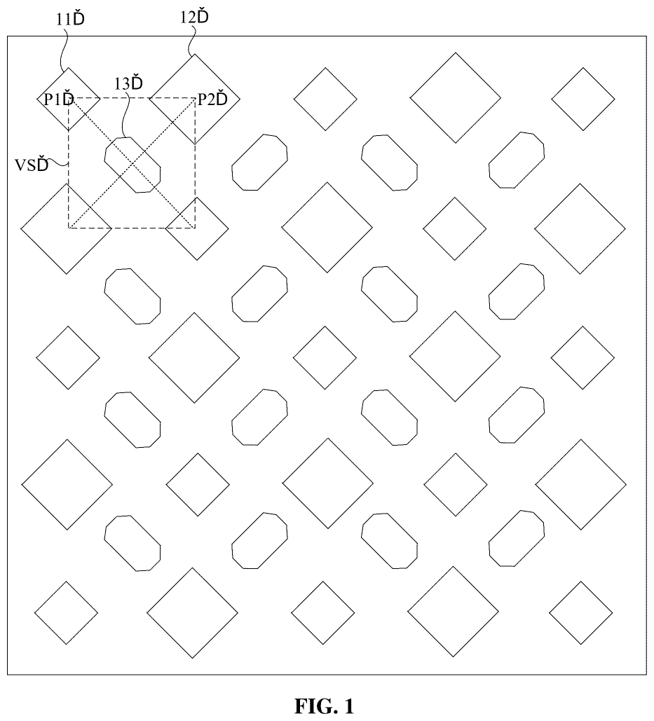

Exemplarily, FIG. 1 is a structural diagram of a display panel in the related art. As shown in FIG. 1, the display panel in the related art includes first sub-pixels 11′, second sub-pixels 12′, and third sub-pixels 13′. The shape of a first sub-pixel 11′ includes a rectangle. The shape of a second sub-pixel 12′ includes a rectangle. The shape of the third sub-pixel 13′ includes a polygon, such as a quadrangle, a hexagon or an octagon. In the related art, a third sub-pixel 13 ‘has a center coincident with the center of a virtual block VS’. A first sub-pixel 11′ is spaced from the third sub-pixel 13′ and has a center at a first vertex P1′ of the virtual block VS′. A second sub-pixel 12′ is spaced from the first sub-pixel 11′ and the third sub-pixel 13′ and has a center at a second vertex P2′ of the virtual block VS′. The second vertex P2′ is adjacent to the first vertex P1′. Those skilled in the art customarily refer to the preceding arrangement between sub-pixels as “diamond” pixel arrangement.

With the improvement of the display resolution of the display panel, the distance between different sub-pixels in the preceding pixel arrangement manner becomes increasingly small, thereby causing a leakage current in the display process of different sub-pixels. That is, a display current in a certain sub-pixel may flow to an adjacent sub-pixel, causing the crosstalk between different sub-pixels and the undesired light emission of sub-pixels and affecting the display effect of the display panel.

Regarding the preceding technical problem, embodiments of the present application provide a display panel. The display panel includes a plurality of first sub-pixels, a plurality of second sub-pixels, and a plurality of third sub-pixels. Multiple first sub-pixels and multiple second sub-pixels constitute a first virtual quadrangle. The center of a first sub-pixel is located at a first vertex of the first virtual quadrangle. The center of a second sub-pixel is located at a second vertex of the first virtual quadrangle.

The first vertex and the second vertex alternate and are spaced apart. A third sub-pixel is located inside the first virtual quadrangle. Multiple third sub-pixels constitute a second virtual quadrangle. Centers of the multiple third sub-pixels are each located at a vertex of the second virtual quadrangle. A first sub-pixel or a second sub-pixel is located inside the second virtual quadrangle. A first sub-pixel or a second sub-pixel includes a main portion and a protrusion portion. The protrusion portion is located on one side of the main portion in a first direction. The length of the protrusion portion is X1 in the first direction. The length of the main portion and the length of the protrusion portion are each X2 in a second direction. 0<X1<X2/2. The second direction intersects the first direction. By using the preceding technical solutions, the first sub-pixel or the second sub-pixel includes the main portion and the protrusion portion that are disposed in the first direction. The length of the protrusion portion is X1 in the first direction. The length of the main portion and the length of the protrusion portion are each X2 in the second direction. 0<X1<X2/2.

Through the preceding technical solutions, the adjustment of the shape of the first sub-pixel or the shape of the second sub-pixel can increase the distance between the first sub-pixel and the second sub-pixel, guarantee that the sub-pixel including the protrusion portion has a relatively large opening area, reduce a display leakage current between the first sub-pixel and the second sub-pixel, guarantee the opening area and aperture ratio of a sub-pixel, alleviate the crosstalk between different sub-pixels and the undesired light emission of sub-pixels, and improve the display effect of the display panel.

The above is the core idea of the present application. Technical solutions in embodiments of the present application will be described clearly and completely in conjunction with the drawings in embodiments of the present application.

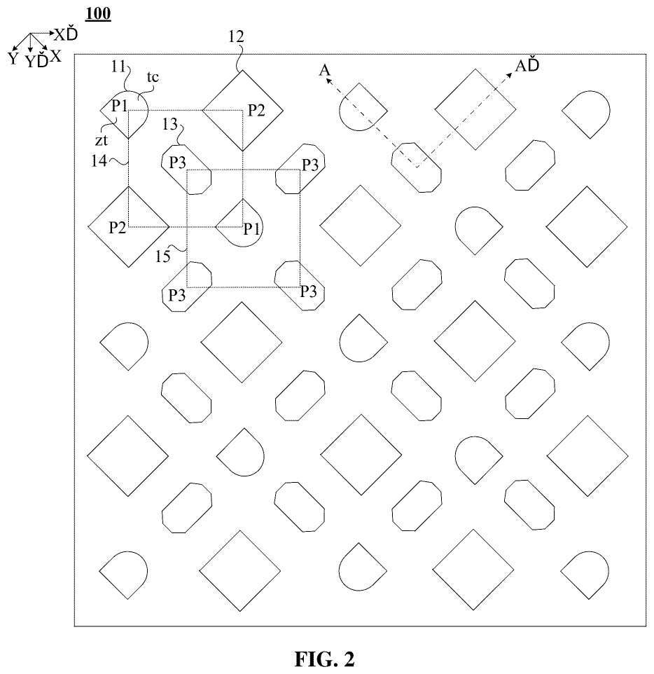

FIG. 2 is a first structural diagram of a display panel according to an embodiment of the present application. As shown in FIG. 2, the display panel 100 provided in the embodiment of the present application includes a plurality of first sub-pixels 11, a plurality of second sub-pixels 12, and a plurality of third sub-pixels 13. Multiple first sub-pixels 11 and multiple second sub-pixels 12 constitute a first virtual quadrangle 14.

The center of a first sub-pixel 11 is located at a first vertex P1 of the first virtual quadrangle 14. The center of a second sub-pixel 12 is located at a second vertex P2 of the first virtual quadrangle 14. The first vertex P1 and the second vertex P2 alternate and are spaced apart. A third sub-pixel 13 is located inside the first virtual quadrangle 14. Multiple third sub-pixels 13 constitute a second virtual quadrangle 15. Centers of the multiple third sub-pixels 13 are each located at a vertex of the second virtual quadrangle 15. A first sub-pixel 11 or a second sub-pixel 12 is located inside the second virtual quadrangle 15. A first sub-pixel 11 or a second sub-pixel 12 includes a main portion zt and a protrusion portion tc. The protrusion portion the is located on one side of the main portion zt in a first direction (a Y direction as shown in FIG. 3). The length of the protrusion portion the is X1 in the first direction. The length of the main portion zt and the length of the protrusion portion tc are each X2 in a second direction (an X direction as shown in FIG. 3). 0<X1<X2/2. The second direction intersects the first direction.

As shown in FIG. 2, the display panel 100 provided in embodiments of the present application includes a display region. A plurality of sub-pixels are disposed in the display region. A sub-pixel in embodiments of the present disclosure may be understood as a light-emitting element. A first sub-pixel 11, a second sub-pixel 12, and a third sub-pixel 13 may represent sub-pixels of three different colors. In embodiments of the present application, by way of example, a first sub-pixel 11 is a red sub-pixel, a second sub-pixel 12 is a blue sub-pixel, and a third sub-pixel 13 is a green sub-pixel. However, the arrangement in which a first sub-pixel 11 is a red sub-pixel, a second sub-pixel 12 is a blue sub-pixel, and a third sub-pixel 13 is a green sub-pixel does not limit the protection scope of embodiments of the present application.

On this basis, pixel arrangement is performed for the plurality of first sub-pixels 11 and the plurality of second sub-pixels 12. Two first sub-pixels 11 and two second sub-pixels 12 constitute one first virtual quadrangle 14. The center of a first sub-pixel 11 is located at a first vertex P1 of the first virtual quadrangle 14. The center of a second sub-pixel 12 is located at a second vertex P2 of the first virtual quadrangle 14. The first vertex P1 and the second vertex P2 alternate and are spaced apart. That is, the two first sub-pixels 11 and the two second sub-pixels 12 are arranged in a 2*2 manner. After the four sub-pixels are arranged, lines of centers of the four sub-pixels can constitute a quadrangle which is defined as the first virtual quadrangle 14. The two first sub-pixels 11 are disposed opposite to each other along one diagonal of the first virtual quadrangle 14 and are located at two opposite vertices of the first virtual quadrilateral 14. The two second sub-pixels 12 are disposed opposite to each other along the other diagonal of the first virtual quadrangle 14 and are located at the other two vertices of the first virtual quadrangle 14. The two first sub-pixels 11 and the two second sub-pixels 12 constitute the first virtual quadrangle 14. One third sub-pixel 13 is disposed inside the first virtual quadrangle 14. It is to be understood that the center of a first sub-pixel 11 may be understood as the center of gravity of the first sub-pixel 11 and that the center of a second sub-pixel 12 may be understood as the center of gravity of the second sub-pixel 12. When the first sub-pixel 11 includes a protrusion portion tc and the second sub-pixel 12 does not include a protrusion portion tc, the center of gravity of the first sub-pixel 11 does not coincide with the geometric center of the first sub-pixel 11, and the center of gravity of the second sub-pixel 12 coincides with the geometric center of the second sub-pixel 12. When the first sub-pixel 11 does not include a protrusion portion tc and the second sub-pixel 12 includes a protrusion portion, the center of gravity of the first sub-pixel 11 coincides with the geometric center of the first sub-pixel 11, and the center of gravity of the second sub-pixel 12 does not coincide with the geometric center of the second sub-pixel 12.

Pixel arrangement is performed for the plurality of third sub-pixels 13. Multiple third sub-pixels 11 constitute the second virtual quadrangle 15 through the arrangement in a 2*2 manner. The center of a third sub-pixel 13 is located at a vertex P3 of the second virtual quadrangle 15. That is, after four third sub-pixels 13 are arranged in a 2*2 manner, lines of centers of the four third sub-pixels 13 can constitute a quadrangle which is defined as the second virtual quadrangle 15. Based on the pixel arrangement manner of the first sub-pixels 11, the second sub-pixels 12 and the third sub-pixels 13, some second virtual quadrangles 15 are each provided with a first sub-pixel 11 inside, and other second virtual quadrangles 15 are each provided with a second sub-pixel 12 inside. It is to be understood that the center of a third sub-pixel 13 may be understood as the center of gravity of the third sub-pixel 13 and that the center of gravity of the third sub-pixel 13 coincides with the geometric center of the third sub-pixel 13.

As shown in FIG. 2, directions in which the first sub-pixels 11 and the second sub-pixels 12 are alternately arranged include the X direction and the Y direction. The X direction intersects the Y direction. In the X direction, one row of sub-pixels are composed of first sub-pixels 11 and second sub-pixels 12 that are alternately arranged. In the Y direction, one column of sub-pixels are composed of first sub-pixels 11 and second sub-pixels 12 that are alternately arranged. On this basis, a plane constituted by the X direction and the Y direction is parallel to a display surface of the display panel. The thickness direction of the display panel is perpendicular to the display surface of the display panel. That is, the thickness direction of the display panel is perpendicular to the X direction and the Y direction.

In an embodiment, FIG. 3 is a first structural diagram of a sub-pixel including a protrusion portion according to an embodiment of the present application. As shown in FIG. 3, a first sub-pixel 11 or a second sub-pixel 12 includes a main portion zt and a protrusion portion tc. FIG. 3 illustrates an example in which a first sub-pixel 11 includes a main portion zt and a protrusion portion tc. A main portion zt may be understood as a main part of a first sub-pixel 11 or a main part of a second sub-pixel 12 to be used to limit a main opening region of the first sub-pixel 11 or a main opening region of the second sub-pixel 12, that is, the main shape of a light emission region of the first sub-pixel 11 or the main shape of a light emission region of the second sub-pixel 12. A protrusion portion tc may be understood as an auxiliary part of a first sub-pixel 11 or an auxiliary part of a second sub-pixel 12 to be used to limit a partial edge contour of the first sub-pixel 11 or a partial edge contour of the second sub-pixel 12. In an embodiment, the main portion zt may include a first edge zt1 and a second edge zt2. The first edge zt1 and the second edge zt2 extend in the first direction (the Y direction as shown) and are arranged in the second direction (the X direction as shown). The main portion zt and the protrusion portion tc are two parts connected to each other. The connection position between the protrusion portion tc and the main portion zt may be understood as the position where the extension direction of the first edge zt1 and the extension direction of the second edge zt2 change. In an embodiment, the length of the protrusion portion tc is X1 in the first direction. That is, the length of the protrusion portion tc in the first direction is X1. The length of the protrusion portion tc in the first direction may also be understood as the projection length in the first direction of a connection line between a connection point of the first edge zt1 and a third edge tc1 and a vertex on one side of the protrusion portion tc farthest from the main portion zt. Alternatively, the length of the protrusion portion tc in the first direction may also be described from the perspective of a virtual shape. As shown in FIG. 3, the sub-pixel including the protrusion portion includes a virtual shape. The virtual shape in embodiments of the present application may be understood as an external shape corresponding to the sub-pixel including the protrusion portion. The external shape includes two groups of opposite edges parallel to each other. The position of the protrusion portion farthest from the main portion is located on the external shape. As shown in FIG. 3, the virtual shape 16 includes a first virtual edge 161, a second virtual edge 162, and a third virtual edge 163. The third virtual edge 163 is connected to the first virtual edge 161 and the second virtual edge 162. The main portion zt includes the first edge zt1 and the second edge zt2. The first edge zt1 and the second edge zt2 extend in the first direction Y and are arranged in the second direction X. The protrusion portion tc includes the third edge tc1. The third edge tc1 is connected to the first edge zt1 and the second edge zt2. The first virtual edge 161 partially coincides with the first edge zt1. The length of the protrusion portion the in the first direction here may be understood as the length of a part of the first virtual edge 161 not coinciding with the first edge zt1. The length of the main portion zt and the length of the protrusion portion the are each X2 in the second direction (the X direction as shown). That is, the length of the main portion zt in the second direction and the length of the protrusion portion tc in the second direction are each X2. In an embodiment, as shown in FIG. 3, the main portion zt includes the first edge zt1, the second edge zt2, and a fourth edge zt3. The first edge zt1 and the second edge zt2 extend in the first direction Y and are arranged in the second direction X. The fourth edge zt3 extends in the second direction X and is connected to the same side of the first edge zt1 and the second edge zt2. The length of the main portion zt in the second direction and the length of the protrusion portion tc in the second direction here may be understood as the length of the fourth edge zt3. In an embodiment, 0<X1<X2/2. That is, the length of the protrusion portion tc in the first direction is greater than zero and less than half of the length of the main portion zt in the second direction and the length of the protrusion portion tc in the second direction. Compared with the virtual shape of the first sub-pixel 11, the size of the main portion zt and the size of the protrusion portion tc are set to satisfy that 0<X1<X2/2. Such an arrangement guarantees a relatively large aperture ratio of the sub-pixel including the protrusion portion tc and increases the minimum distance between the first sub-pixel 11 and an adjacent second sub-pixel 12. That is, the transmission path of the leakage current between the first sub-pixel 11 and the second sub-pixel 12 is prolonged. In this case, the leakage current between the first sub-pixel 11 and the second sub-pixel 12 can be reduced, avoiding the mutual crosstalk of display signals between the first sub-pixel 11 and the second sub-pixel 12, avoiding the undesired light emission between two adjacent sub-pixels, and improving the display effect of the display panel. Further, when X1>X2/2, the minimum distance between the first sub-pixel 11 and the second sub-pixel 12 adjacent to each other in the first direction and/or the second direction is relatively small. Alternatively, the leakage current between the first sub-pixel 11 and the second sub-pixel 12 is increased, causing the mutual crosstalk of display signals between the first sub-pixel 11 and the second sub-pixel 12.

Moreover, as shown in FIG. 3, the protrusion portion tc includes an end point a, an end point b, an end point c, and an end point d. Moreover, the end point a is located on the first edge zt1 of the main portion zt. The end point d is located on the second edge zt2 of the main portion zt. The end point b and the end point c may be the same end point or different end points. Moreover, the end point a, the end point b, the end point c, and the end point d are located on the same virtual circle. The virtual circle 17 is a circumcircle of the sub-pixel including the protrusion portion. Therefore, the contour of the protrusion portion may or may not coincide with the contour of the virtual circle 17 as long as the end point a, the end point b, the end point c and the end point d of the protrusion portion tc are located on an edge contour line of the virtual circle 17. In this case, the protrusion portion protrudes towards one side of the virtual circle 17 to a relatively great degree, that is, towards one side away from the main portion zt. Such an arrangement can guarantee that the protrusion portion the has a relatively large protrusion area. Therefore, when 0<X1<X2/2, the aperture ratio of the sub-pixel including the protrusion portion may be affected to a certain degree compared with the case where X1>X2/2. However, when comparing two different cases where X1<X2/2 and where X1>X2/2, the aperture ratio has a relatively small variation amplitude, and the minimum distance of the first sub-pixel 11 and the second sub-pixel 12 in the first direction and/or the second direction has a relatively large variation amplitude. That is, the variation amplitude of the aperture ratio is smaller than the variation amplitude of the minimum distance in two different cases where

X1<X2/2 and where X1>X2/2. Therefore, the arrangement in which 0<X1<X2/2 guarantees a relatively small leakage current between the first sub-pixel 11 and the second sub-pixel 12 and guarantees that a relatively large aperture ratio of the sub-pixel including the protrusion portion, thereby guaranteeing the display effect of the sub-pixel from two perspectives of the relatively small leakage current and the relatively large aperture ratio.

It is to be noted that the virtual shape 16 of the first sub-pixel 11 may be shown as a dotted line in the form of a dashed line in FIG. 3. The virtual shape 16 of the first sub-pixel 11 may be a parallelogram having an edge length of X2.

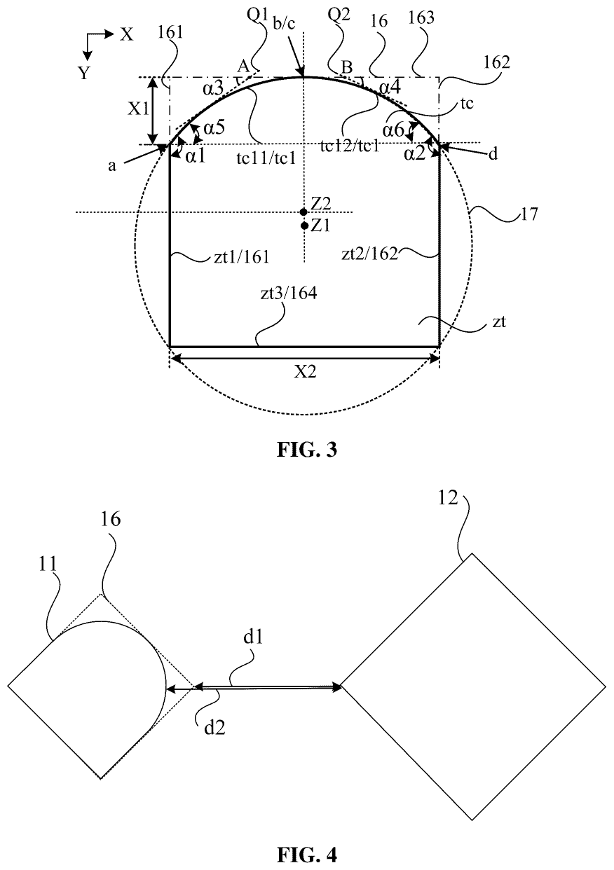

For example, FIG. 4 is a first structural diagram of a first sub-pixel and a second sub-pixel according to an embodiment of the present application. As shown in FIG. 4, the first sub-pixel 11 and the second sub-pixel 12 are adjacent to each other in the second direction. It can be seen that the minimum distance between the virtual shape 16 of the first sub-pixel 11 and the second sub-pixel 12 is d1 and that the minimum distance between the first sub-pixel 11 and the second sub-pixel 12 is d2. d1 is less than d2. It is to be understood that d2 is substantially the minimum distance between an opening region of the first sub-pixel 11 and an opening region of the second sub-pixel 12. Therefore, the preceding design of the first sub-pixel 11 and the second sub-pixel 12 can increase the distance between the opening region of the second sub-pixel 12 and the opening region of the first sub-pixel 11, reduce light emission interference, and improve display effect.

It is to be noted that a first sub-pixel or a second sub-pixel includes a main portion and a protrusion portion in embodiments of the present application here may be understood as the pixel opening of the first sub-pixel or the pixel opening of the second sub-pixel includes a main portion and a protrusion portion. That is, a light emission region of the first sub-pixel or a light emission region of the second sub-pixel includes a main portion and a protrusion portion.

In conclusion, in the technical solutions provided in embodiments of the present application, a first sub-pixel or a second sub-pixel includes a main portion and a protrusion portion that are disposed in the first direction. The length of the protrusion portion is X1 in the first direction. The length of the main portion and the length of the protrusion portion are each X2 in the second direction. 0<X1<X2/2. Through the preceding technical solutions, the adjustment of the shape of the first sub-pixel or the shape of the second sub-pixel can increase the distance between the first sub-pixel and the second sub-pixel, guarantee that the sub-pixel including the protrusion portion has a relatively large opening area, reduce a display leakage current between the first sub-pixel and the second sub-pixel, guarantee the opening area and aperture ratio of a sub-pixel, alleviate the crosstalk between different sub-pixels and the undesired light emission of sub-pixels, and improve the display effect of the display panel.

On the basis of the preceding embodiments, with continued reference to FIG. 3, the virtual shape 16 of the sub-pixel including the protrusion portion tc constitutes a first virtual parallelogram. The first virtual parallelogram has the first virtual edge 161, the second virtual edge 162, and the third virtual edge 163. The third virtual edge 163 is connected to the same side of the first virtual edge 161 and the second virtual edge 162. The main portion zt includes the first edge zt1 and the second edge zt2. The first edge zt1 and the second edge zt2 extend in the first direction Y and are arranged in the second direction X. The protrusion portion tc includes the third edge tel. The third edge tc1 is connected to the first edge zt1 and the second edge zt2. The third edge tc1 includes a first sub-segment tc11 and a second sub-segment tc12. The first sub-segment tc11 is connected to the first edge zt1. The second sub-segment tc12 is connected to the second edge zt2.

The first virtual edge 161 partially coincides with the first edge zt1. The second virtual edge 162 partially coincides with the second edge zt2. An end point on one side of the first sub-segment tc11 close to the second sub-segment tc12 and an end point on one side of the second sub-segment tc12 close to the first sub-segment tc11 are each located on the third virtual edge 163. The center Z1 of the sub-pixel including the protrusion portion tc (the first sub-pixel 11 as shown in FIG. 3) is located on one side of an intersection point between a perpendicular bisector of the first virtual edge 161 and a perpendicular bisector of the third virtual edge 163 facing the main portion zt.

It is to be understood that the center Z1 of the sub-pixel including the protrusion portion tc may be understood as the center of gravity of the sub-pixel. Before the shape of the sub-pixel including the protrusion portion, for example, the virtual shape 16 as shown in FIG. 3, does not change, the center of the sub-pixel is located at the intersection point Z2 between the perpendicular bisector of the first virtual edge 161 and the perpendicular bisector of the third virtual edge 163. When the shape of the sub-pixel changes to form the sub-pixel including the protrusion portion as shown in FIG. 3, the specific change manner may be understood as selecting an end point of the first virtual edge 161, such as the end point a in the figure; selecting at least one end point of the third virtual edge 163 which may be one end point or two end points such as the end point b and the end point c in the figure; selecting an end point in the second virtual edge 162, such as the end point d in the figure; connecting the end point a and the end point b by a straight line or curve; and connecting the end point c and the end point d by a straight line or curve. Moreover, when a connection line segment between the end point a and the end point b is a curve, the curve protrudes in a direction away from the center Z1 of the sub-pixel. When a connection line segment between the end point c and the end point d is a curve, the curve protrudes in a direction away from the center Z1 of the sub-pixel. When the end point b and the end point c are different end points, the end point b and the end point c are connected by a straight line. A connection line segment between the end point b and the end point c coincides with the third virtual edge 163. It may be understood that the opening area of the sub-pixel whose shape changes is reduced. For example, the opening area on one side of the protrusion portion is reduced compared with the opening area of the virtual shape 16. In this case, the center of the sub-pixel is offset towards one side away from the protrusion portion or towards one side facing the main portion compared with the center of the virtual shape 16. That is, the center of the sub-pixel (the first sub-pixel as shown in FIG. 3) including the protrusion portion tc is located on one side of the intersection point between the perpendicular bisector of the first virtual edge 161 and the perpendicular bisector of the third virtual edge 163 close to the main portion zt.

With continued reference to FIG. 3, in an optional embodiment, 2 μm≤X1≤4 μm. That is, the length of the protrusion portion tc is between 2 μm and 4 μm in the first direction (the Y direction as shown). Such an arrangement can guarantee that the protrusion portion tc matches the overall size of each sub-pixel to meet the requirements for the size of each sub-pixel in the display panel with a relatively high pixel resolution. Moreover, such an arrangement can also guarantee a relatively large distance between the first sub-pixel 11 and the second sub-pixel 12 in the case where the aperture ratio of the sub-pixel including the protrusion portion tc is relatively large, guaranteeing the display brightness of sub-pixels and alleviating the crosstalk between different sub-pixels and the undesired light emission of sub-pixels.

In an embodiment, X1=3 μm. That is, the length of the protrusion portion tc is 3 μm in the first direction (the Y direction as shown), guaranteeing that the protrusion portion tc perfectly matches the overall size of each sub-pixel to meet the requirements for the size of each sub-pixel in the display panel with a relatively high pixel resolution.

Moreover, with this arrangement, the aperture ratio of the sub-pixel including the protrusion portion tc and the distance between the first sub-pixel 11 and the second sub-pixel 12 can be well considered, fully guaranteeing the display brightness of sub-pixels and alleviating the crosstalk between different sub-pixels and the undesired light emission of sub-pixels.

With continued reference to FIG. 3, in an optional embodiment, 5 μm≤X2≤60 μm. That is, the length of the main portion zt and the length of the protrusion portion tc are each between 5 μm and 60 μm in the second direction (the X direction as shown). Such an arrangement can guarantee that the main portion zt and the protrusion portion tc match the overall size of each sub-pixel to meet the requirements for the size of each sub-pixel in the display panel with a relatively high pixel resolution. Moreover, such an arrangement can also guarantee a relatively large aperture ratio of the sub-pixel including the protrusion portion tc and the good display brightness of the sub-pixel including the protrusion portion tc.

In an embodiment, a first sub-pixel 11 includes a main portion zt and a protrusion portion tc. The first sub-pixel 11 includes a red sub-pixel. In the first sub-pixel 11, 10 μm≤X2≤20 μm. That is, for the red sub-pixel including the protrusion portion, the length of the main portion zt and the length of the protrusion portion the are each between 10 μm and 20 μm in the second direction (the X direction as shown). With this arrangement, on the basis of considering the luminescence efficiency of the red sub-pixel, it guarantees that the main portion zt and the protrusion portion tc well match the overall size of each sub-pixel to meet the requirements for the size of each sub-pixel in the display panel with a relatively high pixel resolution. Moreover, such an arrangement can guarantee the aperture ratio of the sub-pixel including the protrusion portion tc and fully guarantee the display brightness of sub-pixels.

Alternatively, a second sub-pixel 12 includes a main portion zt and a protrusion portion tc. The second sub-pixel 12 includes a blue sub-pixel. In the second sub-pixel 12, 15 μm≤X2<40 μm. That is, for the blue sub-pixel including the protrusion portion, the length of the main portion zt and the length of the protrusion portion tc are each between 15 μm and 40 μm in the second direction (the X direction as shown). With this arrangement, on the basis of considering the luminescence efficiency of the blue sub-pixel, it guarantees that the main portion zt and the protrusion portion tc well match the overall size of each sub-pixel to meet the requirements for the size of each sub-pixel in the display panel with a relatively high pixel resolution. Moreover, such an arrangement can guarantee the aperture ratio of the sub-pixel including the protrusion portion tc and fully guarantee the display brightness of sub-pixels.

With continued reference to FIG. 3, in an optional embodiment, 5%≤X1/X2≤30%. That is, a ratio of the length of the protrusion portion tc in the first direction (the Y direction as shown) to the length of the main portion zt in the second direction (the X direction as shown) (or the length of the protrusion portion tc in the second direction) is between 5% and 30%. Such an arrangement can guarantee a relatively large aperture ratio of the sub-pixel including the protrusion portion tc, guarantee that the distance between the first sub-pixel 11 and the second sub-pixel 12 adjacent to each other is relatively large, reduce the leakage current between the first sub-pixel 11 and the second sub-pixel 12, fully guarantee the display brightness of sub-pixels, and alleviate the crosstalk between different sub-pixels and the undesired light emission of sub-pixels. For example, if X1/X2 <5%, the length of the protrusion portion tc in the first direction (the Y direction as shown) will be relatively small, and the area of the protrusion portion tc will be relatively small, affecting the aperture ratio of the sub-pixel including the protrusion portion tc and thereby affecting the display brightness of the sub-pixel including the protrusion portion. If X1/X2>30%, the length of the protrusion portion the in the first direction (the Y direction as shown) will be relatively large, causing the distance between the first sub-pixel and the second sub-pixel to be relatively small, shortening the transmission path of the leakage current between the first sub-pixel and the second sub-pixel, increasing the leakage current between the first sub-pixel and the second sub-pixel, and causing the crosstalk between the first sub-pixel and the second sub-pixel and the undesired light emission of sub-pixels. Therefore, the reasonable arrangement in which 5%≤X1/X2<30% guarantees a well consideration of both the aperture ratio of the sub-pixel and the crosstalk between sub-pixels and comprehensively guarantees the display effect of the display panel.

Exemplarily, 5%≤X1/X2≤30%. The ratio of X1 to X2 may be 5%, 7%, 10%, 12.5%, 15.7%, 18%, 22.3%, 24.6%, 27%, 28.6%, or 30%. The specific ratio of X1 to X2 is not described in embodiments of the present application. The ratio of X1 to X2 is described in detail hereinafter in connection with the light-emitting color of the sub-pixel including the protrusion portion.

In an optional embodiment, a first sub-pixel 11 includes a main portion zt and a protrusion portion tc. The first sub-pixel 11 includes a red sub-pixel. In the first sub-pixel 11, 20%≤X1/X2≤25%. That is, for the red sub-pixel including the protrusion portion, the ratio of the length of the protrusion portion tc in the first direction (the Y direction as shown) to the length of the main portion zt in the second direction (the X direction as shown) (or the length of the protrusion portion tc in the second direction) is between 20% and 25%. With this arrangement, on the basis of considering the luminescence efficiency of the red sub-pixel, it guarantees the aperture ratio of the red sub-pixel including the protrusion portion tc and the display brightness of the red sub-pixel. Moreover, the arrangement in which 20%≤X1/X2<25% enables the distance between the first sub-pixel 11 and an adjacent second sub-pixel 12 to be relatively large, reducing the leakage current between the first sub-pixel 11 and the second sub-pixel 12, fully guaranteeing the display brightness of sub-pixels, and alleviating the crosstalk between different sub-pixels and the undesired light emission of sub-pixels.

In an embodiment, with a comprehensive consideration of the luminescence efficiency of the red sub-pixel, the aperture ratio of the red sub-pixel and the transmission path of the leakage current between the red sub-pixel and another adjacent sub-pixel, it may be set after a large number of experimental verifications that in the red sub-pixel including the protrusion portion, X1/X2=23%. Such an arrangement, combined with the luminescence efficiency of the red sub-pixel and the aperture ratio of the red sub-pixel including the protrusion portion, can guarantee that the display brightness of the red sub-pixel including the protrusion portion meets display requirements and that the display brightness of the red sub-pixel is not affected by the inclusion of the protrusion portion.

Moreover, it guarantees that the transmission path of the leakage current between the red sub-pixel including the protrusion portion and another adjacent sub-pixel is relatively long, reducing the leakage current between the first sub-pixel 11 and the second sub-pixel 12.

The arrangement in which X1/X2=23% guarantees the display brightness of the red sub-pixel including the protrusion portion and enables the comprehensive consideration effect of the leakage current between the first sub-pixel and the second sub-pixel to achieve optimal performance.

In another optional embodiment, a second sub-pixel 12 includes a main portion zt and a protrusion portion tc. The second sub-pixel 11 includes a blue sub-pixel. In the second sub-pixel 12, 12%≤X1/X2≤20%. That is, for the blue sub-pixel including the protrusion portion, the ratio of the length of the protrusion portion tc in the first direction (the Y direction as shown) to the length of the main portion zt in the second direction (the X direction as shown) (or the length of the protrusion portion tc in the second direction) is between 12% and 20%. With this arrangement, on the basis of considering the luminescence efficiency of the blue sub-pixel, it guarantees the aperture ratio of the blue sub-pixel including the protrusion portion tc and the display brightness of the blue sub-pixel. Moreover, the arrangement in which 12%≤X1/X2≤20% enables the distance between the second sub-pixel 12 and an adjacent first sub-pixel 11 to be relatively large, reducing the leakage current between the first sub-pixel 11 and the second sub-pixel 12, fully guaranteeing the display brightness of sub-pixels, and alleviating the crosstalk between different sub-pixels and the undesired light emission of sub-pixels.

In an embodiment, with a comprehensive consideration of the luminescence efficiency of the blue sub-pixel, the aperture ratio of the blue sub-pixel and the transmission path of the leakage current between the blue sub-pixel and another adjacent sub-pixel, it may be set after a large number of experimental verifications that in the blue sub-pixel including the protrusion portion, X1/X2=16%. Such an arrangement, combined with the luminescence efficiency of the blue sub-pixel and the aperture ratio of the blue sub-pixel including the protrusion portion, can guarantee that the display brightness of the blue sub-pixel including the protrusion portion meets display requirements and that the display brightness of the blue sub-pixel is not affected by the inclusion of the protrusion portion. Moreover, it guarantees that the transmission path of the leakage current between the blue sub-pixel including the protrusion portion and another adjacent sub-pixel is relatively long, reducing the leakage current between the first sub-pixel 11 and the second sub-pixel 12. The arrangement in which X1/X2=23% guarantees the display brightness of the blue sub-pixel including the protrusion portion and enables the comprehensive consideration effect of the leakage current between the first sub-pixel and the second sub-pixel to achieve optimal performance.

On the basis of the preceding embodiments, the area of the protrusion portion is S1, and the area of the main portion is S2. 1/40<S1/S2≤½. That is, an area ratio of the protrusion portion to the main portion is between 1/40 and ½. The main portion is a main part of a first sub-pixel or a second sub-pixel to be used to limit a main opening region of a sub-pixel; therefore, the arrangement in which the main portion has a relatively large area can guarantee the basic display effect of the sub-pixel. The protrusion portion is an auxiliary part of a first sub-pixel or an auxiliary part of a second sub-pixel to be used to limit an opening region and shape of a sub-pixel; therefore, the arrangement in which the protrusion portion has a relatively small area can guarantee that the overall display effect of the sub-pixel is not affected; moreover, the flexible adjustment of the area of the protrusion portion helps flexibly adjust the aperture ratio of the sub-pixel and the distance from another sub-pixel, thereby extending distances between different sub-pixels to reduce the transmission of leakage currents and eliminating or reducing the display crosstalk between adjacent sub-pixels.

In an embodiment, 1/20≤S1/S2≤⅖. That is, the area ratio between the protrusion portion to the main portion is between 1/20 and ⅖. Such an arrangement can guarantee a relatively large aperture ratio of the sub-pixel including the protrusion portion, guarantee that the distance between the first sub-pixel and the second sub-pixel adjacent to each other is relatively large, reduce the leakage current between the first sub-pixel and the second sub-pixel, fully guarantee the display brightness of sub-pixels, and alleviate the crosstalk between different sub-pixels and the undesired light emission of sub-pixels. For example, if S1/S2< 1/20, the area of the protrusion portion will be relatively small, affecting the aperture ratio of the sub-pixel including the protrusion portion, thereby affecting the display brightness of the sub-pixel including the protrusion portion, and limiting the adjustment of the area and shape of the sub-pixel by the protrusion portion. If S1/S2>⅖, the area of the protrusion portion will be relatively large, causing the distance between the first sub-pixel and the second sub-pixel to be relatively small, shortening the transmission path of the leakage current between the first sub-pixel and the second sub-pixel, increasing the leakage current between the first sub-pixel and the second sub-pixel, and leading to the crosstalk and undesired light emission between the first sub-pixel and the second sub-pixel. Therefore, the reasonable arrangement in which 1/20 ≤S1/S2≤⅖ guarantees a well consideration of both the aperture ratio of the sub-pixel and the crosstalk between sub-pixels and comprehensively guarantees the display effect of the display panel.

Exemplarily, 1/20≤S1/S2≤⅖. The ratio of S1 to S2 may be 1/20, 1/15, 1/10, ⅕, or ⅖. The specific ratio of S1 to S2 is not described in embodiments of the present application.

In conclusion, the preceding embodiments describe the size of the sub-pixel including the protrusion portion so as to well consider both the aperture ratio of the sub-pixel including the protrusion portion and the transmission path of the leakage current between the sub-pixel and another adjacent sub-pixel, guaranteeing the aperture ratio of the sub-pixel including the protrusion portion, reducing leakage currents between different sub-pixels, guaranteeing the display brightness of sub-pixels, alleviating the crosstalk and leakage currents between sub-pixels, and improving the overall display effect of the display panel.

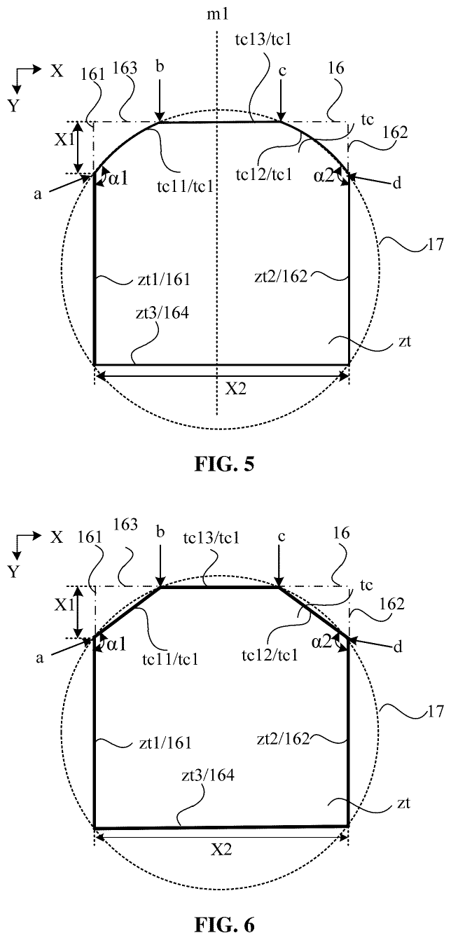

On the basis of the preceding embodiments, FIG. 5 is a second structural diagram of a sub-pixel including a protrusion portion according to an embodiment of the present application. FIG. 6 is a third structural diagram of a sub-pixel including a protrusion portion according to an embodiment of the present application. Referring to FIGS. 3, 5, and 6, the main portion zt includes the first edge zt1 and the second edge zt2. The first edge zt1 and the second edge zt2 extend in the first direction (the Y direction as shown) and are arranged in the second direction (the X direction as shown). The protrusion portion tc includes the third edge tc1. The third edge tc1 is connected to the same side of the first edge zt1 and the second edge zt2. The third edge tc1 includes the first sub-segment tc11 and the second sub-segment tc12. The first sub-segment tc11 is connected to the first edge zt1. The second sub-segment tc12 is connected to the second edge zt2. The maximum included angle between one side of the first sub-segment tc11 facing the second edge zt2 and the first edge zt1 is α1. The maximum included angle between one side of the second sub-segment tc12 facing the first edge zt1 and the second edge zt2 is α2. 100°≤α1≤150°. 100°≤α2≤150°.

For example, referring to FIGS. 3, 5, and 6, the main portion zt includes the first edge zt1 and the second edge zt2 that are opposite to each other. The first edge zt1 and the second edge zt2 each extend in the first direction (the Y direction as shown), guaranteeing that the overall structure of the main portion zt is regular. As the main light emission region of the sub-pixel, the main portion zt helps guarantee the display effect of the sub-pixel including the protrusion portion. In an embodiment, the protrusion portion tc includes the third edge tc1. The third edge tc1 includes the first sub-segment tc11 and the second sub-segment tc12. An included angle exists between one side of the first sub-segment tc11 facing the second edge zt2 and the first edge zt1. An included angle exists between one side of the second sub-segment tc12 facing the first edge zt1 and the second edge zt2. It is to be understood that a larger included angle between one side of the first sub-segment tc11 facing the second edge zt2 and the first edge zt1 indicates that the extension direction of the first sub-segment tc11 is closer to the extension direction of the first edge zt1. Moreover, a larger included angle between one side of the second sub-segment tc12 facing the first edge zt1 and the second edge zt2 indicates that the extension direction of the second sub-segment tc12 is closer to the extension direction of the second edge zt2. In the case where the length of the protrusion portion tc in the first direction (the Y direction as shown) does not change, the larger the area of the protrusion portion tc, the larger the aperture ratio of the sub-pixel including the protrusion portion tc. However, referring to FIG. 4, it can be seen that when the included angle between one side of the first sub-segment tc11 facing the second edge zt2 and the first edge zt1 is larger and when the included angle between one side of the second sub-segment tc12 facing the first edge zt1 and the second edge zt2 is larger, the minimum distance between the first sub-pixel 11 and the second sub-pixel 12 is larger. With this arrangement, the transmission path of the leakage current between the first sub-pixel 11 and the second sub-pixel 12 is shortened, increasing the leakage current between the first sub-pixel 11 and the second sub-pixel 12 and causing the display crosstalk between the first sub-pixel 11 and the second sub-pixel 12 and the undesired light emission of sub-pixels. Therefore, with a comprehensive consideration of the aperture ratio of the sub-pixel including the protrusion portion and the transmission path of the leakage current between the sub-pixel and another adjacent sub-pixel, it can be set that 1000<α1<1500 and that 100°≤α≥150°. Such an arrangement can guarantee that the transmission path of the leakage current between the sub-pixel and another adjacent sub-pixel is relatively long in the case where the aperture ratio of the sub-pixel including the protrusion portion is relatively large, avoiding or alleviating display crosstalk and undesired light emission.

In an embodiment, the preceding embodiments describe an example of the maximum included angle α1 between one side of the first sub-segment tc11 facing the second edge zt2 and the first edge zt1 and the maximum included angle α2 between one side of the second sub-segment tc12 facing the first edge zt1 and the second edge zt2. It is to be understood that the arrangement manner of the third edge tc1 in the protrusion portion tc may be described in other manners.

For example, with continued reference to FIG. 3, an included angle between one side of the first sub-segment tc11 facing the second edge zt2 and a connection line between the end point a and the end point d may be defined as α5. An included angle between one side of the second sub-segment tc12 facing the first edge zt1 and a connection line between the end point a and the end point d may be defined as α6. It may be set that 10°≤α5≤60° and that 10°≤α6≤60°. Such an arrangement can guarantee that the transmission path of the leakage current between the sub-pixel and another adjacent sub-pixel is relatively long in the case where the aperture ratio of the sub-pixel including the protrusion portion is relatively large, avoiding or alleviating display crosstalk and undesired light emission.

It is to be noted that the first sub-segment tc11 may be directly connected to the second sub-segment tc12. That is, the first sub-segment tc11 and the second sub-segment tc12 form the third edge tc1, as shown in FIG. 3. Alternatively, the first sub-segment tc11 is indirectly connected to the second sub-segment tc12. The third edge tc1 further includes a line segment other than the first sub-segment tc11 and the second sub-segment tc12, for example, a third sub-segment tc13 as shown in FIGS. 5 and 6. The specific arrangement manner of the third edge tc1 is described in subsequent embodiments.

In an embodiment, 110°≤α1≤135°. 110°≤α2≤135°. That is, the included angle between one side of the first sub-segment tc11 facing the second edge zt2 and the first edge zt1 is in the range of 110° to 135°, and the included angle between one side of the second sub-segment tc12 facing the first edge zt1 and the second edge zt2 is in the range of 110° to 135°. Such an arrangement can prevent an excessively small included angle from causing a relatively small aperture ratio of the sub-pixel including the protrusion portion and leading to the poor display effect of the sub-pixel. Moreover, such an arrangement can prevent an excessively large included angle from causing a relatively large minimum distance between the sub-pixel including the protrusion portion and an adjacent sub-pixel, from causing a relatively large leakage current, and thus from causing serious crosstalk and serious undesired light emission of sub-pixels.

Exemplarily, 110°≤α1≤135°. For example, α1 may be, for example, 111°, 115°, 120°, 125°, 130°, 134°, or 135°. Similarly, 110°≤α2≤135°. For example, α2 may be, for example, 111°, 115°, 120°, 125°, 130°, 134°, or 135°. Moreover, the specific value of α1 may be the same as or different from the specific value of α2, which is not limited in embodiments of the present application.

In an embodiment, the preceding embodiments describe an example of the maximum included angle α1 between one side of the first sub-segment tc11 facing the second edge zt2 and the first edge zt1 and the maximum included angle α2 between one side of the second sub-segment tc12 facing the first edge zt1 and the second edge zt2. It is to be understood that the arrangement manner of the third edge tc1 in the protrusion portion tc may be described in other manners.

For example, with continued reference to FIG. 3, the included angle between one side of the first sub-segment tc11 facing the second edge zt2 and the connection line between the end point a and the end point d may be defined as α5. The included angle between one side of the second sub-segment tc12 facing the first edge zt1 and the connection line between the end point a and the end point d may be defined as α6. It may be set that 20°≤α5≤45° and that 20°≤α6≤45°. Such an arrangement can prevent an excessively small included angle from causing a relatively small aperture ratio of the sub-pixel including the protrusion portion and leading to the poor display effect of the sub-pixel. Moreover, such an arrangement can prevent an excessively large included angle from causing a relatively large minimum distance between the sub-pixel including the protrusion portion and an adjacent sub-pixel, from causing a relatively large leakage current, and thus from causing serious crosstalk and serious undesired light emission of sub-pixels.

Exemplarily, 20°≤α5≤45°. For example, α5 may be, for example, 20°, 23°, 25°, 28°, 30°, 35°, 40°, or 45°. Similarly, 20°≤α6≤45°. For example, α6 may be, for example, 20°, 23°, 25°, 28°, 30°, 35°, 40°, or 45°. Moreover, the specific value of α5 may be the same as or different from the specific value of α6, which is not limited in embodiments of the present application. In an optional embodiment, it may be set that α5=α6=25°. In another optional embodiment, it may be set that α5=α6=35°.

On the basis of the preceding embodiments, with continued reference to FIGS. 3, 5, and 6, the end point a on one side of the first sub-segment tc11 away from the second sub-segment tc12, the end point b on one side of the first sub-segment tc11 close to the second sub-segment tc12, the end point c on one side of the second sub-segment tc12 close to the first sub-segment tc11, and the end point d on one side of the second sub-segment tc12 away from the first sub-segment tc11 are located on the same virtual circle 17.

For example, as shown in FIGS. 3, 5, and 6, the first sub-segment tc11 includes the end point a on one side away from the second sub-segment tc12 and the end point b on one side close to the second sub-segment tc12. The second sub-segment tc12 includes the end point c on one side close to the first sub-segment tc11 and the end point d on one side away from the first sub-segment tc11. The end point a, the end point b, the end point c, and the end point d are located on the circumference of the same virtual circle. Compared with the case where two end points of the first sub-segment tc11 are located on the circumference of the same virtual circle, two end points of the second sub-segment tc12 are located on the circumference of the same virtual circle, but the two virtual circles are not the same, the technical solutions in embodiments of the present application can guarantee that the virtual circle has a relatively large circumferential radius. For example, the radius R of the virtual circle 17 and the edge length La of the first virtual edge 161 of the virtual shape 16 satisfy that 0.2*La≤Ra≤1.5*La. That is, the radius R of the virtual circle is designed to be 0.2 times to 1.5 times the length La of the first virtual edge of the corresponding sub-pixel. Such an arrangement guarantees that the virtual circle has a relatively large circumferential radius. That is, the shape of the sub-pixel including the protrusion portion differs greatly from the virtual shape of the sub-pixel including the protrusion portion in contour, guaranteeing that the minimum distance between the sub-pixel including the protrusion portion and an adjacent sub-pixel is relatively small, reducing the risk of the leakage current between the sub-pixel including the protrusion portion and an adjacent sub-pixel, reducing the display interference between two adjacent sub-pixels, and guaranteeing the display contrast between two adjacent sub-pixels. Moreover, the end point a, the end point b, the end point c, and the end point d are located on the circumference of the same virtual circle, further guaranteeing that the edge contour of the third edge tc11 of the protrusion portion tc is relatively smooth, avoiding the problem that the edge of the sub-pixel is visible, and improving display quality.

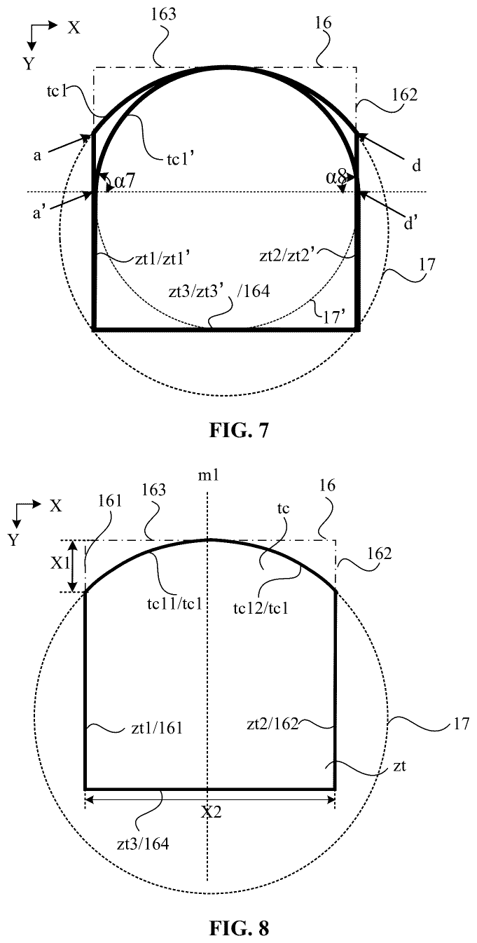

In an embodiment, FIG. 7 is a fourth structural diagram of a sub-pixel including a protrusion portion according to an embodiment of the present application. FIG. 8 is a fifth structural diagram of a sub-pixel including a protrusion portion according to an embodiment of the present application. Referring to FIGS. 3, 5, 6, 7, and 8, the virtual circle 17 is the circumcircle of the sub-pixel including the protrusion portion. The sub-pixel may be located inside the limited range of the virtual circle.

For example, referring to FIGS. 3, 5, 6, 7, and 8, when the virtual circle 17 is the circumcircle of the sub-pixel including the protrusion portion, a partial region of the virtual circle 17 is located inside the sub-pixel, and the remaining region of the virtual circle 17 is located outside the sub-pixel. Exemplarily, if a first sub-pixel includes a protrusion portion, a partial region of the virtual circle will be located inside the first sub-pixel, and the remaining region of the virtual circle will be located outside the first sub-pixel. If a second sub-pixel includes a protrusion portion, a partial region of the virtual circle will be located inside the second sub-pixel, and the remaining region of the virtual circle will be located outside the second sub-pixel. Moreover, referring to FIGS. 3, 5, and 6, an end point on one side of the first edge zt1 away from the protrusion portion tc and an end point on one side of the second edge zt2 away from the protrusion portion tc may be located on the circumference of the virtual circle 17. Alternatively, referring to FIG. 8, the end point on one side of the first edge zt1 away from the protrusion portion tc and the end point on one side of the second edge zt2 away from the protrusion portion tc may be located within the limited range of the virtual circle 17. The arrangement in which the virtual circle is the circumcircle of the sub-pixel and in which the size difference between the third edge tc11 and the virtual shape 16 is relatively small can guarantee a relatively large aperture ratio of the sub-pixel and guarantee the display effect of the sub-pixel. For example, referring to FIG. 7, as a comparative example, FIG. 7 illustrates the case where the virtual circle is an inscribed circle 17′. When the virtual circle is an inscribed circle 17′, a connection point between a third edge tc1′ and a first edge zt1′ is an end point a′, and a connection point between the third edge tc1′ and a second edge zt2′ is an end point d′. Included angles between the third edge tc1′ and a connection line of the end point a′ and the end point d′ are α7 and α8 respectively. 70°≤α7<90°. 70°≤α8≤90°. It can be seen based on FIG. 7 that the opening area of the sub-pixel including the protrusion portion when the virtual circle is a circumcircle is larger than the opening area of the sub-pixel including the protrusion portion when the virtual circle is an inscribed circle. Therefore, the virtual circle in embodiments of the present application is set to a circumcircle, guaranteeing a relatively large opening area of the sub-pixel including the protrusion portion and guaranteeing the display effect of the sub-pixel.

On the basis of the preceding embodiments, with continued reference to FIGS. 3, 5, 7, and 8, the first sub-segment tc11 and the second sub-segment tc12 are each arcuate and each coincide with the circumference of the virtual circle 17.

With continued reference to FIGS. 3, 5, 7, and 8, the first sub-segment tc11 and the second sub-segment tc12 are each arcuate and each protrude towards one side away from the main portion zt, thereby guaranteeing a relatively large aperture ratio of the sub-pixel and guaranteeing the display effect of the sub-pixel. Moreover, the first sub-segment tc11 and the second sub-segment tc12 each coincide with the circumference of the virtual circle 17. With this arrangement, when the sub-pixel including the protrusion portion is prepared, the pattern design of a mask structure required for the first sub-segment tc11 and the second sub-segment tc12 is simple, reducing the preparation difficulty of the first sub-segment tc11 and the second sub-segment tc12, thereby reducing the process difficulty of the sub-pixel including the protrusion portion, and improving preparation efficiency.

On the basis of the preceding embodiments, with continued reference to FIGS. 5 and 6, the third edge tc1 further includes the third sub-segment tc13. The third sub-segment tc13 is connected to the first sub-segment tc11 and the second sub-segment tc12. The third sub-segment tc13 is a straight line segment. A connection point between the third sub-segment tc13 and the first sub-segment tc11 is located on the circumference of the virtual circle 17. A connection point between the third sub-segment tc13 and the second sub-segment tc12 is located on the circumference of the virtual circle 17.

For example, with continued reference to FIGS. 5 and 6, the third edge tc1 further includes the third sub-segment tc13. The third sub-segment tc13, as the connection line segment between the first sub-segment tc11 and the second sub-segment tc12, may be a straight line segment, thereby reducing the preparation difficulty of the third edge tc1 and improving the preparation efficiency of the sub-pixel.

On the basis of the preceding embodiments, with continued reference to FIG. 5, the first sub-segment tc11 and/or the second sub-segment tc12 is arcuate and protrudes towards one side away from the main portion zt, thereby guaranteeing a relatively large aperture ratio of the sub-pixel and guaranteeing the display effect of the sub-pixel. It is to be noted that the arrangement in which the first sub-segment tc11 and/or the second sub-segment tc12 is arcuate may be that the first sub-segment tc11 is arcuate, may be that the second sub-segment tc12 is arcuate, and may be that the first sub-segment tc11 and the second sub-segment tc12 are each arcuate. FIG. 5 illustrates an example in which the first sub-segment tc11 and the second sub-segment tc12 are each arcuate, which is not a limitation.

On the basis of the preceding embodiments, with continued reference to FIG. 6, the first sub-segment tc11 and/or the second sub-segment tc12 is a straight line segment.

Such an arrangement can guarantee that the preparation process of the first sub-segment tc11 and the second sub-segment tc12 is simple, reducing the preparation difficulty of the sub-pixel including the protrusion portion and improving preparation efficiency. Moreover, the arrangement in which the first sub-segment tc11 and/or the second sub-segment tc12 is a straight line segment can increase the distance between the sub-pixel including the protrusion portion and an adjacent sub-pixel, that is, prolong the transmission path of the leakage current, thereby helping reduce the risk of display crosstalk and the undesired light emission of sub-pixels caused by the leakage current and improving display effect. It is to be noted that the arrangement in which the first sub-segment tc11 and/or the second sub-segment tc12 is a straight line segment may be that the first sub-segment tc11 is a straight line segment, may be that the second sub-segment tc12 is a straight line segment, and may be that the first sub-segment tc11 and the second sub-segment tc12 are each a straight line segment. FIG. 6 illustrates an example in which the first sub-segment tc11 and the second sub-segment tc12 are each a straight line segment, which is not a limitation.

On the basis of the preceding embodiments, with continued reference to FIGS. 5 and 6, the main portion zt further includes a fourth edge zt3 opposite to the third edge t1.

The fourth edge zt3 is connected to the same side of the first edge zt1 and the second edge zt2. The length of the third sub-segment tc13 is X3. The length of the fourth edge zt3 is X4. 0<X3≤X4/2.

For example, 0<X3≤X4/2. That is, the length of the third sub-segment tc13 needs to be greater than zero and less than half of the length of the fourth edge zt3. Referring to FIGS. 5 and 6, the larger the length of the third sub-segment tc13, the larger the aperture ratio loss of the sub-pixel (an interval between the third edge tc1 and the virtual shape 16 may be understood as the aperture ratio loss). The smaller the length of the third sub-segment tc13, the smaller the aperture ratio loss but the more difficult the preparation process of the sub-pixel. Therefore, with a comprehensive consideration of the preparation process of the sub-pixel and aperture ratio requirements of the sub-pixel, it may be set that 0<X3≤X4/2, guaranteeing a well consideration of both the preparation process and the aperture ratio and improving the comprehensive performance of the display panel.

In an embodiment, 5%≤X3/X4<40%. That is, a ratio of the length of the third sub-segment tc13 to the length of the fourth edge zt3 is between 5% and 40%, thereby well considering both the preparation process and the pixel aperture ratio. For example, if X3/X4<5%, the length of the third sub-segment tc13 in the first direction (the Y direction as shown) will be small, sharply increasing the process difficulty of the third edge, requiring a mask pattern in a photomask to be extremely accurate, making the process difficult, and easily causing the final product specification not to meet requirements. If X3/X4>40%, the aperture ratio of the sub-pixel including the protrusion portion will be relatively small, which affects the display brightness of the sub-pixel, or a relatively large drive signal will be required in the case of the same display brightness, which increases power consumption. Therefore, the reasonable arrangement in which 5%≤X3/X4≤40% guarantees a well consideration of both the aperture ratio of the sub-pixel and the process difficulty and improves the comprehensive performance of the display panel.

Exemplarily, 5%<X3/X4≤40%. The ratio of X3 to X4 may be 5%, 7%, 10%, 12.5%, 15.7%, 18%, 22.3%, 24.6%, 27%, 28.6%, 30%, 32.5%, 35%, 37%, 38.6%, or 40%. The specific ratio of X3 to X4 is not described in embodiments of the present application. The ratio of X3 to X4 is described in detail hereinafter in connection with the light-emitting color of a sub-pixel including a protrusion portion.

In an optional embodiment, a first sub-pixel includes a protrusion portion. The first sub-pixel includes a red sub-pixel. 20%≤X3/X4≤30%. That is, for the red sub-pixel including the protrusion portion, the ratio of the length of the third sub-segment tc13 to the length of the fourth edge zt3 is between 20% and 30%. With this arrangement, on the basis of considering the luminescence efficiency of the red sub-pixel, it guarantees the aperture ratio of the red sub-pixel including the protrusion portion tc and guarantees that the preparation process of the red sub-pixel is simple.

In an embodiment, with a comprehensive consideration of the luminescence efficiency of the red sub-pixel, the aperture ratio of the red sub-pixel and the preparation process of the red sub-pixel, it may be set after a large number of experimental verifications that in the red sub-pixel including the protrusion portion, X3/X4=26%. Such an arrangement, combined with the luminescence efficiency of the red sub-pixel and the aperture ratio of the red sub-pixel including the protrusion portion, can guarantee that the display brightness of the red sub-pixel including the protrusion portion meets display requirements and that the display brightness of the red sub-pixel is not affected by the inclusion of the protrusion portion. Moreover, such an arrangement can also guarantee that the preparation process of the red sub-pixel including the protrusion portion is relatively simple, the preparation efficiency is good, and that the comprehensive consideration effect of the red sub-pixel including the protrusion portion achieves optimal performance.

In another optional embodiment, a second sub-pixel includes a protrusion portion. The second sub-pixel includes a blue sub-pixel. 20%≤X3/X4≤30%. That is, for the blue sub-pixel including the protrusion portion, the ratio of the length of the third sub-segment tc13 to the length of the fourth edge zt3 is between 20% and 30%. With this arrangement, on the basis of considering the luminescence efficiency of the blue sub-pixel, it guarantees the aperture ratio of the blue sub-pixel including the protrusion portion tc and guarantees that the preparation process of the blue sub-pixel is simple.

In an embodiment, with a comprehensive consideration of the luminescence efficiency of the blue sub-pixel, the aperture ratio of the blue sub-pixel and the preparation process of the blue sub-pixel, it may be set after a large number of experimental verifications that in the blue sub-pixel including the protrusion portion, X3/X4=27%. Such an arrangement, combined with the luminescence efficiency of the blue sub-pixel and the aperture ratio of the blue sub-pixel including the protrusion portion, can guarantee that the display brightness of the blue sub-pixel including the protrusion portion meets display requirements and that the display brightness of the blue sub-pixel is not affected by the inclusion of the protrusion portion. Moreover, such an arrangement can also guarantee that the preparation process of the blue sub-pixel including the protrusion portion is relatively simple, guarantee good preparation efficiency, and guarantee that the comprehensive consideration effect of the blue sub-pixel including the protrusion portion achieves optimal performance.

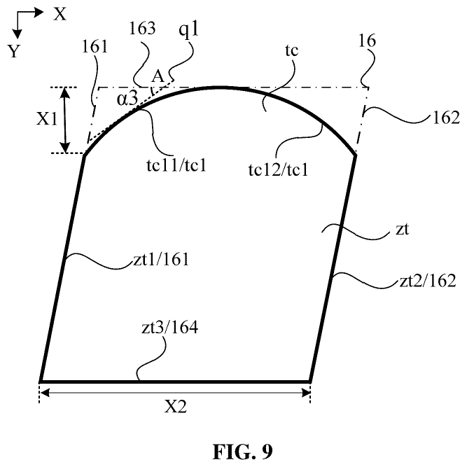

On the basis of the preceding embodiments, FIG. 9 is a sixth structural diagram of a sub-pixel including a protrusion portion according to an embodiment of the present application. Referring to FIGS. 3 and 5 to 9, the virtual shape 16 of the sub-pixel including the protrusion portion tc constitutes the first virtual parallelogram. The first virtual parallelogram has the first virtual edge 161, the second virtual edge 162, and the third virtual edge 163. The third virtual edge 163 is connected to the same side of the first virtual edge 161 and the second virtual edge 162. The first virtual edge 161 partially coincides with the first edge zt1. The second virtual edge 162 partially coincides with the second edge zt2. The end point on one side of the first sub-segment tc11 close to the second sub-segment tc12 and the end point on one side of the second sub-segment tc12 close to the first sub-segment tc11 are each located on the third virtual edge 163.

For example, referring to FIGS. 3 and 5 to 9, the virtual shape of the sub-pixel including the protrusion portion is the first virtual parallelogram. For example, the first virtual parallelogram may be a virtual rectangle shown in FIGS. 3 and 5 to 8 or a virtual parallelogram shown in FIG. 9. The virtual shape in embodiments of the present application may be understood as a circumscribed shape corresponding to the sub-pixel including the protrusion portion. The circumscribed shape includes two groups of opposite edges parallel to each other. The position of the protrusion portion farthest from the main portion is located on the circumscribed shape. As shown, further, the first virtual parallelogram has the first virtual edge 161, the second virtual edge 162, the third virtual edge 163, and a fourth virtual edge 164. The third virtual edge 163 is connected to the same side of the first virtual edge 161 and the second virtual edge 162. The fourth virtual edge 164 is connected to the same side of the first virtual edge 161 and the second virtual edge 162. The third virtual edge 163 and the fourth virtual edge 164 are parallel and opposite to each other. Moreover, the first virtual edge 161 partially coincides with the first edge zt1. The second virtual edge 162 partially coincides with the second edge zt2.

The position of the protrusion portion tc farthest from the main portion zt is located on the third virtual edge 163. For example, the end point on one side of the first sub-segment tc11 close to the second sub-segment tc12 and the end point on one side of the second sub-segment tc12 close to the first sub-segment tc11 are each located on the third virtual edge 163. The fourth virtual edge 164 at least partially coincides with the fourth edge zt3 of the main portion zt. The arrangement in which the end point on one side of the first sub-segment tc11 close to the second sub-segment tc12 and the end point on one side of the second sub-segment tc12 close to the first sub-segment tc11 are each located on the third virtual edge 163 can guarantee that the distance between the protrusion portion tc and the virtual shape 16 is relatively small, guarantee the aperture ratio of the sub-pixel including the protrusion portion tc, and guarantee the display effect of the sub-pixel including the protrusion portion tc.

Optionally, with continued reference to FIG. 3, the first sub-segment tc11 is connected to the second sub-segment tc12. A connection point between the first sub-segment tc11 and the second sub-segment tc12 (the end point b on one side of the first sub-segment tc11 close to the second sub-segment tc12 or the end point c on one side of the second sub-segment tc12 close to the first sub-segment tc11) is located on the third virtual edge 163. The third virtual edge 163 is tangent to the third edge tc1 at the connection point.

As shown in FIG. 3, the first sub-segment tc11 is directly connected to the second sub-segment tc12, and the shape of the first sub-segment tc11 and the shape of the second sub-segment tc12 may be each an arc protruding towards one side away from the main portion zt, guaranteeing a relatively small interval between the third edge tc1 and the third virtual edge 163 and guaranteeing a relatively large aperture ratio of the sub-pixel including the protrusion portion. In an embodiment, the third virtual edge 163 is tangent to the third edge tc1 at the connection point of the first sub-segment tc11 and the second sub-segment tc12. That is, the minimum distance between the third edge tc1 and the third virtual edge 163 is zero, guaranteeing a relatively large aperture ratio of the sub-pixel including the protrusion portion and improving the display effect of the sub-pixel.

Optionally, with continued reference to FIGS. 3 and 9, a first tangent line q1 of any point on the first sub-segment tc11 intersects the third virtual edge 163 at a first intersection point A. An included angle between the third virtual edge 163 located on one side of the first intersection point A close to the first virtual edge 161 and the first tangent line is α3. 0°≤α3<90°. A second tangent line q2 of any point on the second sub-segment tc12 intersects the third virtual edge 163 at a second intersection point B. An included angle between the third virtual edge 163 located on one side of the second intersection point B close to the second virtual edge 162 and the second tangent line is α4. 0°≤α4<90°.

For example, referring to FIGS. 3 and 9, the included angle between the third virtual edge 163 located on one side of the first intersection point A facing the first virtual edge 161 and the first tangent line q1 reflects the edge shape of the first sub-segment tc11. The larger the average value of multiple included angles between corresponding tangents at different positions of the first sub-segment tc11 and the third virtual edge 163, the larger the average slope of the first sub-segment tc11. With this arrangement, the smaller the area of a region enclosed by the first sub-segment tc11, the first virtual edge 161, and the third virtual edge 163, the larger the area corresponding to the protrusion portion tc, helping improve the aperture ratio of the sub-pixel including the protrusion portion, but shortening the distance between the sub-pixel including the protrusion portion and an adjacent sub-pixel and possibly increasing the risk of the leakage current. Similarly, the included angle between the third virtual edge 163 located on one side of the second intersection point B facing the second virtual edge 162 and the second tangent line q2 reflects the edge shape of the second sub-segment tc12. The larger the average value of multiple included angles between corresponding tangents at different positions of the second sub-segment tc 12 and the third virtual edge 163, the larger the average slope of the second sub-segment tc12. With this arrangement, the smaller the area of a region enclosed by the second sub-segment tc12, the second virtual edge 162, and the third virtual edge 163, the larger the area corresponding to the protrusion portion tc, helping improve the aperture ratio of the sub-pixel including the protrusion portion, but shortening the distance between the sub-pixel including the protrusion portion and an adjacent sub-pixel and possibly increasing the risk of the leakage current. Therefore, the reasonable arrangement of the value of α3 and the value of α4 can well consider both the aperture ratio and the effect of reducing the leakage current. For example, it may be set that 0°≤α3<90° and that 0°≤α4<90°. In an embodiment, it may be set that 10°≤α3<80° and that 10°≤α4<80°. Alternatively, it may be further set that 20°≤α3<70° and that 20°≤α4<70°.

It is to be noted that the value of α3 may be the same as or different from the value of α4, which is not limited in embodiments of the present application.

On the basis of the preceding embodiments, with continued reference to FIGS. 5 and 8, the virtual shape 16 of the sub-pixel including the protrusion portion constitutes the first virtual parallelogram. The first virtual parallelogram includes a first virtual axis m1.

The center of the first virtual parallelogram is located on the first virtual axis m1. The first virtual axis m1 intersects the third edge tc1. The first sub-segment tc11 and the second sub-segment tc12 are symmetric about the first virtual axis m1.

Referring to FIGS. 5 and 8, the virtual shape 16 includes the first virtual axis m1. The extension direction of the first virtual axis m1 may be parallel to or approximately parallel to the extension direction of the first virtual edge 161 and the extension direction of the second virtual edge 162. Being approximately parallel may be understood as that the included angle between the first virtual edge 161 and the second virtual edge 162 is smaller than a preset angle, for example, 5° or 10°. Moreover, the first virtual axis m1 intersects the third edge tc1. The first sub-segment tc11 and the second sub-segment tc12 are symmetric about the first virtual axis m1. Such an arrangement guarantees that shapes of the first sub-segment tc11 and the second sub-segment tc12 located on two sides of the first virtual axis m1 are entirely the same. That is, protrusion portions located on two sides of the first virtual axis m1 have the same area, guaranteeing that the sub-pixel including the protrusion portion tc is an axisymmetric structure or an approximate axisymmetric structure, guaranteeing that the display effect of the sub-pixel including the protrusion portion tc is relatively balanced, avoiding obvious display difference between different regions caused by great difference in shape between different regions of the sub-pixel, avoiding square color deviation, and guaranteeing the display effect of the sub-pixel and the display panel.

With continued reference to FIG. 5, the third edge tc1 further includes the third sub-segment tc13. The third sub-segment tc13 is connected to the first sub-segment tc11 and the second sub-segment tc12. The third sub-segment tc13 intersects the first virtual axis m1. A midpoint of the third sub-segment tc13 is located on the first virtual axis m1. That is, third sub-segments tc13 located on two sides of the first virtual axis m1 have the same length, guaranteeing that the sub-pixel including the protrusion portion tc is an axisymmetric structure or an approximate axisymmetric structure, guaranteeing that the display effect of the sub-pixel including the protrusion portion the is relatively balanced, avoiding obvious display difference between different regions caused by great difference in shape between different regions of the sub-pixel, avoiding square color deviation, and guaranteeing the display effect of the sub-pixel and the display panel.

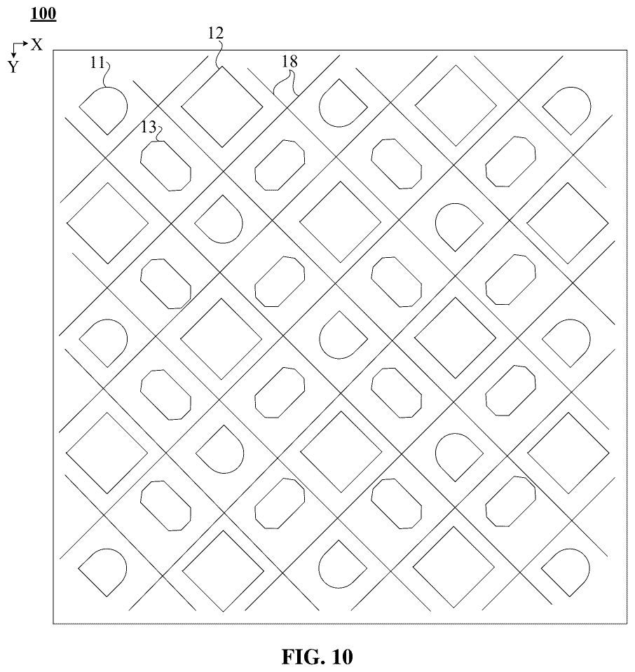

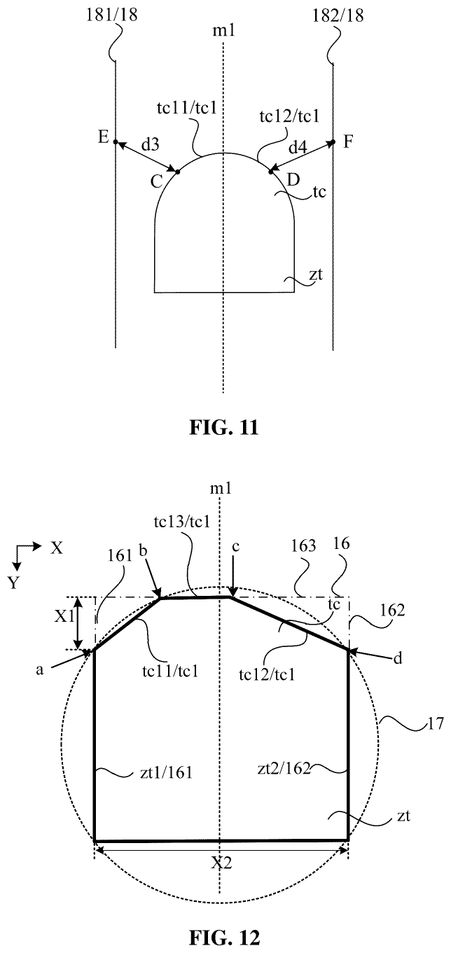

On the basis of the preceding embodiments, FIG. 10 is a second structural diagram of a display panel according to an embodiment of the present application. FIG. 11 is a diagram illustrating a relative positional relationship between a sub-pixel including a protrusion portion and a touch grid line according to an embodiment of the present application. Referring to FIGS. 10 and 11, the display panel further includes a touch electrode 18 located on the light emission side of the sub-pixel. The touch electrode 18 includes a first touch grid line 181 and a second touch grid line 182. The extension direction of the first touch grid line 181 and the extension direction of the second touch grid line 182 are each the same as the extension direction of the first virtual axis m1. The first sub-segment tc11 and the first touch grid line 181 are located on the same side of the first virtual axis m1. The second sub-segment tc12 and the second touch grid line 182 are located on the same side of the first virtual axis m1. The first sub-segment tc11 includes a first point C. The second sub-segment tc12 includes a second point D. The first point C and the second point D are symmetric about the first virtual axis m1. The first touch grid line 181 includes a third point E. The second touch grid line 182 includes a fourth point F. The third point E and the fourth point F are symmetric about the first virtual axis m1. The distance between the first point C and the third point E is a first distance d3. The distance between the second point D and the fourth point F is a second distance d4. The difference between the first distance d3 and the second distance d4 is within a preset range.

As shown in FIG. 10, the display panel provided in embodiments of the present application may be a touch display panel which may include a touch structure located on the light emission side of the display panel. The touch structure may be a self-capacitive touch structure or a mutual capacitive touch structure. A self-capacitive touch structure is usually composed of multiple touch electrode blocks (not shown) arranged in an array. Each touch electrode block may form self-capacitance with the ground. The external capacitance formed by finger contact may change the self-capacitance formed between each touch electrode block and the ground so that the specific position of a touch point can be detected. A mutual capacitive touch structure is usually composed of a touch sensing electrode and a touch driving electrode (not shown). Mutual capacitance is formed at an intersection position of the touch driving electrode and the touch sensing electrode. The external capacitance formed by finger contact may change the mutual capacitance between the two electrodes so that the specific position of a touch point can be detected. In an embodiment, the touch electrode 18 may be a grid touch electrode. The sub-pixel may be disposed in a mesh corresponding to the grid touch electrode 18 so as to guarantee that touch grid lines in the touch electrode 18 do not greatly affect the light emission of the sub-pixel.

In an embodiment, referring to FIGS. 10 and 11, the touch electrode 18 includes the first touch grid line 181 and the second touch grid line 182. The first touch grid line 181 and the first sub-segment tc11 are located on the same side of the first virtual axis m1.

The second touch grid line 182 and the second sub-segment tc12 are located on the same side of the first virtual axis m1. The difference between the distance d3 between the first point C in the first sub-segment tc11 and the third point E in the first touch grid line 181 and the distance d4 between the second point D in the second sub-segment tc12 and the fourth point F in the second touch grid line 182 is within the preset range. That is, the distance d3 between the first point C in the first sub-segment tc11 and the third point E in the first touch grid line 181 is the same as or similar to the distance d4 between the second point D in the second sub-segment tc12 and the fourth point F in the second touch grid line 182. With this arrangement, the effect of the first touch grid line 181 on the light emission of the sub-pixel including the protrusion portion tc is the same as or similar to the effect of the second touch grid line 182 on the light emission of the sub-pixel including the protrusion portion tc, guaranteeing that the touch electrode located on the light emission side of the sub-pixel has the same or similar effect on the light emission of the sub-pixel from different orientations or different angles and guaranteeing the display balance of the display panel.

In an embodiment, as shown in FIG. 10, for the sub-pixel including the protrusion portion and a sub-pixel including no protrusion portion, for example, a sub-pixel 11 including the protrusion portion and a sub-pixel 12 including no protrusion portion as shown in FIG. 10, the distance between the sub-pixel including the protrusion portion and a touch grid line of the touch electrode 18 is larger, helping reduce the brightness decay of the light with a large viewing angle in the sub-pixel including the protrusion portion, guaranteeing the reduction of color deviation with a large viewing angle of the sub-pixel including the protrusion portion, guaranteeing the display effect of the sub-pixel including the protrusion portion, and thereby guaranteeing the display effect of the entire display panel.

It is to be noted that in embodiments of the present application, only by way of example, a touch grid line in the touch electrode serves as a signal line on the light emission side of the sub-pixel. It is to be understood that the display panel provided in embodiments of the present application may also include other signal lines located on the light emission side of the sub-pixel. The arrangement manner of other signal lines may be the same as the arrangement manner between sub-pixels to guarantee that other signal lines have the same or similar effect on the light emission of the sub-pixels from different orientations or different angles, thereby guaranteeing the display balance of the display panel.

It is to be further noted that the first point C is any point in the first sub-segment tc11 and the second point D is any point in the second sub-segment tc12 as long as the first point C and the second point D are symmetric about the first virtual axis m1. The third point E is any point in the first touch grid line 181 and the fourth point Fis any point in the second touch grid line 182 as long as the third point E and the fourth point Fare symmetric about the first virtual axis m1.

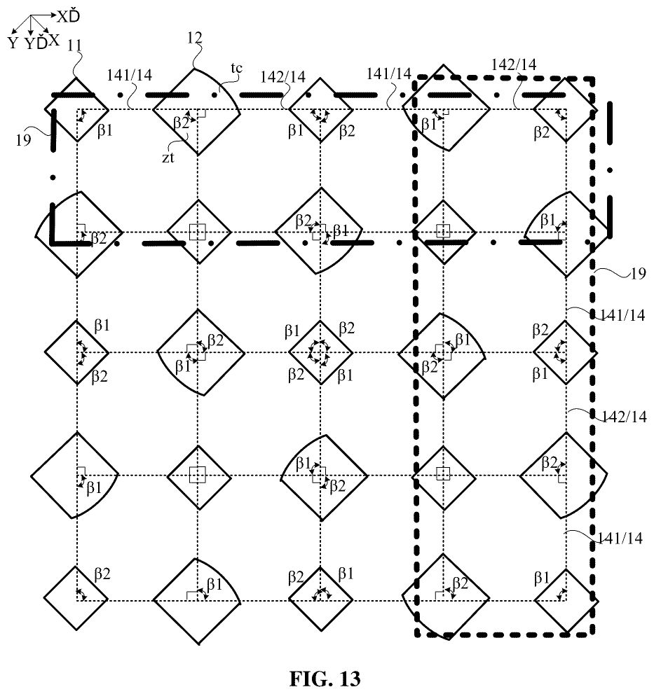

Optionally, FIG. 12 is a seventh structural diagram of a sub-pixel including a protrusion portion according to an embodiment of the present application. As shown in FIG. 12, the virtual shape 16 of the sub-pixel including the protrusion portion tc constitutes a first virtual parallelogram. The first virtual parallelogram includes a first virtual axis m1. The center of the first virtual parallelogram is located on the first virtual axis m1. The first virtual axis m1 intersects the third edge tc1. The first sub-segment tc11 and the second sub-segment tc12 are asymmetric about the first virtual axis m1.

Referring to FIGS. 12, the virtual shape 16 includes the first virtual axis m1. The extension direction of the first virtual axis m1 may be parallel to or approximately parallel to the extension direction of a first virtual edge 161 and the extension direction of a second virtual edge 162. Being approximately parallel may be understood as that the included angle between the first virtual edge 161 and the second virtual edge 162 is smaller than a preset angle, for example, 5° or 10°. Moreover, the first virtual axis m1 intersects the third edge tc1. In an embodiment, the first sub-segment tc11 and the second sub-segment tc12 are asymmetric about the first virtual axis m1, reducing the limitation of the arrangement manner of the first sub-segment tc11 and the second sub-segment tc12, guaranteeing a highly-free arrangement of the first sub-segment tc11 and the second sub-segment tc12, and improving the arrangement flexibility of the first sub-segment tc11 and the second sub-segment tc12. Moreover, combining the orientation of the protrusion portion tc and the positional relationship between the sub-pixel including the protrusion portion and an adjacent sub-pixel, the arrangement in which the first sub-segment tc11 and the second sub-segment tc12 are asymmetric about the first virtual axis m1 can also increase the minimum distance between the sub-pixel including the protrusion portion and an adjacent sub-pixel, shorten the transmission path of the leakage current, reduce the leakage current between the first sub-pixel and the second sub-pixel, avoid the mutual crosstalk of display signals between the first sub-pixel and the second sub-pixel, avoid the undesired light emission between two adjacent sub-pixels, and improve the display effect of the display panel.

In an embodiment, with continued reference to FIG. 12, the third edge tc1 further includes a third sub-segment tc13. The third sub-segment tc13 is connected to the first sub-segment tc11 and the second sub-segment tc12. The third sub-segment tc13 intersects the first virtual axis m1. A midpoint of the third sub-segment tc13 is not located on the first virtual axis m1. That is, third sub-segments tc13 on two sides of the first virtual axis m1 have different lengths, guaranteeing that the sub-pixel including the protrusion portion tc is a non-axisymmetric structure. With this arrangement, the arrangement of the shape of the sub-pixel including the protrusion portion is highly free. The shape of the protrusion portion can be flexibly adjusted according to actual requirements. For example, the relative positional relationship between the third sub-segment and the first virtual edge is adjusted according to the relative positional relationship between the first sub-pixel and the second sub-pixel. Therefore, the transmission path of the leakage current is prolonged, and the display crosstalk and undesired light emission of sub-pixels caused by the leakage current are alleviated.

In conclusion, the preceding embodiments describe the sub-pixel including the protrusion portion from multiple perspectives, such as the shape of the sub-pixel including the protrusion portion, the relative positional relationship with the virtual circle, and the relative positional relationship with the virtual shape. It is to be understood that the sub-pixel including the protrusion portion provided in embodiments of the present application can well consider both the aperture ratio of the sub-pixel and the transmission path of the leakage current between the sub-pixel and another sub-pixel, guaranteeing the aperture ratio of the sub-pixel including the protrusion portion, reducing the leakage current between different sub-pixels, guaranteeing the display brightness of sub-pixels, alleviating the crosstalk and leakage current between sub-pixels, and improving the overall display effect of the display panel.

Optionally, FIG. 13 is a third structural diagram of a display panel according to an embodiment of the present application. Referring to FIGS. 3 and 13, the first virtual quadrangle 14 includes a right trapezoid.

For example, FIG. 3 illustrates an example in which a first sub-pixel is a sub-pixel including a protrusion portion. As shown in FIG. 3, the first sub-pixel 11 includes the protrusion portion. Therefore, the shape of the first sub-pixel 11 changes compared with the related art. With this arrangement, the first virtual quadrangle 14 formed by connecting the center of each first sub-pixel 11 and the center of each second sub-pixel 12 is adjusted from a rectangle in the related art to a right trapezoid. The adjustment of the shape of the first sub-pixel 11 can guarantee a well consideration of both the display aperture ratio and a reduction of the leakage current. Moreover, the shape of a right trapezoid of the first virtual quadrangle 14 has little change compared with the shape of a rectangle. The shape of the first virtual quadrangle 14 is also a relatively regular figure, guaranteeing regular display effect when the display panel performs display. That is, the adjustment of the shape of the first sub-pixel 11 can guarantee that display effect is not affected. FIG. 13 illustrates an example in which a second sub-pixel is a sub-pixel including a protrusion portion. As shown in FIG. 13, the first sub-pixel 12 includes the protrusion portion. Therefore, the shape of the second sub-pixel 11 changes compared with the related art. With this arrangement, the first virtual quadrangle 14 formed by connecting the center of each first sub-pixel 11 and the center of each second sub-pixel 12 is adjusted from a rectangle in the related art to a right trapezoid. The adjustment of the shape of the second sub-pixel 12 can guarantee a well consideration of both the display aperture ratio and a reduction of the leakage current. Moreover, the shape of a right trapezoid of the first virtual quadrangle 14 has little change compared with the shape of a rectangle. The shape of the first virtual quadrangle 14 is also a relatively regular figure, guaranteeing regular display effect when the display panel performs display. That is, the adjustment of the shape of the second sub-pixel 12 can guarantee that display effect is not affected.

With continued reference to FIGS. 3 and 13, in the same first virtual quadrangle 14, the angle difference Δβ between a non-right angle and a right angle satisfies that |Δβ|≤5°. For example, the right trapezoid includes two right angles and two non-right angles. The two non-right angles may be a first non-right angle β1 and a second non-right angle β2. The first non-right angle β1 may be an acute angle. The second non-right angle β2 may be an obtuse angle. It is set that the angle difference Δβ between a non-right angle and a right angle satisfies that |Δβ|≤5°. That is, the angle difference between the first non-right angle β1 and a right angle is within 5°, and the angle difference between the second non-right angle 2 and a right angle is also within 5°. With this arrangement, the right trapezoid formed by the first virtual quadrangle 14 does not differ much from a rectangle. The shape of the first virtual quadrangle 14 is also a relatively regular figure, guaranteeing regular display effect when the display panel performs display. That is, the adjustment of the shape of the sub-pixel including the protrusion portion can guarantee that display effect is not affected.

In an embodiment, the angle difference Δβ between a non-right angle and a right angle satisfies that |Δβ|≤1°. That is, the angle difference between the first non-right angle β1 and a right angle is within 1°, and the angle difference between the second non-right angle β2 and a right angle is also within 1°. With this arrangement, the right trapezoid formed by the first virtual quadrangle 14 has a particularly small difference from a rectangle. The shape of the first virtual quadrangle 14 is also a basically regular figure, guaranteeing regular display effect when the display panel performs display. That is, the adjustment of the shape of the sub-pixel including the protrusion portion can guarantee that display effect is not affected.

On the basis of the preceding embodiments, in an optional embodiment, a first sub-pixel 11 includes a main portion zt and a protrusion portion tc. The first sub-pixel 11 includes a red sub-pixel. In the first virtual quadrangle 14, the first non-right angle β1 satisfies that β1=89.34°, and the second non-right angle β2 satisfies that β2=90.66° That is, when the sub-pixel including the protrusion portion tc is a red sub-pixel, considering the display aperture ratio of the red sub-pixel, the luminescence efficiency of the red sub-pixel, the transmission path of the leakage current between the red sub-pixel and another sub-pixel, and the overall display regularity of the red sub-pixel, it may be set that the first non-right angle β1 in the red sub-pixel satisfies that β1=89.34° and the second non-right angle β 2 satisfies that 2=90.66, thereby guaranteeing the optimal display performance of the red sub-pixel.

On the basis of the preceding embodiments, in another optional embodiment, a second sub-pixel 12 includes a main portion zt and a protrusion portion tc. The second sub-pixel 12 includes a blue sub-pixel. In the first virtual quadrangle 14, the first non-right angle β1 satisfies that β1=89.31°, and the second non-right angle β2 satisfies that β2=90.69°; alternatively, the first non-right angle β1 satisfies that β1=89.32°, and the second non-right angle β2 satisfies that β2=90.68°. That is, when the sub-pixel including the protrusion portion the is a blue sub-pixel, considering the display aperture ratio of the blue sub-pixel, the luminescence efficiency of the blue sub-pixel, the transmission path of the leakage current between the blue sub-pixel and another sub-pixel, and the overall display regularity of the blue ed sub-pixel, it may be set that the first non-right angle β1 in the blue sub-pixel satisfies that β1=89.31° and the second non-right angle β2 satisfies that β2=90.69° or may be set that the first non-right angle β1 in the blue sub-pixel satisfies that β1=89.32° and the second non-right angle β2 satisfies that β2=90.68°, thereby guaranteeing the optimal display performance of the blue sub-pixel.

Optionally, with continued reference to FIG. 13, the first sub-pixels 11 and the second sub-pixels 12 are arranged alternately in a third direction X′ and a fourth direction Y′. The third direction X′ intersects the fourth direction Y′. The display panel further includes a plurality of repetition units 19. A repetition unit 19 includes four first virtual quadrangles 14 arranged in the third direction X′ and/or the fourth direction Y′. The four first virtual quadrangles 14 in the repetition unit 19 include two first-type virtual quadrangles 141 and two second-type virtual quadrangles 142. The first-type virtual quadrangles 141 and the second-type virtual quadrangles 142 are arranged alternately in sequence in the third direction X′ and/or the fourth direction Y′. A first-type virtual quadrangle 141 and a two second-type virtual quadrangle 142 include a common edge. Among four interior angles in a first-type virtual quadrangle 141, two interior angles arranged in the third direction X′ are non-right angles, and two interior angles arranged in the third direction X′ are right angles. Among four interior angles in a two second-type virtual quadrangle 142, two interior angles arranged in the fourth direction Y′ are non-right angles, and two interior angles arranged in the fourth direction Y′ are right angles.

As shown in FIG. 13, the display panel includes the plurality of repetition units 19 which may be understood as structures that occur repeatedly in the display panel. Each repetition unit 19 includes four first virtual quadrangles 14 which may be arranged in the third direction X′ or the fourth direction Y′. FIG. 13 illustrates the case where four first virtual quadrangles 14 in one repetition unit 19 included in the display panel are arranged in the third direction X′ and the case where four first virtual quadrangles 14 in one repetition unit 19 included in the display panel are arranged in the fourth direction Y′. In an embodiment, four first virtual quadrangles 14 in each repetition unit 19 include two first-type virtual quadrangles 141 and two second-type virtual quadrangles 142. Two non-right angles in a first-type virtual quadrangle 141 are arranged in the third direction X′. Two non-right angles in a second-type virtual quadrangle 142 are arranged in the fourth direction Y′. That is, the arrangement manner of non-right angles in a first-type virtual quadrangle 141 differs from the arrangement manner of non-right angles in a second-type virtual quadrangle 142. Moreover, the first-type virtual quadrangles 141 and the second-type virtual quadrangles 142 are arranged alternately in sequence in the third direction X′ and/or the fourth direction Y′. Such an arrangement can avoid the case where non-right angles in a first-type virtual quadrangle 141 are arranged in the third direction X′ and/or the fourth direction Y′, guaranteeing that non-right angles in a first-type virtual quadrangle 141 are evenly distributed in the third direction X′ and/or the fourth direction Y′, guaranteeing good display uniformity, avoiding the case where a region where non-right angles are arranged intensively has a relatively large display difference from another region due to the intensive arrangement of non-right angles, and guaranteeing that the overall display balance of the display panel is good.

In an embodiment, with continued reference to FIG. 13, in the same repetition unit 19, first non-right angles β1 and second non-right angles β2 are arranged alternately in sequence in the third direction X′ and/or the fourth direction Y′. That is, acute angles and obtuse angles are arranged alternately in sequence in the third direction X′ and/or the fourth direction Y′, further guaranteeing good display uniformity, avoiding the case where a region where acute angles or obtuse angles are arranged intensively has a relatively large display difference from another region due to the intensive arrangement of acute angles or obtuse angles, and guaranteeing that the overall display balance of the display panel is good.

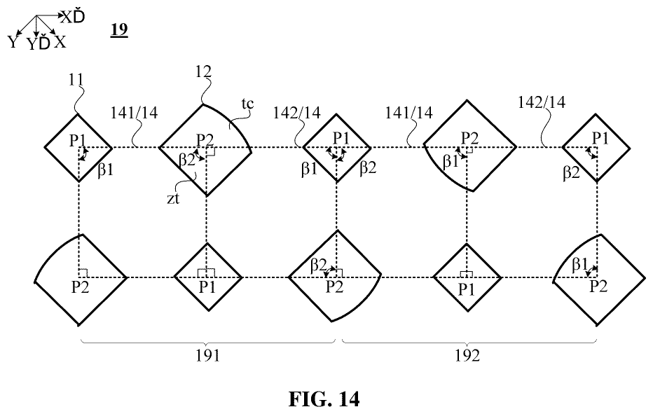

On the basis of the preceding embodiments, FIG. 14 is a structural diagram of a repetition unit according to an embodiment of the present application. With continued reference to FIGS. 13 and 14, the repetition unit 19 includes a first sub-unit 191 and a second sub-unit 192 that are arranged in the third direction X′ and/or the fourth direction Y′. The first sub-unit 191 includes one first-type virtual quadrangle 141 and one second-type virtual quadrangle 142. The second sub-unit 192 includes one first-type virtual quadrangle 141 and one second-type virtual quadrangle 142. Among four interior angles corresponding to a common edge of the first-type virtual quadrangle 141 in the first sub-unit 191 and the second-type virtual quadrangle 142 in the first sub-unit 191, three interior angles are right angles, and one interior angle is a non-right angle. Among four interior angles corresponding to a common edge of the first-type virtual quadrangle 141 in the second sub-unit 192 and the second-type virtual quadrangle 142 in the second sub-unit 192, three interior angles are right angles, and one interior angle is a non-right angle.

Among four interior angles corresponding to a common edge of the first sub-unit 191 and the second sub-unit 192, one interior angle is a right angle, and three interior angles are non-right angles.

As shown in FIGS. 13 and 14, each repetition unit 19 includes a first sub-unit 191 and a second sub-unit 192 each of which includes one first-type virtual quadrangle 141 and one second-type virtual quadrangle 142. Four interior angles corresponding to a common edge of two first virtual quadrangles 14 in the same sub-unit include three right angles and one non-right angle. Four interior angles corresponding to a common edge of the first sub-unit 191 and the second sub-unit 192 include three non-right angles and one right angle. Such an arrangement manner of right angles and non-right angles in each repetition unit 19 guarantees that each first virtual quadrangle 14 is a right trapezoid and that right angles and non-right angles are staggered, avoiding the case where a region where non-right angles are arranged intensively has a relatively large display difference from another region due to the intensive arrangement of non-right angles, and guaranteeing that the overall display balance of the display panel is good.

With continued reference to FIGS. 13 and 14, in the first-type virtual quadrangle 141 in the first sub-unit 191 and the second-type virtual quadrangle 142 in the first sub-unit 191, an interior angle where a first vertex P1 is located is an acute angle, and an interior angle where a second vertex P2 is located is an obtuse angle. In the first-type virtual quadrangle 141 in the second sub-unit 192 and the second-type virtual quadrangle 142 in the second sub-unit 192, an interior angle where a first vertex P1 is located is an obtuse angle, and an interior angle where a second vertex P2 is located is an acute angle.

As shown in FIG. 14, in the first sub-unit 191, interior angles corresponding to first vertices P1 include an acute angle and a right angle, and interior angles corresponding to second vertices P2 include an obtuse angle and a right angle. In the second sub-unit 192, interior angles corresponding to first vertices P1 include an obtuse angle and a right angle, and interior angles corresponding to second vertices P2 include an acute angle and a right angle. That is, in the first sub-unit 191, an interior angle where a first vertex P1 is located is an acute angle, and an interior angle where a second vertex P2 is located is an obtuse angle. In the second sub-unit 192, an interior angle where a first vertex P1 is located is an obtuse angle, and an interior angle where a second vertex P2 is located is an acute angle. That is, an interior angle corresponding to a first vertex P1 in the first sub-unit 191 differs from an interior angle corresponding to a first vertex P1 in the second sub-unit 192, and an interior angle corresponding to a second vertex P2 in the first sub-unit 191 differs from an interior angle corresponding to a second vertex P2 in the second sub-unit 192. Such a differential arrangement guarantees that acute angles and obtuse angles in right trapezoids are evenly distributed in the third direction X′ and/or the fourth direction Y′, avoiding the case where a region where acute angles or obtuse angles are arranged intensively has a relatively large display difference from another region due to the intensive arrangement of acute angles or obtuse angles, and guaranteeing that the overall display balance of the display panel is good.

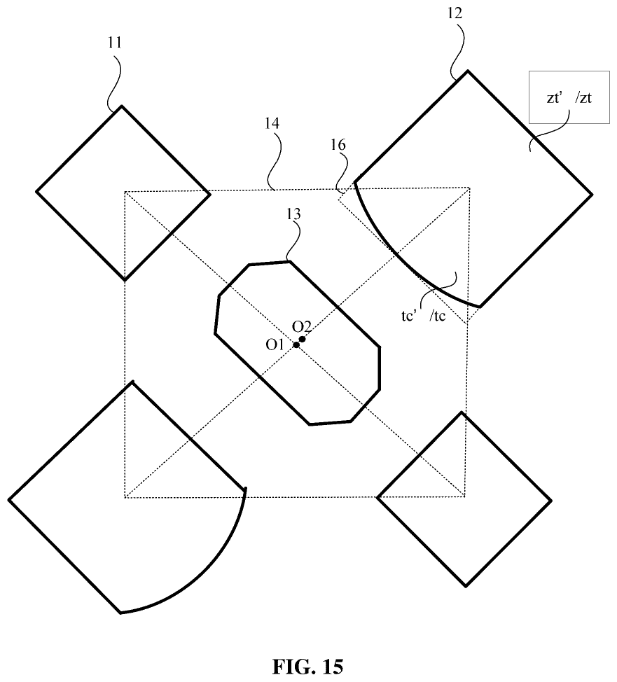

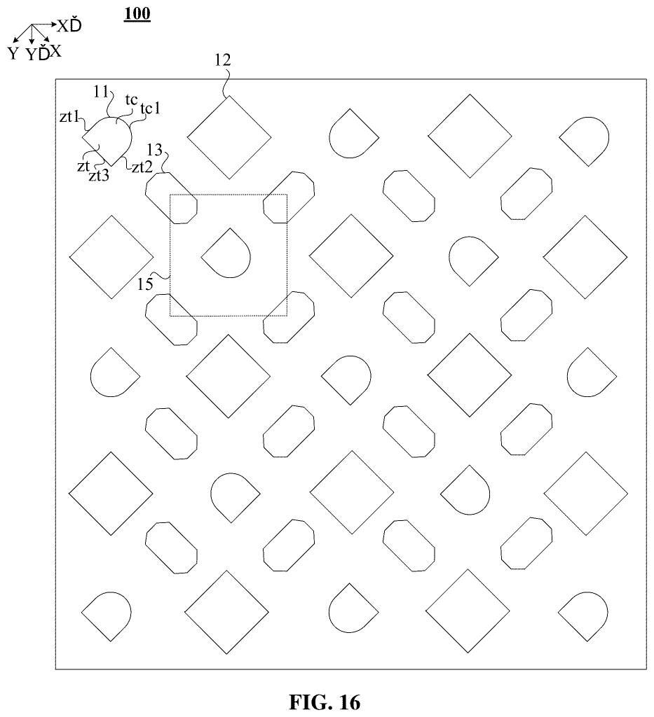

On the basis of the preceding embodiments, FIG. 15 is a first structural diagram of a first virtual quadrangle according to an embodiment of the present application. As shown in FIG. 15, the center O1 of the first virtual quadrangle 14 does not coincide with the center O2 of the third sub-pixel 13 located inside the first virtual quadrangle 14. In the related art, when the shape of a first sub-pixel or the shape of a second sub-pixel does not change, the center of the first virtual quadrangle coincides with the center of the third sub-pixel located inside the first virtual quadrangle. Since the shape of a first sub-pixel or the shape of a second sub-pixel changes, for example, since a second sub-pixel 12 includes a main portion zt and a protrusion portion tc and the shape of the second sub-pixel 12 changes as shown in FIG. 14, the center position of the second sub-pixel 12 changes compared with the case where the shape of the second sub-pixel 12 does not change. Accordingly, the center O1 of the first virtual quadrangle 14 does not coincide with the center O2 of the third sub-pixel 13 located inside the first virtual quadrangle 14. In this case, the position of the third sub-pixel 13 may be adjusted reasonably according to the change of the shape of the sub-pixel including the protrusion portion (for example, the second sub-pixel 12) so as to guarantee that distances between the third sub-pixel 13 and two sub-pixels (for example, second sub-pixels 12) arranged around the third sub-pixel 13 and each including a protrusion portion are the same or similar, guaranteeing the mixing effect between sub-pixels of different colors and suppressing the effect of leakage currents to be the same or similar. It is to be noted that the center of the first virtual quadrangle may be understood as the geometric center of the first virtual quadrangle, for example, an intersection point of two diagonals. The center of the third sub-pixel may be understood as the geometric center of the third sub-pixel, for example, an intersection point of perpendicular bisectors of two edges connected to each other.

For example, as shown in FIG. 15, among two first sub-pixels 11 corresponding to the same first virtual quadrangle 14 or two second sub-pixels 12 corresponding to the same first virtual quadrangle 14, one first sub-pixel 11 or one second sub-pixel 12 includes a first protrusion portion tc′ and a first main portion zt′. The first protrusion portion tc′ is located on one side of the first main portion zt′ close to an intersection point O1 of two diagonals in the first virtual quadrangle 14. The center of the third sub-pixel 13 is located on one side of the intersection point of the two diagonals in the first virtual quadrangle 14 close to the first protrusion portion tc′.

For example, the arrangement in which one first sub-pixel 11 or one second sub-pixel 12 includes a first protrusion portion tc′ and a first main portion zt′ may be understood as that the sub-pixel including the protrusion portion includes a first protrusion portion tc′ and a first main portion zt′. As shown in FIG. 15, a second sub-pixel 12 includes a first protrusion portion tc′ and a first main portion zt′. Moreover, as shown in FIG. 15, the first protrusion portion tc′ is located on one side of the first main portion zt′ close to the intersection point O1 of the two diagonals in the first virtual quadrangle 14. With this arrangement, the average distance between the sub-pixel including the first protrusion portion tc′ and the first main portion zt′ and the intersection point O1 of the two diagonals in the first virtual quadrangle 14 increases compared with a sub-pixel whose shape (for example, the virtual shape 16 as shown) does not change. That is, average distances between two sub-pixels including protrusion portions and located on two sides of the intersection point O1 of the two diagonals in the first virtual quadrangle 14 and the intersection point O1 of the two diagonals in the first virtual quadrangle 14 are different. Therefore, in embodiments of the present application, the center of the third sub-pixel 13 is located on one side of the intersection point of the two diagonals in the first virtual quadrangle 14 close to the first protrusion portion tc′. Such an arrangement can guarantee that average distances between the third sub-pixel 13 and two sub-pixels (for example, second sub-pixels 12 as shown) each including a protrusion portion are the same or similar.

Accordingly, it can guarantee the same or similar color mixture effect between the third sub-pixel 13 and two sub-pixels each including a protrusion portion, thereby guaranteeing the display effect of the display panel. Moreover, the arrangement in which average distances between the third sub-pixel 13 and two sub-pixels (for example, second sub-pixels 12 as shown) each including a protrusion portion are the same or similar can also guarantee the same or similar transmission distance of leakage currents between the third sub-pixel 13 and two sub-pixels each including a protrusion portion, avoiding an excessively large leakage current caused by a small transmission distance of a leakage current on one side, and avoiding relatively serious display crosstalk and undesired light emission of sub-pixels.

On the basis of the preceding embodiments, FIG. 16 is a structural diagram of a second virtual quadrangle according to an embodiment of the present application. As shown in FIG. 16, the center of the second virtual quadrangle 15 does not coincide with the center of the first sub-pixel located inside the second virtual quadrangle 15; alternatively, the center of the second virtual quadrangle 15 does not coincide with the center of the second sub-pixel located inside the second virtual quadrangle 15.

For example, the center of the second virtual quadrangle 15 does not coincide with the center of the first sub-pixel located inside the second virtual quadrangle 15.

Alternatively, the arrangement in which the center of the second virtual quadrangle 15 does not coincide with the center of the first sub-pixel located inside the second virtual quadrangle 15 indicates that the center of the second virtual quadrangle 15 does not coincide with the center of the sub-pixel including the protrusion portion and located inside the second virtual quadrangle 15. FIG. 16 exemplarily illustrates that the center of the second virtual quadrangle 15 does not coincide with the center of the first sub-pixel located inside the second virtual quadrangle 15. Moreover, as shown in FIG. 16, the shape of the second virtual quadrangle 15 is a rectangle.

In the related art, when the shape of the first sub-pixel or the shape of the second sub-pixel does not change, the center of the second virtual quadrangle coincides with the center of the first sub-pixel located inside the second virtual quadrangle and coincides with the center of the second sub-pixel located inside the second virtual quadrangle. Since the shape of the first sub-pixel 11 or the shape of the second sub-pixel 12 changes, for example, since a first sub-pixel 11 includes a main portion zt and a protrusion portion tc and the shape of the first sub-pixel 11 changes, the center position of the first sub-pixel 11 changes compared with the case where the shape of the first sub-pixel 11 does not change. Accordingly, the center O3 of the second virtual quadrangle 15 does not coincide with the center O4 of the first sub-pixel 11 located inside the second virtual quadrangle 15. In this case, the position of the sub-pixel including the protrusion portion (for example, the first sub-pixel 11) may be adjusted reasonably according to the change of the shape of the sub-pixel including the protrusion portion (for example, the first sub-pixel 12) so as to guarantee that distances between the sub-pixel including the protrusion portion (for example, the first sub-pixel 11) and multiple third sub-pixels 13 arranged around the sub-pixel including the protrusion portion are the same or similar, guaranteeing the mixing effect between sub-pixels of different colors and suppressing the effect of leakage currents to be the same or similar. It is to be noted that the center of the second virtual quadrangle may be understood as the geometric center of the second virtual quadrangle, for example, an intersection point of two diagonals. The center of the first sub-pixel or the center of the second sub-pixel may be understood as the geometric center of the first sub-pixel or the geometric center of the second sub-pixel. When the sub-pixel including the protrusion portion is an axisymmetric structure, the center of the sub-pixel including the protrusion portion is located on an axis of symmetry of the sub-pixel including the protrusion portion.

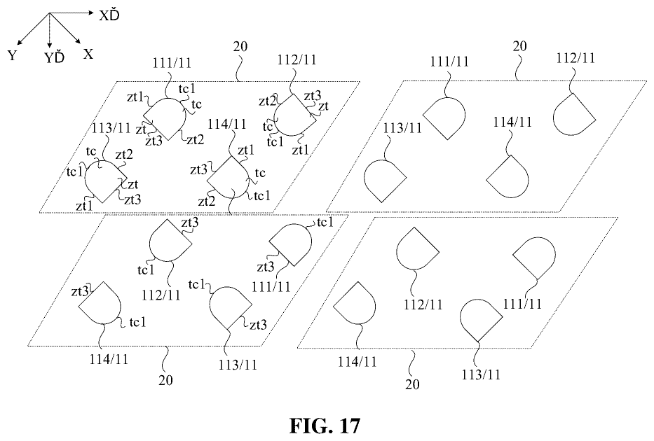

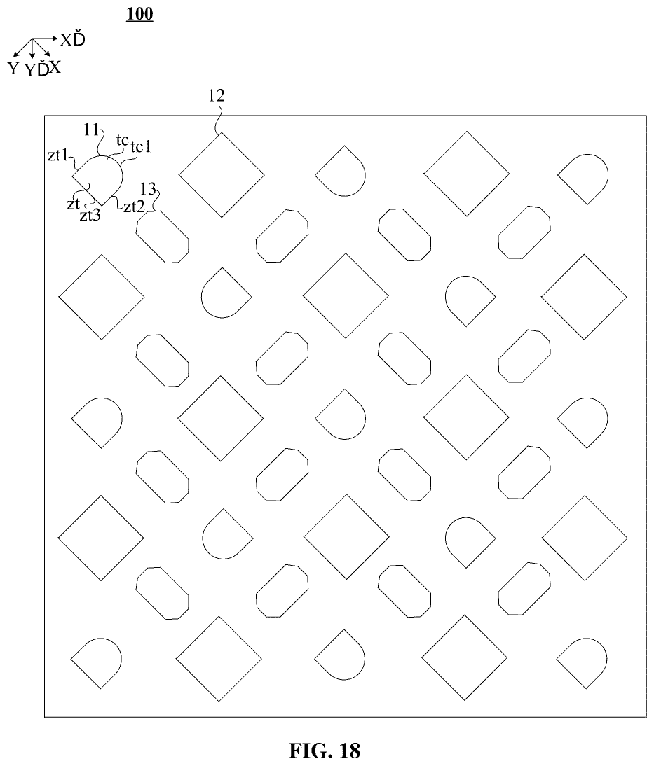

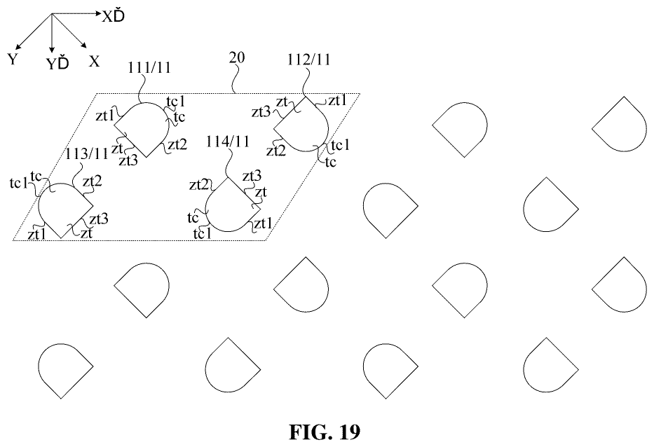

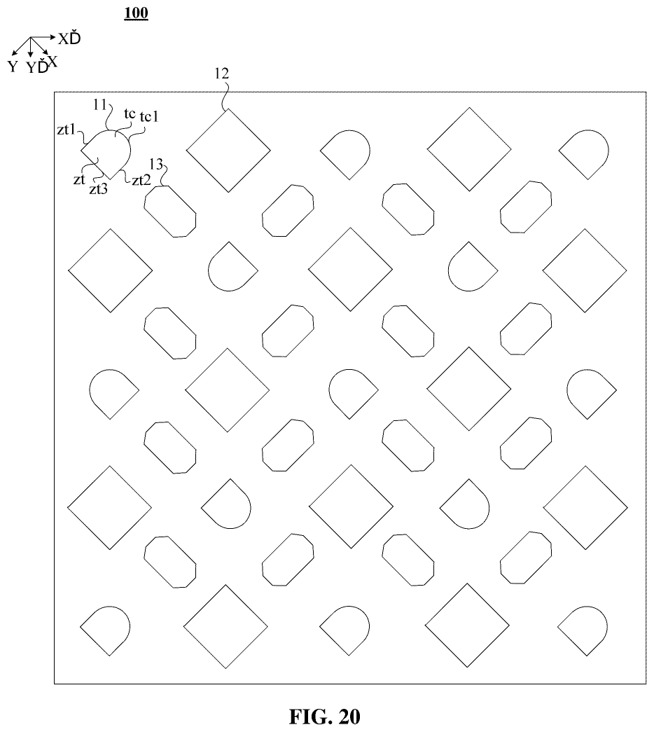

On the basis of the preceding embodiments, FIG. 16 is a fourth structural diagram of a display panel according to an embodiment of the present application. FIG. 17 is a first structural diagram of a first sub-pixel group according to an embodiment of the present application. FIG. 18 is a fifth structural diagram of a display panel according to an embodiment of the present application. FIG. 19 is a second structural diagram of a first sub-pixel group according to an embodiment of the present application. Referring to FIGS. 16 to 19, the first sub-pixels 11 and the second sub-pixels 12 are arranged alternately in the third direction X′ and the fourth direction Y′. The first sub-pixels 11 and the third sub-pixels 13 are arranged alternately in the first direction Y and the second direction X. The second sub-pixels 12 and the third sub-pixels 13 are arranged alternately in the first direction Y and the second direction X. The third direction X′ intersects the fourth direction Y′. The third direction X′ intersects the first direction Y and the second direction X. The fourth direction Y′ intersects the first direction Y and the second direction X. A first sub-pixel 11 includes a protrusion portion tc. A main portion zt includes a first edge zt1 and a second edge zt2. The first edge zt1 and the second edge zt2 extend in the first direction Y and are arranged in the second direction X. The protrusion portion tc includes a third edge tc1. The third edge tc1 is connected to the same side of the first edge zt1 and the second edge zt2. The first sub-pixel 11 further includes a fourth edge zt3 opposite to the fourth edge zt3. The fourth edge zt3 is connected to the same side of the first edge zt1 and the second edge zt2. The display panel includes first sub-pixel groups 20. A first sub-pixel group 20 includes a first first sub-pixel 111, a second first sub-pixel 112, a third first sub-pixel 113, and a fourth first sub-pixel 114. The first first sub-pixel 111 and the second first sub-pixel 112 are adjacent to each other and arranged in the third direction X′.

The third first sub-pixel 113 and the fourth first sub-pixel 114 are adjacent to each other and arranged in the third direction X′. The first first sub-pixel 111 and the third first sub-pixel 113 are adjacent to each other and arranged in the first direction Y. The first first sub-pixel 111 and the fourth first sub-pixel 114 are adjacent to each other and arranged in the second direction X. The second first sub-pixel 112 and the fourth first sub-pixel 114 are adjacent to each other and arranged in the first direction Y. In the same first sub-pixel group 20, third edges tc1 and fourth edges zt3 of each of two first sub-pixels are arranged in the first direction Y, and protrusion directions of protrusion portions tc of the two first sub-pixels 11 whose third edges tc1 and fourth edges zt3 are arranged in the first direction Y are opposite to each other; and third edges tc1 and fourth edges zt3 of two first sub-pixels 11 are arranged in the second direction X, and protrusion directions of protrusion portions tc of the two first sub-pixels 11 whose third edges tc1 and fourth edges zt3 are arranged in the second direction X are opposite to each other.

As shown in FIGS. 16 and 18, the first sub-pixels 11 and the second sub-pixels 12 are arranged alternately in the third direction X′ and the fourth direction Y′. The first sub-pixels 11 and the third sub-pixels 13 are arranged alternately in the first direction Y and the second direction X. The second sub-pixels 12 and the third sub-pixels 13 are arranged alternately in the first direction Y and the second direction X. Moreover, each of a first sub-pixel 11, a second sub-pixel 12, and a third sub-pixel 13 is one of a red sub-pixel, a blue sub-pixel, or a green sub-pixel; and a first sub-pixel 11, a second sub-pixel 12, and a third sub-pixel 13 are different from each other. With this arrangement, the first sub-pixels 11, the second sub-pixels 12, and the third sub-pixels 13 are arranged in an array and regularly, implementing the color display of the display panel.

In an embodiment, the first sub-pixel group 20 includes the first first sub-pixel 111, the second first sub-pixel 112, the third first sub-pixel 113, and the fourth first sub-pixel 114. The first first sub-pixel 111 and the second first sub-pixel 112 are adjacent to each other and arranged in the third direction X′. The third first sub-pixel 113 and the fourth first sub-pixel 114 are adjacent to each other and arranged in the third direction X′. The first first sub-pixel 111 and the third first sub-pixel 113 are adjacent to each other and arranged in the first direction Y. The first first sub-pixel 111 and the fourth first sub-pixel 114 are adjacent to each other and arranged in the second direction X. The second first sub-pixel 112 and the fourth first sub-pixel 114 are adjacent to each other and arranged in the first direction Y. That is, four first sub-pixels 11 in the same first sub-pixel group 20 are arranged in two rows and four columns. The same first sub-pixel group 20 substantially forms the shape of a parallelogram. The row direction is the same as the third direction X′. The column direction is the same as the fourth direction Y′. In the same first sub-pixel group 20, third edges tc1 and fourth edges zt3 of two first sub-pixels are arranged in the first direction Y or in the second direction X, for example, the first first sub-pixel 11 and the second first sub-pixel 112 shown in FIG. 17, the third first sub-pixel 113 and the fourth first sub-pixel 114 shown in FIG. 17, the first first sub-pixel 111 and the fourth first sub-pixel 114 shown in FIG. 19, or the second first sub-pixel 112 and the third first sub-pixel 113 shown in FIG. 19. Protrusion directions of protrusion portions tc of the two preceding first sub-pixels 11 whose third edges tc1 and fourth edges zt3 are arranged in the first direction Y or the second direction X are opposite to each other. For example, as shown in FIG. 17, a protrusion portion tc of the first first sub-pixel 111 and a protrusion portion tc of the second first sub-pixel 112 protrude towards the positive direction of Y and the negative direction of Y respectively. For example, as shown in FIG. 17, a protrusion portion tc of the third first sub-pixel 113 and a protrusion portion tc of the fourth first sub-pixel 114 protrude towards the positive direction of X and the negative direction of X respectively. For example, as shown in FIG. 19, the protrusion portion tc of the first first sub-pixel 111 and the protrusion portion tc of the fourth first sub-pixel 114 protrude towards the positive direction of Y and the negative direction of Y respectively. For example, as shown in FIG. 19, the protrusion portion tc of the second first sub-pixel 112 and the protrusion portion tc of the third first sub-pixel 113 protrude towards the positive direction of X and the negative direction of X respectively. Such an arrangement guarantees protrusion directions of protrusion portions tc of four first sub-pixels 11 in each first sub-pixel group 20 are different from each other. For example, protrusion directions of protrusion portions tc of four first sub-pixels 11 are the positive direction of Y, the negative direction of Y, the positive direction of X, and the negative direction of X respectively. That is, four sub-pixels including protrusion portions in each first sub-pixel group 20 protrude towards four orientations respectively. Such an arrangement guarantees that arrangement positions of four first sub-pixels 11 in the same first sub-pixel group 20 are balanced, avoiding color deviation of the four orientations and guaranteeing the balanced display effect of the first sub-pixels and the display panel.

On the basis of the preceding embodiments, with continued reference to FIG. 17, a third edge tc1 of the first first sub-pixel 111, a fourth edge zt3 of the first first sub-pixel 111, a third edge tc1 of the second first sub-pixel 112, and a fourth edge zt3 of the second first sub-pixel 112 are arranged in the first direction Y. The protrusion direction of the protrusion portion tc of the first first sub-pixel 111 is opposite to the protrusion direction of the protrusion portion tc of the second first sub-pixel 112. A third edge tc1 of the third first sub-pixel 113, a fourth edge zt3 of the third first sub-pixel 113, a third edge tc1 of the fourth first sub-pixel 114, and a fourth edge zt3 of the fourth first sub-pixel 114 are arranged in the second direction X. The protrusion direction of the protrusion portion tc of the third first sub-pixel 113 is opposite to the protrusion direction of the protrusion portion tc of the fourth first sub-pixel 114. As shown in FIG. 17, the protrusion portion tc of the first first sub-pixel 111 protrudes towards the negative direction of Y. The protrusion portion tc of the second first sub-pixel 112 protrudes towards the positive direction of Y. That is, the protrusion direction of the protrusion portion the of the first first sub-pixel 111 is opposite to the protrusion direction of the protrusion portion tc of the second first sub-pixel 112. The protrusion portion tc of the third first sub-pixel 113 protrudes towards the negative direction of X. The protrusion portion the of the fourth first sub-pixel 114 protrudes towards the positive direction of X. That is, the protrusion portion tc of the third first sub-pixel 113 is opposite to the protrusion direction of the protrusion portion tc of the fourth first sub-pixel 114. With this arrangement, protrusion directions of protrusion portions tc of four first sub-pixels 11 in each first sub-pixel group 20 are different from each other. Four first sub-pixels 11 including protrusion portions in each first sub-pixel group 20 protrude towards four orientations respectively. Such an arrangement guarantees that arrangement positions of four first sub-pixels 11 in the same first sub-pixel group 20 are balanced, avoiding color deviation of the four orientations and guaranteeing the balanced display effect of the first sub-pixel group and the display panel. Moreover, in the same first sub-pixel group 20, protrusion directions of protrusion portions of two first sub-pixels in the same row are opposite to each other (for example, one protrusion portion protrudes towards the positive direction of Y, and the other protrusion portion protrudes towards the negative direction of Y; alternatively, one protrusion portion protrudes towards the positive direction of X, and the other protrusion portion protrudes towards the negative direction of X), guaranteeing that arrangement manners and color deviation of two first sub-pixels in the same row are complementary, guaranteeing the balanced display effect of two first sub-pixels in the same row, and thereby guaranteeing the balanced display effect of the entire display panel.

In an embodiment, with continued reference to FIG. 17, in two first sub-pixel groups 20 adjacent to each other in the fourth direction Y′, protrusion directions of protrusion portions of two first sub-pixels 11 adjacent to each other in the fourth direction Y′ are opposite to each other.

For example, two first sub-pixels 11 adjacent to each other in the fourth direction Y′ in two first sub-pixel groups 20 adjacent to each other in the fourth direction Y′ may be understood as two first sub-pixels 11 having the same positional relationship in two first sub-pixel groups 20, for example, two first sub-pixels each located in the first row and the second column in one of two first sub-pixel groups 20 adjacent to each other in the fourth direction Y′, two first sub-pixels each located in the first row and the fourth column in one of two first sub-pixel groups 20 adjacent to each other in the fourth direction Y′, two first sub-pixels each located in the second row and the first column in one of two first sub-pixel groups 20 adjacent to each other in the fourth direction Y′, and two first sub-pixels each located in the second row and the third column in one of two first sub-pixel groups 20 adjacent to each other in the fourth direction Y′. In an example shown in FIG. 17 in which two first sub-pixel groups 20 are adjacent to each other in the fourth direction Y′, two first sub-pixels each located in the first row and the second column in one of the two first sub-pixel groups 20 are a first first sub-pixel 111 and a second first sub-pixel 112, a protrusion portion tc of one of the two first sub-pixels protrudes towards the negative direction of Y, and a protrusion portion tc of the other first sub-pixel protrudes towards the positive direction of Y. In an example shown in FIG. 17 in which two first sub-pixel groups 20 are adjacent to each other in the fourth direction Y′, two first sub-pixels each located in the first row and the fourth column in one of the two first sub-pixel groups 20 are a second first sub-pixel 111 and a first first sub-pixel 112, a protrusion portion tc of one of the two first sub-pixels protrudes towards the positive direction of Y, and a protrusion portion tc of the other first sub-pixel protrudes towards the negative direction of Y. In an example shown in FIG. 17 in which two first sub-pixel groups 20 are adjacent to each other in the fourth direction Y′, two first sub-pixels each located in the second row and the first column in one of the two first sub-pixel groups 20 are a third first sub-pixel 113 and a fourth first sub-pixel 114, a protrusion portion tc of one of the two first sub-pixels protrudes towards the negative direction of X, and a protrusion portion tc of the other first sub-pixel protrudes towards the positive direction of X. In an example shown in FIG. 17 in which two first sub-pixel groups 20 are adjacent to each other in the fourth direction Y′, two first sub-pixels each located in the second row and the third column in one of the two first sub-pixel groups 20 are a fourth first sub-pixel 114 and a third first sub-pixel 113, a protrusion portion tc of one of the two first sub-pixels protrudes towards the positive direction of X, and a protrusion portion tc of the other first sub-pixel protrudes towards the negative direction of X. With this arrangement, in two first sub-pixel groups 20 adjacent to each other in the fourth direction Y′, protrusion directions of protrusion portions of two first sub-pixels in the same row are opposite to each other (for example, one protrusion portion protrudes towards the positive direction of Y, and the other protrusion portion protrudes towards the negative direction of Y; alternatively, one protrusion portion protrudes towards the positive direction of X, and the other protrusion portion protrudes towards the negative direction of X), guaranteeing that arrangement manners and color deviation of two first sub-pixels in the same column are complementary, guaranteeing the balanced display effect of two first sub-pixels in the same column, and thereby guaranteeing the balanced display effect of the entire display panel.

The arrangement in which protrusion directions of any two first sub-pixels 11 adjacent to each other in the fourth direction Y′ are opposite to each other guarantees that arrangement positions of the first sub-pixels in the entire display panel are balanced, avoids color deviation of the four orientations, and guarantees the balanced display effect of the entire display panel.

With continued reference to FIG. 19, the third edge tc1 of the first first sub-pixel 111, the fourth edge zt3 of the first first sub-pixel 111, the third edge tc1 of the fourth first sub-pixel 114, and the fourth edge zt3 of the fourth first sub-pixel 114 are arranged in the first direction Y. The protrusion direction of the protrusion portion tc of the first first sub-pixel 111 is opposite to the protrusion direction of the protrusion portion tc of the fourth first sub-pixel 114. The third edge tc1 of the second first sub-pixel 112, the fourth edge zt3 of the second first sub-pixel 112, the third edge tc1 of the third first sub-pixel 113, and the fourth edge zt3 of the third first sub-pixel 113 are arranged in the second direction X. The protrusion direction of the protrusion portion tc of the second first sub-pixel 112 is opposite to the protrusion direction of the protrusion portion the of the third first sub-pixel 113. As shown in FIG. 19, the protrusion portion tc of the first first sub-pixel 111 protrudes towards the negative direction of Y. The protrusion portion tc of the fourth first sub-pixel 114 protrudes towards the positive direction of Y. That is, the protrusion direction of the protrusion portion tc of the first first sub-pixel 111 is opposite to the protrusion direction of the protrusion portion tc of the fourth first sub-pixel 114. The protrusion portion tc of the second first sub-pixel 112 protrudes towards the positive direction of X. The protrusion portion tc of the third first sub-pixel 113 protrudes towards the negative direction of X. That is, the protrusion portion tc of the second first sub-pixel 112 is opposite to the protrusion direction of the protrusion portion tc of the third first sub-pixel 113. With this arrangement, protrusion directions of protrusion portions tc of four first sub-pixels 11 in each first sub-pixel group 20 are different from each other. Four first sub-pixels 11 including protrusion portions protrude towards four orientations respectively. Such an arrangement guarantees that arrangement positions of four first sub-pixels 11 in the same first sub-pixel group 20 are balanced, avoiding color deviation of the four orientations and guaranteeing the balanced display effect of the first sub-pixel group and the display panel. Moreover, protrusion directions of protrusion portions of two first sub-pixels in the same row are the X direction and the Y direction respectively, compensating for the color deviation in the X direction and the color deviation in the Y direction respectively and guaranteeing display effect.

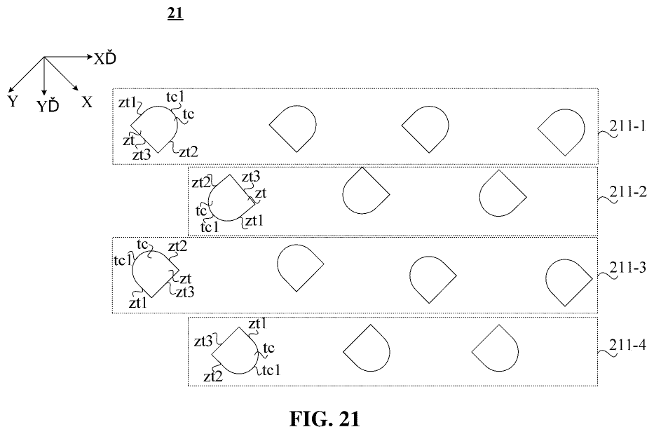

Optionally, FIG. 20 is a sixth structural diagram of a display panel according to an embodiment of the present application. FIG. 21 is a structural diagram of a second sub-pixel group according to an embodiment of the present application. Referring to FIGS. 20 and 21, the first sub-pixels 11 and the second sub-pixels 12 are arranged alternately in the third direction X′ and the fourth direction Y′. The third direction X′ intersects the fourth direction Y′. The third direction X′ intersects the first direction Y and the second direction X. The fourth direction Y′ intersects the first direction Y and the second direction X. The first sub-pixels 11 and the third sub-pixels 13 are arranged alternately in the first direction Y and the second direction X. The second sub-pixels 12 and the third sub-pixels 13 are arranged alternately in the first direction Y and the second direction X. A first sub-pixel 11 includes a protrusion portion tc. A main portion includes a first edge zt1 and a second edge zt2. The first edge zt1 and the second edge zt2 extend in the first direction Y and are arranged in the second direction X. The protrusion portion the includes a third edge tc1. The third edge tc1 is connected to the same side of the first edge zt1 and the second edge zt2. The first sub-pixel 11 further includes a fourth edge zt3 opposite to the third edge tc1. The fourth edge zt3 is connected to the same side of the first edge zt1 and the second edge zt2. The display panel includes second sub-pixel groups 21. A second sub-pixel group 21 includes four first sub-pixel rows 211 arranged in the fourth direction Y′. Among the four first sub-pixel rows 211, third edges tc1 and fourth edges zt3 in two first sub-pixel rows 211 are arranged in the first direction Y, and protrusion directions of protrusion portions tc in the two first sub-pixel rows 211 in which the third edges tc1 and the fourth edges zt3 are arranged in the first direction Y are opposite to each other; third edges tc1 and fourth edges zt3 in two first sub-pixel rows 211 are arranged in the second direction X, and protrusion directions of protrusion portions tc in the two first sub-pixel rows 211 in which the third edges tc1 and the fourth edges zt3 are arranged in the second direction X are opposite to each other. In the same first sub-pixel row 211, protrusion directions of protrusion portions tc of any two first sub-pixels 11 are the same.

Referring to FIG. 20, the first sub-pixels 11 and the second sub-pixels 12 are arranged alternately in the third direction X′ and the fourth direction Y′. The first sub-pixels 11 and the third sub-pixels 13 are arranged alternately in the first direction Y and the second direction X. The second sub-pixels 12 and the third sub-pixels 13 are arranged alternately in the first direction Y and the second direction X. Moreover, each of a first sub-pixel 11, a second sub-pixel 12, and a third sub-pixel 13 is one of a red sub-pixel, a blue sub-pixel, or a green sub-pixel; and a first sub-pixel 11, a second sub-pixel 12, and a third sub-pixel 13 are different from each other. With this arrangement, the first sub-pixels 11, the second sub-pixels 12, and the third sub-pixels 13 are arranged in an array and regularly, implementing the color display of the display panel.

In an embodiment, as shown in FIG. 21, the second sub-pixel group 20 includes the four first sub-pixel rows 211. Multiple first sub-pixels 11 in each first sub-pixel row 211 are arranged in the third direction X′. Multiple first sub-pixel rows 211 are arranged in the fourth direction Y′. Among the four first sub-pixel rows 211, third edges tc1 and fourth edges zt3 in two first sub-pixel rows 211 are arranged in the first direction Y, for example, a first first sub-pixel row 211-1 and a second first sub-pixel row 211-2 as shown. The protrusion direction of a protrusion portion tc of each first sub-pixel 11 in the first first sub-pixel row 211-1 is opposite to the protrusion direction of a protrusion portion tc of each first sub-pixel 11 in the second first sub-pixel row 211-2. For example, the protrusion direction of a protrusion portion tc of each first sub-pixel 11 in the first first sub-pixel row 211-1 protrudes towards the negative direction of Y, and the protrusion direction of a protrusion portion tc of each first sub-pixel 11 in the second first sub-pixel row 211-2 protrudes towards the positive direction of Y. In an embodiment, third edges tc1 and fourth edges zt3 in two first sub-pixel rows 211 are arranged in the first direction X, for example, a third first sub-pixel row 211-3 and a fourth first sub-pixel row 211-4 as shown. The protrusion direction of a protrusion portion tc of each first sub-pixel 11 in the third first sub-pixel row 211-3 is opposite to the protrusion direction of a protrusion portion tc of each first sub-pixel 11 in the fourth first sub-pixel row 211-4. For example, the protrusion direction of a protrusion portion tc of each first sub-pixel 11 in the third first sub-pixel row 211-3 protrudes towards the negative direction of X, and the protrusion direction of a protrusion portion tc of each first sub-pixel 11 in the fourth first sub-pixel row 211-4 protrudes towards the positive direction of X. Such an arrangement guarantees protrusion directions of protrusion portions tc in four first sub-pixel rows 211 in each second sub-pixel group 21 are different from each other. For example, protrusion directions of protrusion portions tc in four first sub-pixel rows 211 are the positive direction of Y, the negative direction of Y, the positive direction of X, and the negative direction of X respectively. That is, four sub-pixels in four sub-pixel rows including protrusion portions in each second sub-pixel group 21 protrude towards four orientations respectively. Such an arrangement guarantees that arrangement positions of four first sub-pixel rows 211 in the same second sub-pixel group 21 are balanced, avoiding color deviation of the four orientations and guaranteeing the balanced display effect of the second sub-pixel group 21 and the display panel.

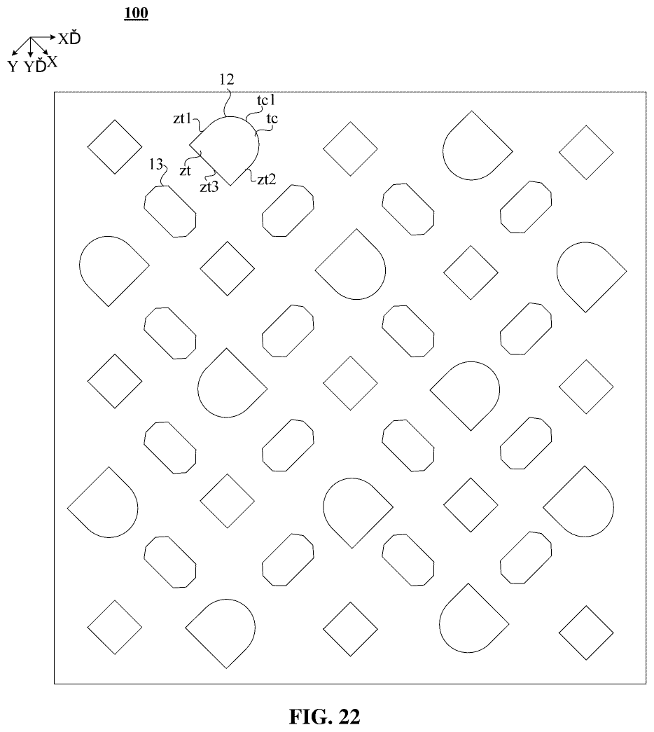

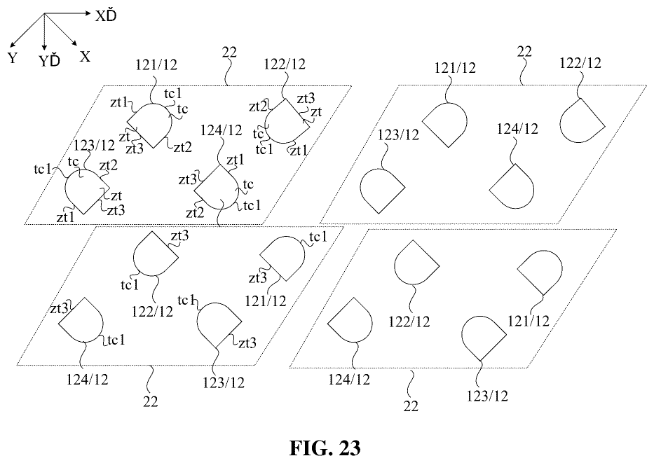

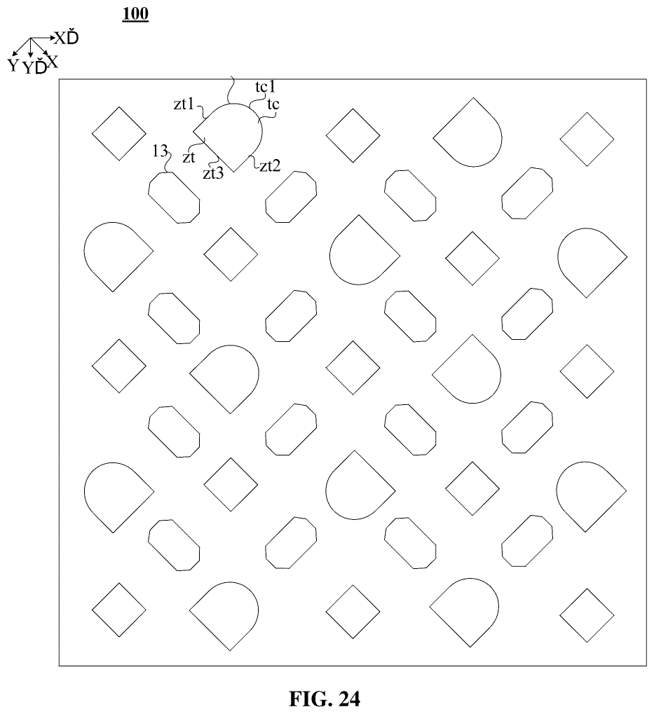

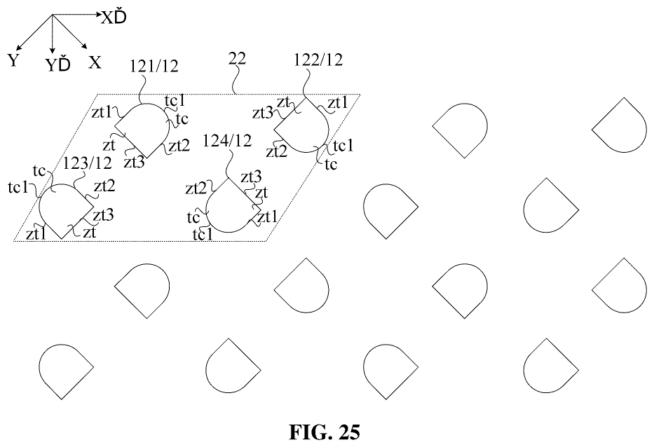

Optionally, FIG. 22 is a seventh structural diagram of a display panel according to an embodiment of the present application. FIG. 23 is a first structural diagram of a third sub-pixel group according to an embodiment of the present application. FIG. 24 is an eighth structural diagram of a display panel according to an embodiment of the present application. FIG. 25 is a second structural diagram of a third sub-pixel group according to an embodiment of the present application. As shown in FIGS. 22 to 25, the first sub-pixels 11 and the second sub-pixels 12 are arranged alternately in the third direction X′ and the fourth direction Y′. The third direction X′ intersects the fourth direction Y′. The third direction X′ intersects the first direction Y and the second direction X. The fourth direction Y′ intersects the first direction Y and the second direction X. The first sub-pixels 11 and the third sub-pixels 13 are arranged alternately in the first direction Y and the second direction X. The second sub-pixels 12 and the third sub-pixels 13 are arranged alternately in the first direction Y and the second direction X. A second sub-pixel 12 includes a protrusion portion tc. A main portion includes a first edge zt1 and a second edge zt2. The first edge zt1 and the second edge zt2 extend in the first direction Y and are arranged in the second direction X. The protrusion portion tc includes a third edge tc1. The third edge tc1 is connected to the same side of the first edge zt1 and the second edge zt2. The second sub-pixel 12 further includes a fourth edge zt3 opposite to the third edge tc1. The fourth edge zt3 is connected to the same side of the first edge zt1 and the second edge zt2. The display panel includes third sub-pixel groups 22. A third sub-pixel group 22 includes a first second sub-pixel 121, a second second sub-pixel 122, a third second sub-pixel 123, and a fourth second sub-pixel 124. The first second sub-pixel 121 and the second second sub-pixel 122 are adjacent to each other and arranged in the third direction X′. The third second sub-pixel 123 and the fourth second sub-pixel 124 are adjacent to each other and arranged in the third direction X′. The first second sub-pixel 121 and the third second sub-pixel 123 are adjacent to each other and arranged in the first direction Y. The first second sub-pixel 121 and the fourth second sub-pixel 124 are adjacent to each other and arranged in the second direction X. The second second sub-pixel 122 and the fourth second sub-pixel 124 are adjacent to each other and arranged in the first direction Y. In the same third sub-pixel group, third edges tc1 and fourth edges zt3 of two second sub-pixels 12 are arranged in the first direction Y, and protrusion directions of protrusion portions tc of the two second sub-pixels 12 whose third edges tc1 and fourth edges zt3 are arranged in the first direction Y are opposite to each other; and third edges tc1 and fourths edge zt3 of two second sub-pixels 12 are arranged in the second direction X, and protrusion directions of protrusion portions tc of the two second sub-pixels 12 whose third edges tc1 and fourth edges zt3 are arranged in the second direction X are opposite to each other.

As shown in FIGS. 22 and 24, the first sub-pixels 11 and the second sub-pixels 12 are arranged alternately in the third direction X′ and the fourth direction Y′. The first sub-pixels 11 and the third sub-pixels 13 are arranged alternately in the first direction Y and the second direction X. The second sub-pixels 12 and the third sub-pixels 13 are arranged alternately in the first direction Y and the second direction X. Moreover, each of a first sub-pixel 11, a second sub-pixel 12, and a third sub-pixel 13 is one of a red sub-pixel, a blue sub-pixel, or a green sub-pixel; and a first sub-pixel 11, a second sub-pixel 12, and a third sub-pixel 13 are different from each other. With this arrangement, the first sub-pixels 11, the second sub-pixels 12, and the third sub-pixels 13 are arranged in an array and regularly, implementing the color display of the display panel.

In an embodiment, the third sub-pixel group 22 includes the first second sub-pixel 121, the second second sub-pixel 122, the third second sub-pixel 123, and the fourth second sub-pixel 124. The first second sub-pixel 121 and the second second sub-pixel 122 are adjacent to each other and arranged in the third direction X′. The third second sub-pixel 123 and the fourth second sub-pixel 124 are adjacent to each other and arranged in the third direction X′. The first second sub-pixel 121 and the third second sub-pixel 123 are adjacent to each other and arranged in the first direction Y. The first second sub-pixel 121 and the fourth second sub-pixel 124 are adjacent to each other and arranged in the second direction X. The second second sub-pixel 122 and the fourth second sub-pixel 124 are adjacent to each other and arranged in the first direction Y. That is, four second sub-pixels 11 in the same third sub-pixel group 22 are arranged in two rows and four columns. The same third sub-pixel group 22 substantially forms the shape of a parallelogram. The row direction is the same as the third direction X′. The column direction is the same as the fourth direction Y′. In the same third sub-pixel group 22, third edges tc1 and fourth edges zt3 of two second sub-pixels are arranged in the first direction Y or in the second direction X, for example, the first second sub-pixel 121 and the second second sub-pixel 122 shown in FIG. 23, the third second sub-pixel 123 and the fourth second sub-pixel 124 shown in FIG. 23, the first second sub-pixel 121 and the fourth second sub-pixel 124 shown in FIG. 25, or the second second sub-pixel 122 and the third second sub-pixel 123 shown in FIG. 25. Protrusion directions of protrusion portions tc of the two preceding second sub-pixels 12 whose third edges tc1 and fourth edges zt3 are arranged in the first direction Y or the second direction X are opposite to each other. For example, as shown in FIG. 23, a protrusion portion tc of the first second sub-pixel 121 and a protrusion portion tc of the second second sub-pixel 122 protrude towards the positive direction of Y and the negative direction of Y respectively. For example, as shown in FIG. 23, a protrusion portion tc of the third second sub-pixel 123 and a protrusion portion tc of the fourth second sub-pixel 124 protrude towards the positive direction of X and the negative direction of X respectively. For example, as shown in FIG. 25, the protrusion portion tc of the first second sub-pixel 121 and the protrusion portion tc of the fourth second sub-pixel 124 protrude towards the positive direction of Y and the negative direction of Y respectively. For example, as shown in FIG. 25, the protrusion portion tc of the second second sub-pixel 122 and the protrusion portion tc of the third second sub-pixel 123 protrude towards the positive direction of X and the negative direction of X respectively. Such an arrangement guarantees protrusion directions of protrusion portions tc of four second sub-pixels 12 in each third sub-pixel group 22 are different from each other. For example, protrusion directions of protrusion portions tc of four second sub-pixels 12 are the positive direction of Y, the negative direction of Y, the positive direction of X, and the negative direction of X respectively. That is, four sub-pixels including protrusion portions in each third sub-pixel group 22 protrude towards four orientations respectively. Such an arrangement guarantees that arrangement positions of four second sub-pixels 12 in the same third sub-pixel group 22 are balanced, avoiding color deviation of the four orientations and guaranteeing the balanced display effect of the third sub-pixels and the display panel.

On the basis of the preceding embodiments, with continued reference to FIG. 23, a third edge tc1 of the first second sub-pixel 121, a fourth edge zt3 of the first second sub-pixel 121, a third edge tc1 of the second second sub-pixel 122, and a fourth edge zt3 of the second second sub-pixel 122 are arranged in the first direction Y. The protrusion direction of the protrusion portion tc of the first second sub-pixel 121 is opposite to the protrusion direction of the protrusion portion tc of the second second sub-pixel 122. A third edge tc1 of the third second sub-pixel 123, a fourth edge zt3 of the third second sub-pixel 123, a third edge tc1 of the fourth second sub-pixel 124, and a fourth edge zt3 of the fourth second sub-pixel 124 are arranged in the second direction X. The protrusion direction of the protrusion portion the of the third second sub-pixel 123 is opposite to the protrusion direction of the protrusion portion the of the fourth second sub-pixel 124. As shown in FIG. 23, the protrusion portion tc of the first second sub-pixel 121 protrudes towards the negative direction of Y. The protrusion portion tc of the second second sub-pixel 122 protrudes towards the positive direction of Y. That is, the protrusion direction of the protrusion portion tc of the first second sub-pixel 121 is opposite to the protrusion direction of the protrusion portion tc of the second second sub-pixel 122. The protrusion portion tc of the third second sub-pixel 123 protrudes towards the negative direction of X. The protrusion portion tc of the fourth second sub-pixel 124 protrudes towards the positive direction of X. That is, the protrusion portion tc of the third second sub-pixel 123 is opposite to the protrusion direction of the protrusion portion tc of the fourth second sub-pixel 124. With this arrangement, protrusion directions of protrusion portions tc of four second sub-pixels 12 in each third sub-pixel group 22 are different from each other. Four second sub-pixels 12 including protrusion portions protrude towards four orientations respectively. Such an arrangement guarantees that arrangement positions of four second sub-pixels 12 in the same third sub-pixel group 22 are balanced, avoiding color deviation of the four orientations and guaranteeing the balanced display effect of the third sub-pixel group and the display panel. Moreover, in the same third sub-pixel group 22, protrusion directions of protrusion portions of two second sub-pixels in the same row are opposite to each other (for example, one protrusion portion protrudes towards the positive direction of Y, and the other protrusion portion protrudes towards the negative direction of Y; alternatively, one protrusion portion protrudes towards the positive direction of X, and the other protrusion portion protrudes towards the negative direction of X), guaranteeing that arrangement manners and color deviation of two second sub-pixels in the same row are complementary, guaranteeing the balanced display effect of two second sub-pixels in the same row, and thereby guaranteeing the balanced display effect of the entire display panel.

In an embodiment, with continued reference to FIG. 23, in two third sub-pixel groups 22 adjacent to each other in the fourth direction Y′, protrusion directions of protrusion portions of two second sub-pixels 12 adjacent to each other in the fourth direction Y′ are opposite to each other.

For example, two second sub-pixels 12 adjacent to each other in the fourth direction Y′ in two third sub-pixel groups 22 adjacent to each other in the fourth direction Y′ may be understood as two second sub-pixels 12 having the same positional relationship in two third sub-pixel groups 22, for example, two second sub-pixels each located in the first row and the second column in one of two third sub-pixel groups 22 adjacent to each other in the fourth direction Y′, two second sub-pixels each located in the first row and the fourth column in one of two third sub-pixel groups 22 adjacent to each other in the fourth direction Y′, two second sub-pixels each located in the second row and the first column in one of two third sub-pixel groups 22 adjacent to each other in the fourth direction Y′, and two second sub-pixels each located in the second row and the third column in one of two third sub-pixel groups 22 adjacent to each other in the fourth direction Y′. In an example shown in FIG. 23 in which two third sub-pixel groups 22 are adjacent to each other in the fourth direction Y′, two second sub-pixels each located in the first row and the second column in one of the two third sub-pixel groups 22 are a first second sub-pixel 121 and a second second sub-pixel 122, a protrusion portion tc of one of the two second sub-pixels protrudes towards the negative direction of Y, and a protrusion portion tc of the other second sub-pixel protrudes towards the positive direction of Y. In an example shown in FIG. 23 in which two third sub-pixel groups 22 are adjacent to each other in the fourth direction Y′, two second sub-pixels each located in the first row and the fourth column in one of the two third sub-pixel groups 22 are a second second sub-pixel 122 and a first second sub-pixel 121, a protrusion portion tc of one of the two second sub-pixels protrudes towards the positive direction of Y, and a protrusion portion tc of the other second sub-pixel protrudes towards the negative direction of Y. In an example shown in FIG. 23 in which two third sub-pixel groups 22 are adjacent to each other in the fourth direction Y′, two second sub-pixels each located in the second row and the first column in one of the two third sub-pixel groups 22 are a third second sub-pixel 123 and a fourth second sub-pixel 124, a protrusion portion tc of one of the two second sub-pixels protrudes towards the negative direction of X, and a protrusion portion tc of the other second sub-pixel protrudes towards the positive direction of X. In an example shown in FIG. 23 in which two third sub-pixel groups 22 are adjacent to each other in the fourth direction Y′, two second sub-pixels each located in the second row and the third column in one of the two third sub-pixel groups 22 are a fourth second sub-pixel 124 and a third second sub-pixel 123, a protrusion portion tc of one of the two second sub-pixels protrudes towards the positive direction of X, and a protrusion portion the of the other second sub-pixel protrudes towards the negative direction of X. With this arrangement, in two third sub-pixel groups 22 adjacent to each other in the fourth direction Y′, protrusion directions of protrusion portions of two second sub-pixels in the same row are opposite to each other (for example, one protrusion portion protrudes towards the positive direction of Y, and the other protrusion portion protrudes towards the negative direction of Y; alternatively, one protrusion portion protrudes towards the positive direction of X, and the other protrusion portion protrudes towards the negative direction of X), guaranteeing that arrangement manners and color deviation of two second sub-pixels in the same column are complementary, guaranteeing the balanced display effect of two second sub-pixels in the same column, and thereby guaranteeing the balanced display effect of the entire display panel.

The arrangement in which protrusion directions of any two second sub-pixels 12 adjacent to each other in the fourth direction Y′ are opposite to each other guarantees that arrangement positions of the second sub-pixels in the entire display panel are balanced, avoids color deviation of the four orientations, and guarantees the balanced display effect of the entire display panel.

With continued reference to FIG. 25, the third edge tc1 of the first second sub-pixel 121, the fourth edge zt3 of the first second sub-pixel 121, the third edge tc1 of the fourth second sub-pixel 124, and the fourth edge zt3 of the fourth second sub-pixel 124 are arranged in the first direction Y. The protrusion direction of the protrusion portion tc of the first second sub-pixel 121 is opposite to the protrusion direction of the protrusion portion tc of the fourth second sub-pixel 124. The third edge tc1 of the second second sub-pixel 122, the fourth edge zt3 of the second second sub-pixel 122, the third edge tc1 of the third second sub-pixel 123, and the fourth edge zt3 of the third second sub-pixel 123 are arranged in the second direction X. The protrusion direction of the protrusion portion tc of the second second sub-pixel 122 is opposite to the protrusion direction of the protrusion portion tc of the third second sub-pixel 123. As shown in FIG. 25, the protrusion portion tc of the first second sub-pixel 121 protrudes towards the negative direction of Y. The protrusion portion tc of the fourth second sub-pixel 124 protrudes towards the positive direction of Y. That is, the protrusion direction of the protrusion portion tc of the first second sub-pixel 121 is opposite to the protrusion direction of the protrusion portion tc of the fourth second sub-pixel 124. The protrusion portion tc of the second second sub-pixel 122 protrudes towards the positive direction of X. The protrusion portion tc of the third second sub-pixel 123 protrudes towards the negative direction of X. That is, the protrusion portion tc of the second second sub-pixel 122 is opposite to the protrusion direction of the protrusion portion tc of the third second sub-pixel 123. With this arrangement, protrusion directions of protrusion portions the of four second sub-pixels 12 in each third sub-pixel group 22 are different from each other. Four second sub-pixels 12 including protrusion portions protrude towards four orientations respectively. Such an arrangement guarantees that arrangement positions of four second sub-pixels 12 in the same third sub-pixel group 22 are balanced, avoiding color deviation of the four orientations and guaranteeing the balanced display effect of the third sub-pixel group and the display panel. Moreover, protrusion directions of protrusion portions of two second sub-pixels in the same row are the X direction and the Y direction respectively, compensating for the color deviation in the X direction and the color deviation in the Y direction respectively and guaranteeing display effect.

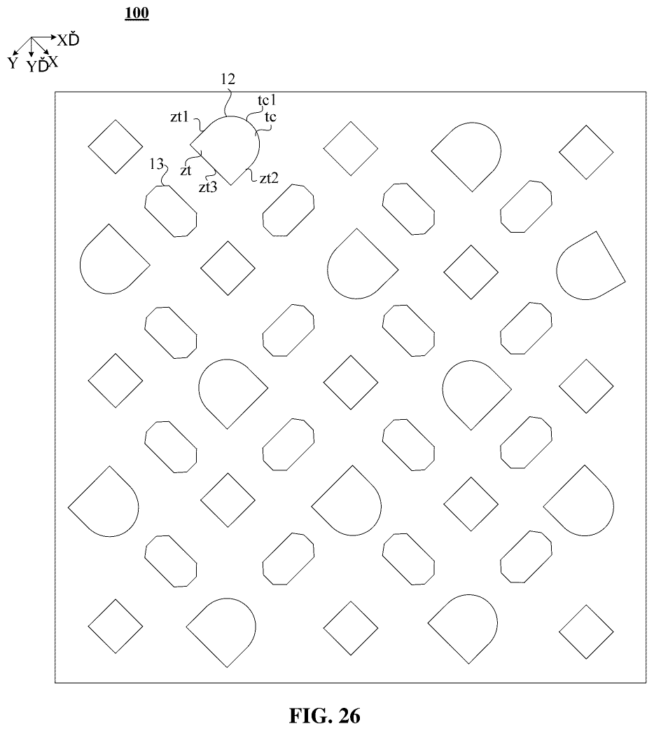

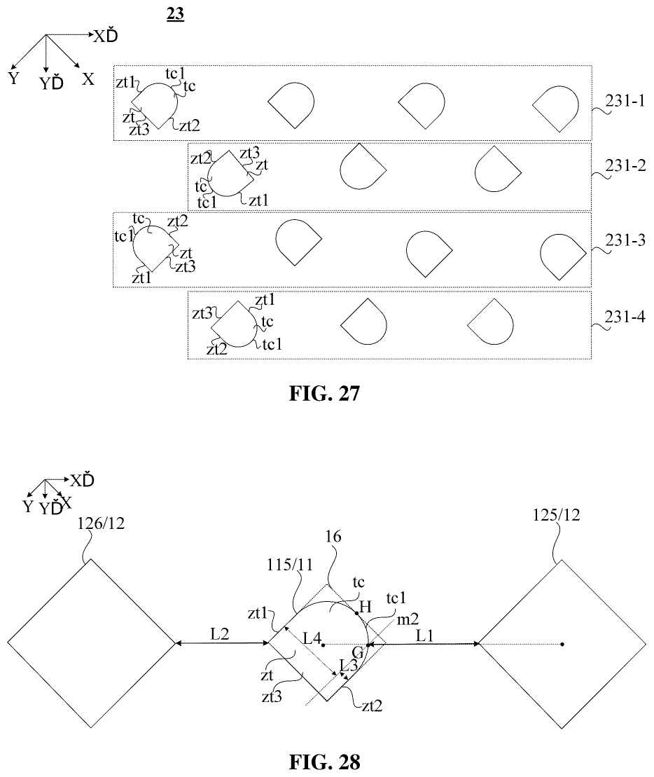

Optionally, FIG. 26 is a ninth structural diagram of a display panel according to an embodiment of the present application. FIG. 27 is a structural diagram of a fourth sub-pixel group according to an embodiment of the present application. Referring to FIGS. 26 and 27, the first sub-pixels 11 and the second sub-pixels 12 are arranged alternately in the third direction X′ and the fourth direction Y′. The third direction X′ intersects the fourth direction Y′. The third direction X′ intersects the first direction Y and the second direction X. The fourth direction Y′ intersects the first direction Y and the second direction X. The first sub-pixels 11 and the third sub-pixels 13 are arranged alternately in the first direction Y and the second direction X. The second sub-pixels 12 and the third sub-pixels 13 are arranged alternately in the first direction Y and the second direction X. A second sub-pixel 12 includes a protrusion portion tc. A main portion includes a first edge zt1 and a second edge zt2. The first edge zt1 and the second edge zt2 extend in the first direction Y and are arranged in the second direction X. The protrusion portion tc includes a third edge tc1. The third edge tc1 is connected to the same side of the first edge zt1 and the second edge zt2. The second sub-pixel 12 further includes a fourth edge zt3 opposite to the third edge tc1. The fourth edge zt3 is connected to the same side of the first edge zt1 and the second edge zt2. The display panel includes fourth sub-pixel groups 23. A fourth sub-pixel group 23 includes four second sub-pixel rows 231 arranged in the fourth direction Y′. Among the four second sub-pixel rows 231, third edges tc1 and fourth edges zt3 in two second sub-pixel rows 231 are arranged in the first direction Y, and protrusion directions of protrusion portions tc in the two second sub-pixel rows 231 in which the third edges tc1 and the fourth edges zt3 are arranged in the first direction Y are opposite to each other; third edges tc1 and fourth edges zt3 in two second sub-pixel rows 231 are arranged in the second direction X, and protrusion directions of protrusion portions tc in the two second sub-pixel rows 231 in which the third edges tc1 and the fourth edges zt3 are arranged in the second direction X are opposite to each other. In the same second sub-pixel row 231, protrusion directions of protrusion portions tc of any two second sub-pixels 23 are the same.

Referring to FIG. 26, the first sub-pixels 11 and the second sub-pixels 12 are arranged alternately in the third direction X′ and the fourth direction Y′. The first sub-pixels 11 and the third sub-pixels 13 are arranged alternately in the first direction Y and the second direction X. The second sub-pixels 12 and the third sub-pixels 13 are arranged alternately in the first direction Y and the second direction X. Moreover, each of a first sub-pixel 11, a second sub-pixel 12, and a third sub-pixel 13 is one of a red sub-pixel, a blue sub-pixel, or a green sub-pixel; and a first sub-pixel 11, a second sub-pixel 12, and a third sub-pixel 13 are different from each other. With this arrangement, the first sub-pixels 11, the second sub-pixels 12, and the third sub-pixels 13 are arranged in an array and regularly, implementing the color display of the display panel.

In an embodiment, as shown in FIG. 27, the fourth sub-pixel group 23 includes the four second sub-pixel rows 231. Multiple second sub-pixels 12 in each second sub-pixel row 231 are arranged in the third direction X′. Multiple second sub-pixel rows 231 are arranged in the fourth direction Y′. Among the four second sub-pixel rows 231, third edges tc1 and fourth edges zt3 in two second sub-pixel rows 231 are arranged in the first direction Y, for example, a first second sub-pixel row 231-1 and a second second sub-pixel row 231-2 as shown. The protrusion direction of a protrusion portion tc of each second sub-pixel 12 in the first second sub-pixel row 231-1 is opposite to the protrusion direction of a protrusion portion tc of each second sub-pixel 12 in the second second sub-pixel row 231-2. For example, the protrusion direction of a protrusion portion tc of each second sub-pixel 12 in the first second sub-pixel row 231-1 protrudes towards the negative direction of Y, and the protrusion direction of a protrusion portion tc of each second sub-pixel 12 in the second second sub-pixel row 231-2 protrudes towards the positive direction of Y. In an embodiment, third edges tc1 and fourth edges zt3 in two second sub-pixel rows 231 are arranged in the first direction X, for example, a third second sub-pixel row 231-3 and a fourth second sub-pixel row 231-4 as shown. The protrusion direction of a protrusion portion tc of each second sub-pixel 12 in the third second sub-pixel row 231-3 is opposite to the protrusion direction of a protrusion portion tc of each second sub-pixel 12 in the fourth second sub-pixel row 231-4. For example, the protrusion direction of a protrusion portion tc of each second sub-pixel 12 in the third second sub-pixel row 231-3 protrudes towards the negative direction of X, and the protrusion direction of a protrusion portion tc of each second sub-pixel 12 in the fourth second sub-pixel row 231-4 protrudes towards the positive direction of X. Such an arrangement guarantees protrusion directions of protrusion portions tc in four second sub-pixel rows 221 in each fourth sub-pixel group 23 are different from each other. For example, protrusion directions of protrusion portions the in four second sub-pixel rows 231 are the positive direction of Y, the negative direction of Y, the positive direction of X, and the negative direction of X respectively. That is, four sub-pixels in four sub-pixel rows including protrusion portions in each fourth sub-pixel group 23 protrude towards four orientations respectively. Such an arrangement guarantees that arrangement positions of four second sub-pixel rows 231 in the same fourth sub-pixel group 23 are balanced, avoiding color deviation of the four orientations and guaranteeing the balanced display effect of the fourth sub-pixel group and the display panel.

On the basis of the preceding embodiments, FIG. 28 is a second structural diagram of a first sub-pixel and a second sub-pixel according to an embodiment of the present application. As shown in FIGS. 2 and 28, the first sub-pixels 11 and the second sub-pixels 12 are arranged alternately in the third direction X′ and the fourth direction Y′. The third direction X′ intersects the fourth direction Y′. The third direction X′ intersects the first direction Y and the second direction X. The fourth direction Y′ intersects the first direction Y and the second direction X. A line segment connecting the center of a first sub-pixel 11 and the center of a second sub-pixel 12 passes through a protrusion portion, where the first sub-pixel 11 and the second sub-pixel 12 are adjacent to each other and arranged in the third direction X′ and/or the fourth direction Y′.

Referring to FIG. 2, the first sub-pixels 11 and the second sub-pixels 12 are arranged alternately in the third direction X′ and the fourth direction Y′. The first sub-pixels 11 and the third sub-pixels 13 are arranged alternately in the first direction Y and the second direction X. The second sub-pixels 12 and the third sub-pixels 13 are arranged alternately in the first direction Y and the second direction X. Moreover, each of a first sub-pixel 11, a second sub-pixel 12, and a third sub-pixel 13 is one of a red sub-pixel, a blue sub-pixel, or a green sub-pixel; and a first sub-pixel 11, a second sub-pixel 12, and a third sub-pixel 13 are different from each other. With this arrangement, the first sub-pixels 11, the second sub-pixels 12, and the third sub-pixels 13 are arranged in an array and regularly, implementing the color display of the display panel.

In an embodiment, as shown in FIG. 28, the line segment connecting the center of a sub-pixel (for example, the first sub-pixel 11 as shown) including the protrusion portion and the center of a sub-pixel (for example, the second sub-pixel 12 located on the right side of the first sub-pixel 11 as shown) towards which the protrusion portion protrudes passes through the protrusion portion. That is, for the first sub-pixel 11 and the second sub-pixel 12 adjacent to each other and arranged in the third direction X′ and/or the fourth direction Y′, the segment connecting the center of the first sub-pixel 11 and the center of the second sub-pixel 12 passes through the protrusion portion. Compared with the virtual shape 16, the distance between the sub-pixel including the protrusion portion tc and an adjacent sub-pixel is relatively large. Such an arrangement can guarantee the relatively long transmission path of the leakage current between the first sub-pixel 11 and the second sub-pixel 12, thereby reducing the leakage current between two adjacent sub-pixels, eliminating or reducing the display crosstalk between two adjacent sub-pixels, avoiding the undesired light emission between two adjacent sub-pixels when performing display, and improving the display effect of the display panel.

On the basis of the preceding embodiments, with continued reference to FIG. 28, the display panel includes a fifth first sub-pixel 115, a fifth second sub-pixel 125, and a sixth second sub-pixel 126. The fifth second sub-pixel 125, the fifth first sub-pixel 115, and the sixth second sub-pixel 126 are arranged in sequence in the third direction X′ or the fourth direction Y′. The fifth first sub-pixel 115 includes a protrusion portion tc. The protrusion portion tc protrudes towards one side of the fifth second sub-pixel 125. The minimum distance between the fifth first sub-pixel 115 and the fifth second sub-pixel 125 is greater than the minimum distance between the fifth first sub-pixel 115 and the sixth second sub-pixel 126.

As shown in FIG. 28, two sub-pixels located on two sides of a sub-pixel including the protrusion portion tc includes a sub-pixel on one side facing a main portion zt and a sub-pixel on one side facing the protrusion portion tc. As shown in FIG. 28, the fifth second sub-pixel 125 is located on one side facing the protrusion part tc and the sixth second sub-pixel 126 is located on one side facing the main portion zt. Moreover, the minimum distance L1 between the fifth first sub-pixel 115 and the fifth second sub-pixel 125 is greater than the minimum distance L2 between the fifth first sub-pixel 115 and the sixth second sub-pixel 126. That is, the minimum distance between the protrusion portion tc and the sub-pixel on one side facing the protrusion portion tc is greater than the minimum distance between the main portion zt and the sub-pixel on one side facing the main portion zt. In this case, the arrangement in which the sub-pixel includes the protrusion portion the can reduce the minimum distance between the sub-pixel including the protrusion portion and part of adjacent sub-pixels, thereby reducing the leakage current between two adjacent sub-pixels, eliminating or reducing the display crosstalk between two adjacent sub-pixels, avoiding the undesired light emission between two adjacent sub-pixels when performing display, and improving the display effect of the display panel.

In an optional embodiment, with continued reference to FIG. 28, the minimum distance between the fifth first sub-pixel 115 and the fifth second sub-pixel 125 is L1. The minimum distance between the fifth first sub-pixel 115 and the sixth second sub-pixel 126 is L2. 0.5 μm≤L1-L2≤6 μm. That is, the difference between the minimum distance between the fifth first sub-pixel 115 and the fifth second sub-pixel 125 and the minimum distance between the fifth first sub-pixel 115 and the sixth second sub-pixel 126 is between 0.5 μm and 6 μm. That is, the adjustment of the shape of the protrusion portion tc in the fifth first sub-pixel 115 guarantees that the transmission distance of the leakage current in the range of 0.5 μm to 6 μm can be increased. Therefore, the shape of the protrusion portion can be adjusted reasonably in combination with the requirements of the aperture ratio of the sub-pixel including the protrusion portion and the requirements of reducing the leakage current so as to well consider both the requirements of the aperture ratio of the sub-pixel including the protrusion portion and the requirements of reducing display crosstalk, thereby improving the display effect of the display panel.

For example, 0.5 μm≤L1-L2≤6 μm. L1-L2 may be 0.5 μm, 1.0 μm, 1.5 μm, 1.9 μm, 2.5 μm, 3.0 μm, 3.6 μm, 4.1 μm, 4.5 μm, 5.0 μm, 5.5 μm, or 6 μm. No special limitations are made to the specific value in embodiments of the present application.

In an embodiment, 1 μm≤L1-L2<6 μm. The further refinement of the value difference between L1 and L2 can further well consider both the requirements of the aperture ratio of the sub-pixel including the protrusion portion and the requirements of reducing display crosstalk, thereby improving the display effect of the display panel. On the basis of the preceding embodiments, with continued reference to FIG. 28, the main portion zt includes a first edge zt1, a second edge zt2, and a fourth edge zt3. The first edge zt1 and the second edge zt2 extend in the first direction Y and are arranged in the second direction X. The protrusion portion tc includes a third edge tc1. The third edge tc1 is connected to the same side of the first edge zt1 and the second edge zt2. The fourth edge zt3 is connected to the same side of the first edge zt1 and the second edge zt2. A minimum distance connection line between the fifth first sub-pixel 115 and the fifth second sub-pixel 125 intersects the third edge tc1 at a third intersection point G. The third edge tc1 includes a protrusion high point H. The distance between the protrusion high point (which is also referred to as a protrusion vertex) H and the fourth edge zt3 is greater than the distance between the third intersection point G and the fourth edge zt3. The third intersection point G is located on one side of the protrusion high point H close to the first edge zt1 or the second edge zt2.

For example, as shown in FIG. 28, the minimum distance connection line between the fifth first sub-pixel 115 and the fifth second sub-pixel 125 intersects the third edge tc1 at the third intersection point G. The third intersection point G is not the protrusion high point H of the protrusion portion H. The protrusion high point H may be understood as a point on the third edge tc1 and having the largest distance from the fourth edge zt3. The distance between the protrusion high point H and the fourth edge zt3 is greater than the distance between the third intersection point G and the fourth edge zt3.

The third intersection point G is located on one side of the protrusion high point H close to the first edge zt1 or the second edge zt2. Such an arrangement can guarantee that the distance between the sub-pixel including the protrusion portion tc and another adjacent sub-pixel is relatively large and guarantee that the transmission path of the leakage current between adjacent sub-pixels is relatively long, thereby reducing the leakage current between the sub-pixel including the protrusion portion tc and another adjacent sub-pixel, eliminating or reducing the display crosstalk between different sub-pixels, eliminating or alleviating the undesired light emission of sub-pixels, and improving the display effect of the display panel.

With continued reference to FIG. 28, the display panel further includes a first virtual line m2. The first virtual line m2 passes through the third intersection point G and is parallel to the first edge zt1. A smaller value of the distance between the first virtual line m2 and the first edge zt1 and the distance between the first virtual line m2 and the second edge zt2 is L3. A larger value of the distance between the first virtual line m2 and the first edge zt1 and the distance between the first virtual line m2 and the second edge zt2 is LA. 3%≤L3/L4≤30%. That is, a ratio of the smaller value of the distance between the first virtual line m2 and the first edge zt1 and the distance between the first virtual line m2 and the second edge zt2 to the larger value of the distance between the first virtual line m2 and the first edge zt1 and the distance between the first virtual line m2 and the second edge zt2 is between 3% and 30%. Such an arrangement can guarantee that the distance between the sub-pixel including the protrusion portion and an adjacent sub-pixel in the third direction X′ or the fourth direction Y′ is relatively large, reducing the leakage current between the sub-pixel including the protrusion portion tc and another adjacent sub-pixel. As shown in FIG. 28, if L3/L4<3%, the distance between the fifth first sub-pixel 115 and the fifth second sub-pixel 125 in the third direction X′ will be further increased, but the minimum distance between the fifth first sub-pixel 115 and another sub-pixel in the fourth direction Y′ will be reduced, causing the leakage current to rise. If L3/L4>30%, the distance between the fifth first sub-pixel 115 and the fifth second sub-pixel 125 in the third direction X′ will be reduced, causing the leakage current between the fifth first sub-pixel 115 and the fifth second sub-pixel 125 to rise. Therefore, with a comprehensive consideration of the leakage current between the sub-pixel including the protrusion portion and another adjacent sub-pixel, it may be reasonably set that 3%≤L3/L4≤30% to guarantee that the leakage current between the sub-pixel including the protrusion portion and another adjacent sub-pixel stays in a relatively small range, guaranteeing that the display crosstalk of the display panel and the undesired light emission of sub-pixels are alleviated in general.

For example, 3%≤L3/L4≤30%. L3/L4 may be 3%, 5%, 8%, 10.2%, 12.3%, 15%, 17.5%, 20%, 23%, 25%, 27.5%, or 30%. No special limitations are made to the specific ratio in embodiments of the present application.

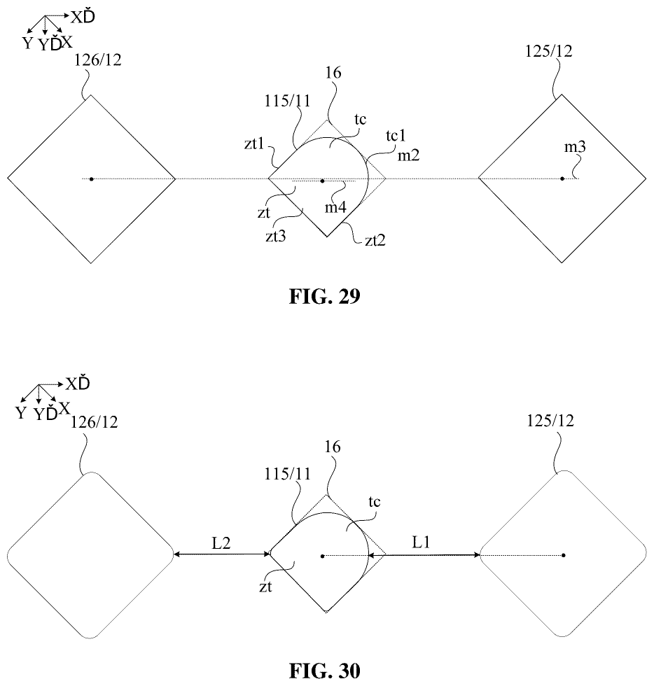

Optionally, FIG. 29 is a third structural diagram of a first sub-pixel and a second sub-pixel according to an embodiment of the present application. As shown in FIGS. 2 and 29, the first sub-pixels 11 and the second sub-pixels 12 are arranged alternately in the third direction X′ and the fourth direction Y′. The third direction X′ intersects the fourth direction Y′. The third direction X′ intersects the first direction Y and the second direction X. The fourth direction Y′ intersects the first direction Y and the second direction X. The display panel includes the fifth first sub-pixel 115, the fifth second sub-pixel 125, and the sixth second sub-pixel 126. The fifth second sub-pixel 125, the fifth first sub-pixel 115, and the sixth second sub-pixel 126 are arranged in sequence in the third direction X′ or the fourth direction Y′. The fifth first sub-pixel 115 includes a protrusion portion tc. The display panel further includes a second virtual line m3 and a third virtual line m4. The second virtual line m3 connects the center of the fifth second sub-pixel 125 and the center of the sixth second sub-pixel 126. The third virtual line m4 passes through the center of the fifth first sub-pixel 115 and is parallel to the second virtual line m3. An interval exists between the second virtual line m3 and the third virtual line m4.

Referring to FIG. 2, the first sub-pixels 11 and the second sub-pixels 12 are arranged alternately in the third direction X′ and the fourth direction Y′. The first sub-pixels 11 and the third sub-pixels 13 are arranged alternately in the first direction Y and the second direction X. The second sub-pixels 12 and the third sub-pixels 13 are arranged alternately in the first direction Y and the second direction X. Moreover, each of a first sub-pixel 11, a second sub-pixel 12, and a third sub-pixel 13 is one of a red sub-pixel, a blue sub-pixel, or a green sub-pixel; and a first sub-pixel 11, a second sub-pixel 12, and a third sub-pixel 13 are different from each other. With this arrangement, the first sub-pixels 11, the second sub-pixels 12, and the third sub-pixels 13 are arranged in an array and regularly, implementing the color display of the display panel.

In an embodiment, as shown in FIG. 29, before the shape of the sub-pixel including the protrusion portion, for example, the virtual shape 16 corresponding to the fifth first sub-pixel 115 as shown, does not change, the center of the sixth second sub-pixel 126, the center of the fifth first sub-pixel 115, and the center of the fifth second sub-pixel 125 are located on the same virtual line. Since the shape of the sub-pixel including the protrusion portion changes, for example, the shape of the fifth first sub-pixel as shown, the shape of the sub-pixel including the protrusion portion is inwardly reduced at the position corresponding to the protrusion portion tc compared with the virtual shape 16. In this case, the center of the sub-pixel including the protrusion portion shifts towards one side away from the protrusion portion and towards one side facing the main portion zt. Therefore, an interval exists between the third virtual line m4 passing through the center of the sub-pixel including the protrusion portion and the second virtual line m3 connecting the center of the fifth second sub-pixel 125 and the center of the sixth second sub-pixel 126. Moreover, the distance is related to the shape of the protrusion portion tc. It is to be understood that the smaller the interval between the shape of the sub-pixel including the protrusion portion and the virtual shape 16, the smaller the distance between the third virtual line m4 and the second virtual line m3. The larger the interval between the shape of the sub-pixel including the protrusion portion and the virtual shape 16, the larger the distance between the third virtual line m4 and the second virtual line m3.

It is to be noted that the preceding embodiments only describe an example in which the sub-pixel including the protrusion portion is a first sub-pixel. It is to be understood that the sub-pixel including the protrusion portion may also be a second sub-pixel. When the sub-pixel including the protrusion portion is a second sub-pixel, the preceding limitations of L1, L2, L3, L4, the first virtual line, the second virtual line, and the third virtual line are also applicable.

In an embodiment, FIG. 30 is a fourth structural diagram of a first sub-pixel and a second sub-pixel according to an embodiment of the present application. Referring to FIGS. 28, 29, and 30, an interior angle in a first sub-pixel 11 or a second sub-pixel 12 and not connected to a third edge tc1 includes a right angle or an arc angle. The arc radius corresponding to the arc angle is less than the radius of the virtual circle.

For example, FIGS. 28 and 29 illustrate the example in which an interior angle not connected to the third edge tc1 is a right angle. FIG. 30 illustrates the example in which an interior angle not connected to the third edge tc1 is an arc angle. An arc angle here may be understood as that the region corresponding to a single top angle is an arc and that arcs corresponding to different positions of the top angle are not co-circumferential. Moreover, the radius of curvature of the arc corresponding to the arc angle is much less than the radius of the virtual circle corresponding to the protrusion portion tc. For example, a ratio of the radius of curvature corresponding to the arc in the arc angle to the radius of curvature of the virtual circle is less than 10.

In an embodiment, referring to FIGS. 28 to 30, in a sub-pixel including no protrusion portion, for example, a second sub-pixel 12 shown in FIG. 30, an interior angle of the sub-pixel may also be set to a right angle or an arc angle. FIGS. 28 and 29 illustrate an example in which an interior angle in the second sub-pixel is a right angle. FIG. 30 illustrates an example in which an interior angle in the second sub-pixel is an arc angle. Moreover, the radius of curvature corresponding to an arc angle in the second sub-pixel may be the same as or different from the radius of curvature corresponding to an arc angle in the first sub-pixel, which is not limited in embodiments of the present application.

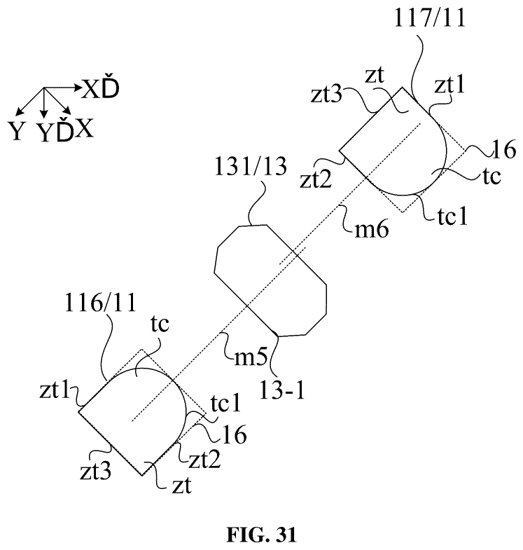

Optionally, FIG. 31 is a structural diagram of a first sub-pixel and a third sub-pixel according to an embodiment of the present application. As shown in FIG. 31, a first sub-pixel 11 includes a protrusion portion tc. A third sub-pixel 13 includes a fifth edge 13-1. The fifth edge 13-1 is located on one side of another edge of the third sub-pixel 13 close to the protrusion portion tc. The minimum distance between the protrusion portion tc and the third sub-pixel 13 is equal to the distance between the protrusion portion tc and the fifth edge 13-1.

As shown in FIG. 31, the first sub-pixel 11 includes a main portion zt and the protrusion portion tc. The main portion zt and the protrusion portion tc are arranged in the first direction Y. Moreover, the first sub-pixels 11 and the third sub-pixels 13 are arranged alternately in sequence in the first direction Y and the second direction X. The third sub-pixel 13 includes the fifth edge 13-1. The fifth edge 13-1 may be understood as an edge on one side of the third sub-pixel 13 closest to the protrusion portion of the sub-pixel including the protrusion portion. Since the third sub-pixels 13 and the first sub-pixels 11 are arranged alternately in the first direction Y, the minimum distance between the protrusion portion tc and the third sub-pixel 13 may be understood as the distance between the protrusion portion tc and the fifth edge 13-1. The arrangement in which the minimum distance between the protrusion portion tc and the third sub-pixel 13 is equal to the distance between the protrusion portion tc and the fifth edge 13-1 can guarantee that the transmission path of the leakage current between the sub-pixel including the protrusion portion and the third sub-pixel is relatively long and that the leakage current between two sub-pixels is relatively small.

On the basis of the preceding embodiments, with continued reference to FIG. 31, the main portion zt includes a first edge zt1, a second edge zt2, and a fourth edge zt3. The first edge zt1 and the second edge zt2 extend in the first direction Y and are arranged in the second direction X. The protrusion portion tc includes a third edge tc1. The third edge tc1 is connected to the same side of the first edge zt1 and the second edge zt2. The fourth edge zt3 is connected to the same side of the first edge zt1 and the second edge zt2. The display panel includes a sixth first sub-pixel 116, a seventh first sub-pixel 117, and a first third sub-pixel 131. The sixth first sub-pixel 116, the first third sub-pixel 131, and the seventh first sub-pixel 117 are arranged in sequence in the first direction Y or the second direction X. The first sub-pixel includes the protrusion portion tc. A third edge tc1 of the sixth first sub-pixel 116 and a fourth edge zt3 of the sixth first sub-pixel 116 are arranged in the first direction Y. A third edge tc1 of the seventh first sub-pixel 117 and a fourth edge zt3 of the seventh first sub-pixel 117 are arranged in the second direction X. The display panel further includes a fourth virtual line m5 and a fifth virtual line m6. The fourth virtual line m5 connects the center of the sixth first sub-pixel 116 and the center of the first third sub-pixel 131. The fifth virtual line m6 passes through the center of the seventh first sub-pixel 117 and is parallel to the fourth virtual line m5. An interval exists between the fourth virtual line m5 and the fifth virtual line m6.

As shown in FIG. 31, before the shape of the sub-pixel including the protrusion portion does not change, the center of the sixth first sub-pixel 116, the center of the first third sub-pixel 131, and the center of the seventh first sub-pixel 117 are located on the same virtual line. Since the shape of the sub-pixel including the protrusion portion changes, for example, since the shape of the sixth first sub-pixel 116 and the shape of the seventh first sub-pixel 117 are changed as shown, the shape of the sub-pixel including the protrusion portion is inwardly reduced at the position corresponding to the protrusion portion tc compared with the virtual shape 16. In this case, the center of the sub-pixel including the protrusion portion shifts towards one side away from the protrusion portion and towards one side facing the main portion zt. Therefore, an interval exists between the fifth virtual line m6 passing through the center of the sub-pixel including the protrusion portion and the fourth virtual line m5 connecting the center of the sixth first sub-pixel 116 and the center of the first third sub-pixel 131. Moreover, the distance is related to the shape of the protrusion portion tc. It is to be understood that the smaller the interval between the shape of the sub-pixel including the protrusion portion and the virtual shape 16, the smaller the distance between the fourth virtual line m5 and the fifth virtual line m6. The larger the interval between the shape of the sub-pixel including the protrusion portion and the virtual shape 16, the larger the distance between the fourth virtual line m5 and the fifth virtual line m5.

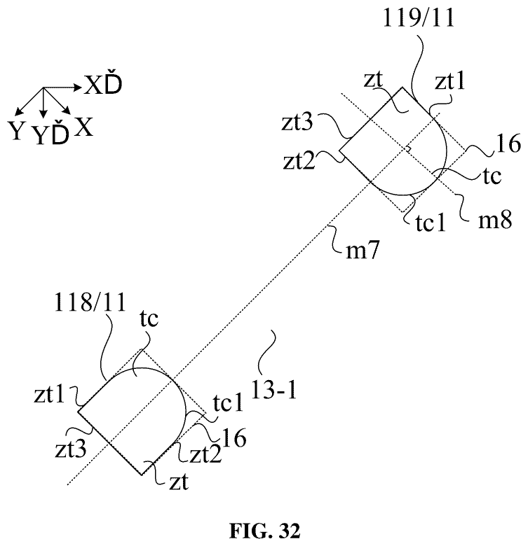

Optionally, FIG. 32 is a structural diagram of a first sub-pixel according to an embodiment of the present application. As shown in FIG. 32, a main portion comprises a first edge zt1, a second edge zt2, and a fourth edge zt4. The first edge zt1 and the second edge zt2 extend in the first direction Y and are arranged in the second direction X. A protrusion portion tc includes a third edge tc1. The third edge tc1 is connected to the same side of the first edge zt1 and the second edge zt2. The fourth edge zt3 is connected to the same side of the first edge zt1 and the second edge zt2. The first sub-pixels 11 include an eighth first sub-pixel 118 and a ninth first sub-pixel 119. The eighth first sub-pixel 118 and the ninth first sub-pixel 119 are arranged in the first direction Y or the second direction X. A first sub-pixel 11 includes the protrusion portion tc. A third edge tc1 of the eighth first sub-pixel 118 and a fourth edge zt3 of the eighth first sub-pixel 118 are arranged in the first direction Y. A third edge tc1 of the ninth first sub-pixel 119 and a fourth edge zt3 of the ninth first sub-pixel 119 are arranged in the second direction X. The display panel further includes a sixth virtual line m7 and a seventh virtual line m8. The center of the eighth first sub-pixel 118 is located on the sixth virtual line m7. The center of the ninth first sub-pixel 119 is located on the seventh virtual line m8. The sixth virtual line m7 is a central axis of the fourth edge zt3 of the eighth first sub-pixel 118. The seventh virtual line m8 is a central axis of the fourth edge zt3 of the ninth first sub-pixel 119. The sixth virtual line m7 is orthogonal to the seventh virtual line m8.

For example, before the shape of the sub-pixel including the protrusion portion does not change, the central axis of the fourth edge zt3 of the eighth first sub-pixel 118 is orthogonal to the central axis of the fourth edge zt3 of the ninth first sub-pixel 119. Since the shape of the sub-pixel including the protrusion portion changes, the shape of the sub-pixel including the protrusion portion is inwardly reduced at the position corresponding to the protrusion portion the compared with the virtual shape 16. In this case, the center of the sub-pixel including the protrusion portion shifts towards one side away from the protrusion portion and towards one side facing the main portion zt. However, in this case, the third edge tc1 of a protrusion portion tc of the eighth first sub-pixel 118 is symmetrical about the central axis of the fourth edge zt3 of the eighth first sub-pixel 118, and the third edge tc1 of a protrusion portion tc of the ninth first sub-pixel 119 is symmetrical about the central axis of the fourth edge zt3 of the ninth first sub-pixel 119. Therefore, in this case, the center of the eighth first sub-pixel 118 is also located on the central axis of the fourth edge zt3 of the eighth first sub-pixel 118, that is, the sixth virtual line m7; and the center of the ninth first sub-pixel 119 is located on the central axis of the fourth edge zt3 of the ninth first sub-pixel 119, that is, the seventh virtual line m8. However, because the arrangement manner of the fourth edge of the sub-pixel including the protrusion portion does not change, the central axis of the fourth edge zt3 of the eighth first sub-pixel 118 is still orthogonal to the central axis of the fourth edge zt3 of the ninth first sub-pixel 119. That is, the sixth virtual line m7 is orthogonal to the seventh virtual line m8.

It is to be noted that the preceding embodiments only describe an example in which the sub-pixel including the protrusion portion is a first sub-pixel. It is to be understood that the sub-pixel including the protrusion portion may also be a second sub-pixel. When the sub-pixel including the protrusion portion is a second sub-pixel, the preceding solutions about the arrangement of virtual lines are also applicable.

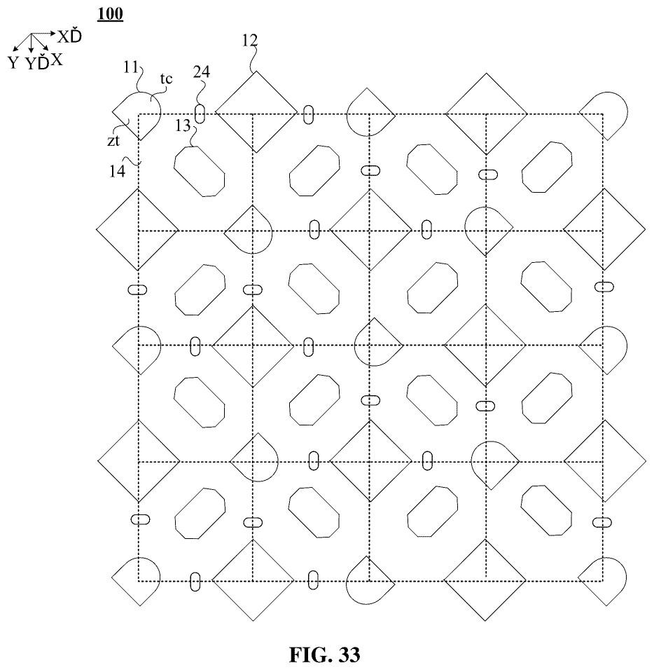

Optionally, FIG. 33 is a tenth structural diagram of a display panel according to an embodiment of the present application. Referring to FIGS. 3 and 33, the display panel provided in embodiments of the present application may further include a plurality of support columns 24. A support column 24 overlaps at least one virtual edge of a first virtual quadrangle 14 in the thickness direction of the display panel. The main portion zt includes a first edge zt1 and a second edge zt2. The first edge zt1 and the second edge zt2 extend in the first direction Y and are arranged in the second direction X. The protrusion portion tc includes a third edge tc1. The third edge tc1 is connected to the same side of the first edge zt1 and the second edge zt2. A virtual edge intersects the third edge tc1 of a first sub-pixel 11 or a second sub-pixel 12.

As shown in FIG. 33, the display panel provided in embodiments of the present application may further include the plurality of support columns 24 configured to support the display panel in the thickness direction, for example, to support a photomask in use in the evaporation process of part of the layers in the display panel. In an embodiment, in embodiments of the present application, a first sub-pixel 11 or a second sub-pixel 12 includes a protrusion portion tc which is inwardly reduced compared with the virtual shape 16. That is, in the sub-pixel including the protrusion portion, the minimum distance between the protrusion portion tc of the sub-pixel and another adjacent sub-pixel is larger than the minimum distance of the virtual shape 16 of the sub-pixel and another adjacent sub-pixel. Therefore, the support column 24 is disposed between the protrusion portion tc and an adjacent sub-pixel so that the station of the support column 24 is relatively far away from an opening region of the sub-pixel. On one hand, such an arrangement increases the arrangement freedom of the support column, reduces the process difficulty of the support column and the alignment accuracy in preparation, prevents the station of the support column from being excessively close to an opening of the sub-pixel due to the relatively small distance between adjacent sub-pixels, preventing the support column from easily falling into the opening region of the sub-pixel due to the squeeze of tools such as a mask in preparation, and prevents a display dark spot from being formed and affecting the yield. On the other hand, with no need to compress the area of the support column or compress the area of the support column to a relatively great degree, the good support effect of the support column is guaranteed. In an embodiment, the first virtual quadrangle 14 is constituted by connecting centers of two first sub-pixels 11 and two second sub-pixels 12. A virtual edge of the first virtual quadrangle 14 intersects a third edge of a first sub-pixel 11 or a third edge of a second sub-pixel 12; therefore, the distance between an opening region of the first sub-pixel 11 at the position of the virtual edge and an opening region of the second sub-pixel 12 at the position of the virtual edge is relatively large. Therefore, the arrangement in which the support column 24 overlaps at least one virtual edge of the first virtual quadrangle 14 in the thickness direction of the display panel, on one hand, reduces the process difficulty of the support column 24 and guarantee the support effect of the support column, and, on the other hand, guarantees that the arrangement of the support column slightly affects the opening region.

With continued reference to FIG. 33, a first sub-pixel 11 includes a protrusion portion tc. The minimum distance between the support column 24 and the first sub-pixel 11 is greater than the minimum distance between the support column 24 and a second sub-pixel 12.

As shown in FIG. 33, the support column 24 is disposed between the protrusion portion tc and an adjacent sub-pixel to support the photomask in use in the evaporation process of part of the layers in the display panel. Moreover, the arrangement of the support column 24 can be prepared and obtained by the mask process corresponding to the case where shapes of sub-pixels do not change. That is, for sub-pixels whose shapes do not change, the support column is disposed between two sub-pixels and has the same distance from the two sub-pixels. In this case, for the sub-pixel whose shape changes, that is, the sub-pixel including the protrusion portion, the protrusion portion which is inwardly reduced compared with the virtual shape due to the arrangement of the protrusion portion. Therefore, for the sub-pixel provided with the protrusion portion, the minimum distance between the support column 24 and the first sub-pixel 11 is greater than the minimum distance between the support column 24 and the second sub-pixel 12. Therefore, for the solution in which the minimum distance between the support column 24 and the first sub-pixel 11 is greater than the minimum distance between the support column 24 and the second sub-pixel 12, for example, when the minimum distance between the virtual shape of the sub-pixel including the protrusion portion and the support column is equal to the minimum distance between another sub-pixel including no protrusion portion and the support column, the original support column preparation process and the corresponding mask process can be applied, guaranteeing that the preparation process of the support column is simple with no need to replace the photomask and reducing the process cost of the support column.

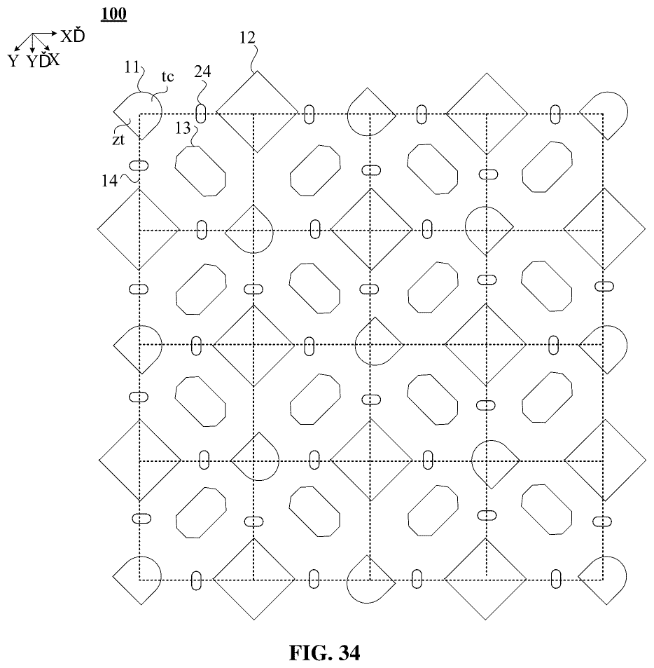

In an embodiment, FIG. 34 is an eleventh structural diagram of a display panel according to an embodiment of the present application. The difference between FIG. 34 and FIG. 33 lies in that a support column 24 overlaps at least three virtual edges of one of at least one first virtual quadrangle 14. Such an arrangement can further improve the support of the support column 24 for the photomask, provide more balanced support effect, and guarantee the good film-forming effect of a film evaporated by the photomask.

FIG. 35 is a twelfth structural diagram of a display panel according to an embodiment of the present application. FIG. 35 illustrates an example in which a second sub-pixel 12 includes a protrusion portion. As shown in FIG. 35, the minimum distance between a support column 24 and the second sub-pixel 12 is greater than the minimum distance between the support column 24 and a first sub-pixel 11. With this arrangement, the original support column preparation process and the corresponding mask process can be applied to the support column, guaranteeing that the preparation process of the support column is simple with no need to replace the photomask and reducing the process cost of the support column.

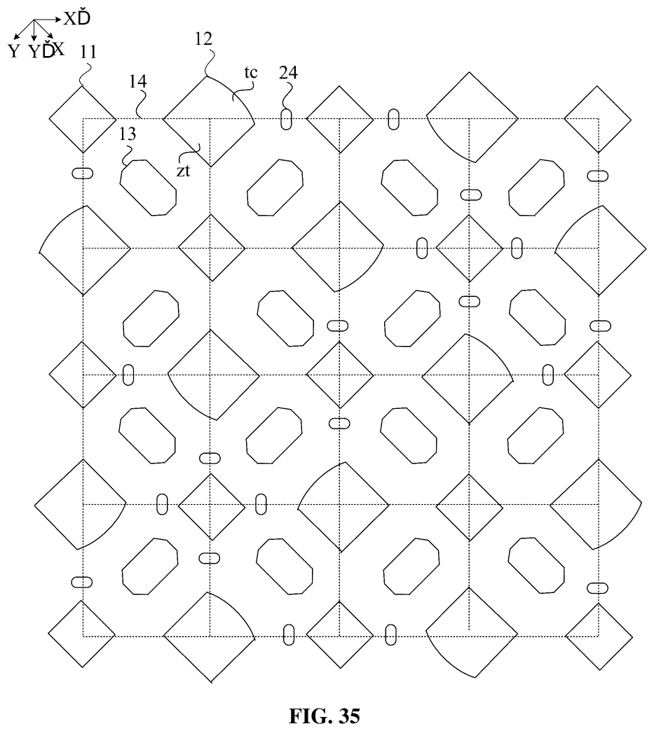

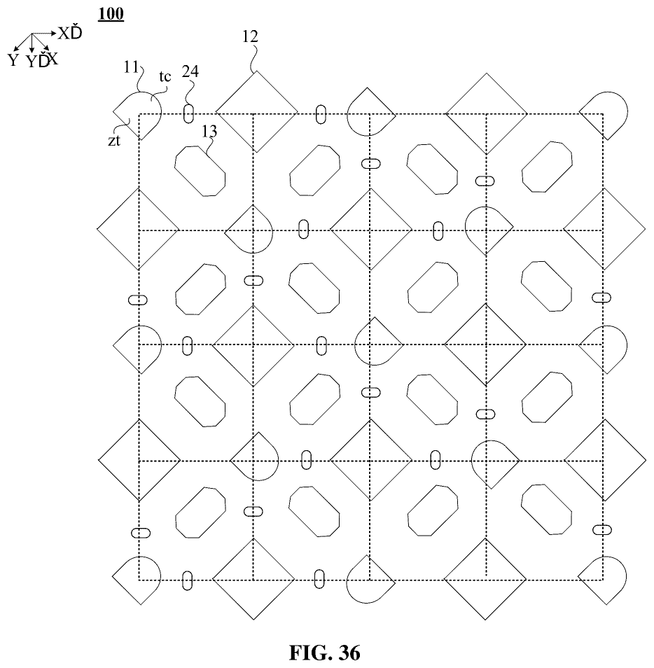

FIG. 36 is a thirteenth structural diagram of a display panel according to an embodiment of the present application. As shown in FIG. 36, a first sub-pixel 11 includes a protrusion portion tc. The minimum distance between a support column 24 and the first sub-pixel 11 is equal to the minimum distance between the support column 24 and a second sub-pixel 12. With this arrangement, the support column 24 is located in an intermediate region between the first sub-pixel 11 and the second sub-pixel 12. The distance between the support column 24 and the first sub-pixel 11 is the same as or similar to the distance between the support column 24 and the second sub-pixel 12. Such an arrangement can prevent the support column 24 from falling into an opening region of a certain sub-pixel due to the relatively small distance between the support column and the sub-pixel, guaranteeing the display effect of the display panel.

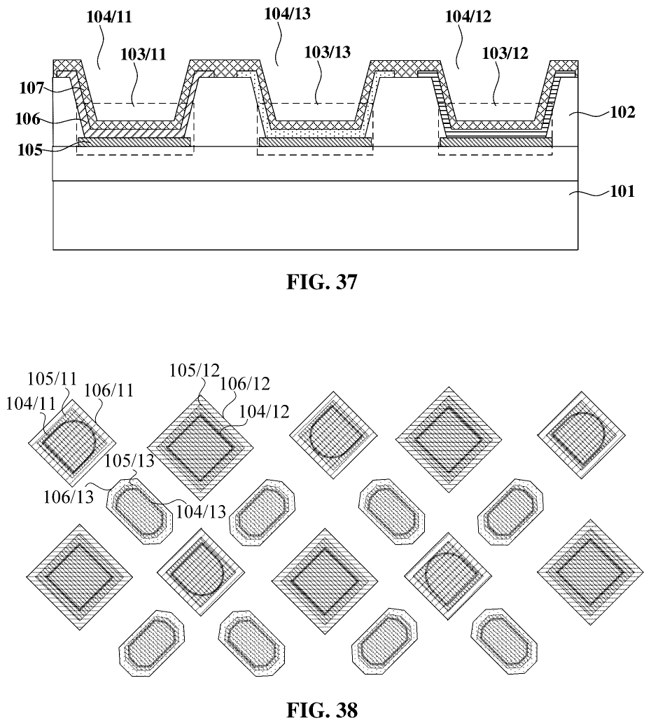

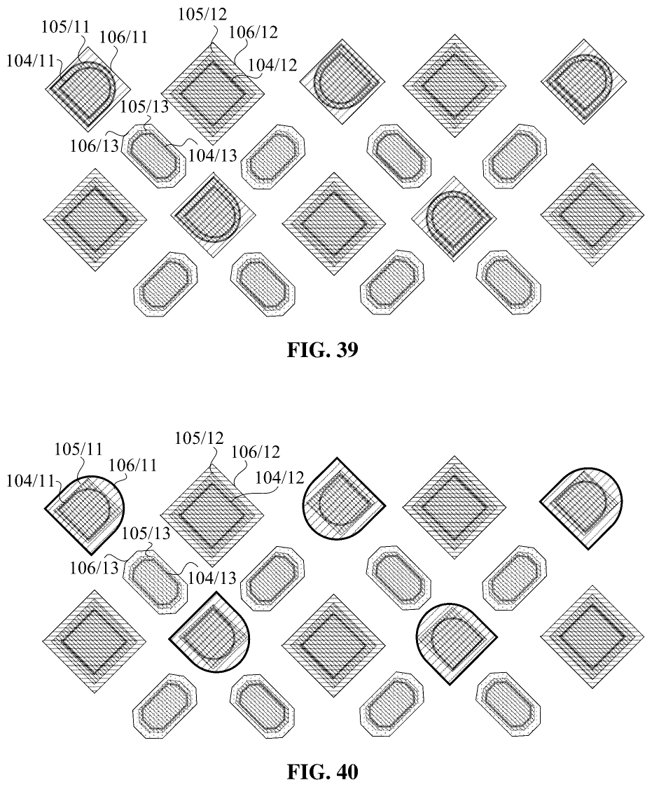

On the basis of the preceding embodiments, FIG. 37 is a first sectional view of the display panel shown in FIG. 2 taken along section line A-A′. FIG. 38 is a first diagram illustrating the arrangement manner of anode structures, pixel openings, and a light emission layer according to an embodiment of the present application. FIG. 39 is a second diagram illustrating the arrangement manner of anode structures, pixel openings, and a light emission layer according to an embodiment of the present application. As shown in FIGS. 37 to 39, the display panel 100 further includes a substrate 101, a pixel defining layer 102 located on one side of the substrate, and a plurality of light-emitting elements 103. The pixel defining layer 102 includes a plurality of pixel openings 104. A light-emitting element 103 includes a first electrode 105, a second electrode 107, and a light emission layer 106 located between the first electrode 105 and the second electrode 107. The light-emitting elements 103 include the first sub-pixels 11, the second sub-pixels 12, and the third sub-pixels 13. In a first sub-pixel 11 or second sub-pixel 12 including a protrusion portion, the shape of a light emission layer 106 is different from the shape of a pixel opening 104.

As shown in FIG. 37, the substrate 101 of the display panel includes a thin-film transistor array substrate. The pixel defining layer 102 is an insulating layer located on one side of the substrate 101. The pixel defining layer 102 is provided with the plurality of pixel openings 104. A region corresponding to a lower opening in a pixel opening 104 is a light emission region of a sub-pixel. A region other than the pixel openings 104 in the pixel defining layer 102 is a non-opening region configured to be provided with the support columns.

The pixel defining layer 102 and the plurality of light-emitting elements 103 are located on the same side of the substrate 101. The first electrode 105 in the light-emitting element 103 may be an anode, and the second electrode 107 in the light-emitting element 103 may be a cathode. However, it is not limited thereto. The position of an anode and the position of a cathode in other embodiments are not limited thereto. The light emission layer 106 is located between the first electrode 105 and the second electrode 107. The light emission layer 106 of a first sub-pixel 11 may be configured to include a red light-emitting material. The light emission layer 106 of a second sub-pixel 12 may be configured to include a blue light-emitting material. The light emission layer 106 of a third sub-pixel 13 may be configured to include a green light-emitting material. However, it is not limited thereto.

It is to be understood that a first function layer may be further included between the first electrode 105 of the light-emitting element 103 and the light emission layer 106 of the light-emitting element 103 and that a second function layer may be further included between the second electrode 107 of the light-emitting element 103 and the light emission layer 106 of the light-emitting element 103. If the first electrode 105 is an anode and the second electrode 107 is a cathode, the first function layer may include a hole injection layer and a hole transport layer, and the second function layer may include an electron transport layer and a hole blocking layer. Layer structures of the display panel further include, for example, a protective layer on one side of the second electrode 107 facing away from the first electrode 105, which is not specifically illustrated and described.

As shown in FIGS. 38 and 39, in the sub-pixel including the protrusion portion, the pixel opening 104 in the pixel defining layer 102 needs to include the protrusion portion. FIGS. 38 and 39 each illustrate an example in which the pixel opening 104 of a first sub-pixel 11 includes the protrusion portion. Moreover, for the sub-pixel including the protrusion portion, the shape of the first electrode 105 may be the same as the shape of the pixel opening 104, as shown in FIG. 39; and the shape of the first electrode 105 may be different from the shape of the pixel opening 104, as shown in FIG. 38.

For example, as shown in FIG. 38, a first electrode 105/11 is the first electrode 105 of the first sub-pixel 11. A pixel opening 104/11 is the pixel opening of the first sub-pixel 11. It is set that the shape of the first electrode 105/11 is different from the opening shape of the pixel opening 104/11. The shape of the first electrode 105/11 and the virtual shape of the first sub-pixel may be similar figures. The pixel opening 104/11 includes the protrusion portion, thereby guaranteeing that the light emission shape of the first sub-pixel includes the protrusion portion. Moreover, it is set that the shape of the first electrode 105/11 and the virtual shape of the first sub-pixel may be similar figures. That is, the shape of the first electrode 105/11 is not adjusted, thereby guaranteeing that the coupling capacitance between the first electrode 105/11 and the pixel circuit remains unchanged and that the display uniformity of the sub-pixel including the protrusion portion is relatively good.

For example, as shown in FIG. 39, the first electrode 105/11 is the first electrode 105 of the first sub-pixel 11. The pixel opening 104/11 is the pixel opening of the first sub-pixel 11. It is set that the shape of the first electrode 105/11 and the opening shape of the pixel opening 104/11 are similar figures. That is, the light emission shape of the first sub-pixel 11 is enabled to include the protrusion portion by designing the shape of the first electrode 105/11 and the pixel opening 104/11 at the same time. That is, the first electrode 105/11 and the pixel opening 104/11 each include a third sub-edge of a third edge of the first sub-pixel 11. The shape and radian of the third sub-edge may be basically the same as those of the third edge of the first sub-pixel 11. In this case, the third edge of the opening of the first sub-pixel 11 formed subsequently meets design requirements. On this basis, the same parameter and the same tools such as a mask may be applied to the preparation of the first electrode 105/11 and the pixel opening 104/11, thereby reducing production cost.

Referring to FIGS. 38 and 39, a first electrode 105/12 is the first electrode 105 of a second sub-pixel 12. A pixel opening 104/12 is the pixel opening of the second sub-pixel 12. Optionally, the shape of the first electrode 105/12 is basically the same as the shape of the pixel opening 104/12. A first electrode 105/13 is the first electrode 105 of a third sub-pixel 13. A pixel opening 104/13 is the pixel opening of the third sub-pixel 13. Optionally, the shape of the first electrode 105/13 is basically the same as the shape of the pixel opening 104/13.

In an embodiment, the shape of the light emission layer 106 is different from the shape of the pixel opening 104. Such an arrangement may include the shape of the light emission layer 106 in the sub-pixel including the protrusion portion is different from the shape of the pixel opening 104. That is, the shape of the light emission layer 106/11 is different from the shape of the pixel opening 104/11. Moreover, the shape of the light emission layer 106 in the sub-pixel including the protrusion portion and the shape of the virtual shape are similar figures. For example, the light emission layer 106 is prepared by evaporating the photomask. It is set that the shape of the light emission layer 106 in the sub-pixel including the protrusion portion and the shape of the virtual shape may be similar figures. With this arrangement, the existing photomask can be used for evaporation in the evaporation process of the light emission layer. That is, the photomask when the protrusion portion of the sub-pixel is inwardly reduced is used for evaporation. In this case, it is unnecessary to provide a separate photomask for the preparation of the light emission layer in the sub-pixel including the protrusion portion, reducing the cost of the mask. Especially in the case of high display resolution in existing display panels, high-precision masks are generally used in the evaporation process of light emission layers, making the cost of masks high. The shape of the light emission layer 106 is set to be different from the shape of the pixel opening 104, and the shape of the light emission layer 106 in the sub-pixel including the protrusion portion and the shape of the virtual shape are further set to be similar figures. With this arrangement, when the light emission layer in the sub-pixel including the protrusion portion is evaporated, the existing photomask art can be adopted so that the photomask does not need to be replaced, reducing the cost of the mask.

It is to be noted that the shape of the pixel opening 104 is the same as the shape of the sub-pixel including the protrusion portion. Therefore, the case where the shape of the light emission layer in the sub-pixel including the protrusion portion is not the same as the shape of the pixel opening may not affect the final light emission shape of the sub-pixel.

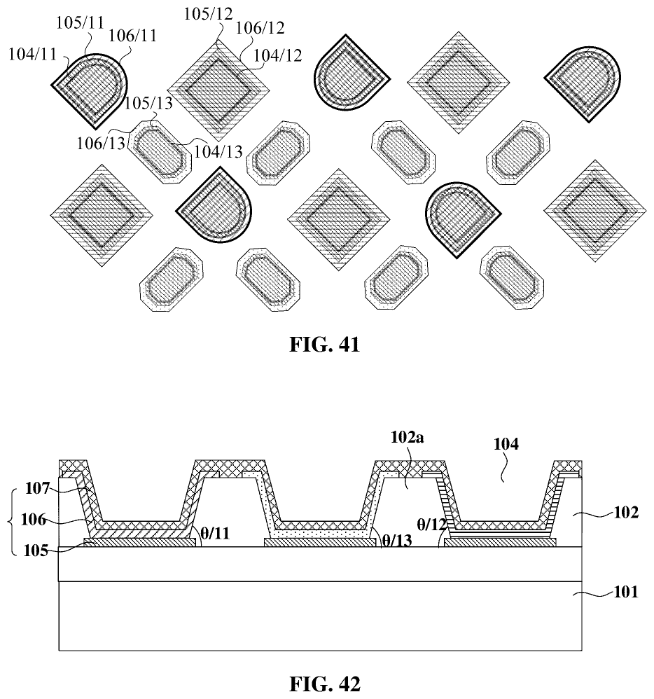

Optionally, FIG. 40 is a third diagram illustrating the arrangement manner of anode structures, pixel openings, and a light emission layer according to an embodiment of the present application. FIG. 41 is a fourth diagram illustrating the arrangement manner of anode structures, pixel openings, and a light emission layer according to an embodiment of the present application. Referring to FIGS. 37, 40, and 41, the display panel 100 further includes a substrate 101, a pixel defining layer 102 located on one side of the substrate, and a plurality of light-emitting elements 103. The pixel defining layer 102 includes a plurality of pixel openings 104. A light-emitting element 103 includes a first electrode 105, a second electrode 107, and a light emission layer 106 located between the first electrode 105 and the second electrode 107. The light-emitting elements 103 include the first sub-pixels 11, the second sub-pixels 12, and the third sub-pixels 13. In a first sub-pixel 11 or second sub-pixel 12 including a protrusion portion, the shape of a light emission layer 106 is approximately the same as the shape of a pixel opening 104. For example, the arrangement in which the shape of the light emission layer 106 is approximately the same as the shape of the pixel opening 104 may be understood as that the shape of the light emission layer 106 and the shape of the pixel opening 104 are similar figures. For example, the shape of the light emission layer 106 is similar to the shape of the pixel opening of the sub-pixel including the protrusion portion. The light emission layer also includes a light emission main portion and a light emission protrusion portion. The light emission main portion corresponds to a main portion of the pixel opening. The light emission protrusion portion corresponds to a protrusion portion of the pixel opening. Moreover, in the case where the shape of the light emission layer 106 is approximately the same as the shape of the pixel opening 104, it may be set that the area of the light emission layer 106 is larger than the area of the pixel opening 104. Such an arrangement guarantees that the coverage effect of the light emission layer 106 is the same at different edge positions of the pixel opening 104, guaranteeing that different edge positions of the pixel opening 104 are covered by the light emission layer 106 to the same degree, guaranteeing the balanced display effect of the sub-pixel, and avoiding display difference among different regions of the pixel opening due to the fact that a partial region is not covered by the light emission layer or that coverage conditions of the light emission layer are different in different regions.

In an embodiment, as shown in FIG. 40, on the premise that the shape of the light-emitting layer 106 is approximately the same as the shape of the pixel opening 104, it may be set that in the sub-pixel including the protrusion portion, the shape of the first electrode 105 is different from the shape of the pixel opening 104. By way of example, a first sub-pixel is the sub-pixel including the protrusion portion. The shape of the first electrode 105/11 is different from the shape of the pixel opening 104/11. The shape of the first electrode 105/11 and the shape of the first sub-pixel may be similar figures. The pixel opening 104/11 includes the protrusion portion, thereby guaranteeing that the light emission shape of the first sub-pixel includes the protrusion portion. Moreover, it is set that the shape of the first electrode 105/11 and the virtual shape of the first sub-pixel may be similar figures. That is, the shape of the first electrode 105/11 is not adjusted, thereby guaranteeing that the coupling capacitance between the first electrode 105/11 and the pixel circuit remains unchanged and that the display uniformity of the sub-pixel including the protrusion portion is relatively good.

In an embodiment, as shown in FIG. 41, on the premise that the shape of the light emission layer 106 is approximately the same as the shape of the pixel opening 104, it may be set that in the sub-pixel including the protrusion portion, the shape of the first electrode 105 is approximately the same as the shape of the pixel opening 104. By way of example, a first sub-pixel is the sub-pixel including the protrusion portion. The first electrode 105/11 is the first electrode 105 of the first sub-pixel 11. The pixel opening 104/11 is the pixel opening of the first sub-pixel 11. It is set that the shape of the first electrode 105/11 and the opening shape of the pixel opening 104/11 are similar figures. That is, the light emission shape of the first sub-pixel 11 is enabled to include the protrusion portion by designing the shape of the first electrode 105/11 and the pixel opening 104/11 at the same time. That is, the first electrode 105/11 and the pixel opening 104/11 each include a third sub-edge of a third edge of the first sub-pixel 11. The shape and radian of the third sub-edge may be basically the same as those of the third edge of the first sub-pixel 11. In this case, the third edge of the opening of the first sub-pixel 11 formed subsequently meets design requirements. On this basis, the same parameter and the same tools such as a mask may be applied to the preparation of the first electrode 105/11 and the pixel opening 104/11, thereby reducing production cost.

Optionally, FIG. 42 is a second sectional view of the display panel shown in FIG. 2 taken along section line A-A′. As shown in FIG. 42, optionally, the display panel includes a substrate 101, a pixel defining layer 102 located on one side of the substrate, and a plurality of light-emitting elements 103. The pixel defining layer 102 includes pixel openings 104 and bank portions 102a. A light-emitting element 104 is disposed in a pixel opening 104. A bank portion 102a includes a side surface and a bottom surface on one side facing the substrate 101. An included angle θ formed between the side surface and the bottom surface is an acute angle. The included angle θ differs according to positions. In this embodiment, the pixel defining layer 102 includes the plurality of pixel openings 104 and the bank portions 102a. For one pixel opening 104, a bank portion 102a surrounds the pixel opening 104. In the thickness direction of the display panel, the pixel opening 104 includes an upper opening and a lower opening. The lower opening of the pixel opening 104 faces a light emission layer 106, and the upper opening faces away from the light emission layer 106. Therefore, the cross-sectional shape of the pixel opening 104 in the thickness direction of the display panel may be an inverted trapezoid. That is, the upper opening of the pixel opening 104 may be larger than the lower opening of the pixel opening 104. Moreover, considering that the pixel opening 104 is generally etched from one side of the pixel defining layer 102 facing away from the substrate 101, the opening on an upper surface is relatively large and the opening on a lower surface is relatively small during the etching process in general. Therefore, the arrangement manner of the pixel opening 104 matches the preparation process of the pixel opening 104.

The bank portion 102a includes a top surface, a bottom surface, and a side surface connecting the top surface and the bottom surface. Based on the shape of an inverted trapezoid of the pixel opening 104, the cross-sectional shape of the bank portion 102a in the thickness direction of the display panel is a normal trapezoid. With this arrangement, the included angle θ between the side surface of the bank portion 102a and the bottom surface of the bank portion 102a is an acute angle.

In the display panel, a first sub-pixel 11, a second sub-pixel 12, and a third sub-pixel 13 are different in the area and shape. Therefore, considering the opening area and opening shape of each sub-pixel and the process of each pixel opening, θs of bank portions 102a adjacent to different sub-pixels may be different. θ/11 is one included angle 0 of a bank portion 102a adjacent to a first sub-pixel 11. θ/12 is one included angle θ of a bank portion 102a adjacent to a second sub-pixel 12. θ/13 is one included angle θ of a bank portion 102a adjacent to a third sub-pixel 13. θ/11, θ/12, and θ/13 may be different. Additionally, included angles θ at different positions of a bank portion 102a adjacent to the same sub-pixel may also be different, which is not repeated here.

On the basis of the preceding embodiments, the main portion zt includes a first edge zt1 and a second edge zt2. The first edge zt1 and the second edge zt2 extend in the first direction Y and are arranged in the second direction X. The protrusion portion tc includes a third edge tc1. The third edge tc1 is connected to the same side of the first edge zt1 and the second edge zt2. The included angle includes a first included angle between the first edge and the bottom surface and a second included angle between the third edge and the bottom surface. The first included angle θ1 and the second included angle θ2 satisfy that θ2≥θ1.

Referring to FIGS. 2 and 42, a region surrounded by the first edge zt1, the second edge zt2, the third edge tc1 and the fourth edge zt3 of the sub-pixel including the protrusion portion is the lower opening of the sub-pixel including the protrusion portion. Therefore, the edge of the bottom surface of a bank portion 102a overlaps the first edge zt1, the second edge zt2, the third edge tc1 and the fourth edge zt3 of the sub-pixel including the protrusion portion. The first edge zt1 of the sub-pixel including the protrusion portion is a straight line segment. 01 is the included angle between the side surface of the bank portion 102a and the first edge zt1 of the sub-pixel including the protrusion portion. The third edge tc1 of the sub-pixel including the protrusion portion is composed of multiple sub-segments. 02 is the included angle between the side surface of the bank portion 102a and the third edge tc1 of the sub-pixel including the protrusion portion.

For example, the larger the radian of an edge of the sub-pixel including the protrusion portion, the larger the included angle between the side surface of the bank portion 102a and the edge. The first edge zt1 of the sub-pixel including the protrusion portion is a straight line segment. The third edge tc1 of the sub-pixel including the protrusion portion is composed of multiple sub-segments. Therefore, it is set that the included angle θ2 between the side surface of the bank portion 102a of the sub-pixel including the protrusion portion and the third edge tc1 is larger than the included angle θ1 between the side surface of the bank portion 102a of the sub-pixel including the protrusion portion and the first edge zt1. The reason lies in that when an opening of the pixel defining layer is formed, an exposure operation needs to be performed through the mask and that light forms interference fringes during exposure. When the light passes through a straight edge of the mask, the formed interference fringes are sparse, and the corresponding exposure is small. When the light passes through an edge of the mask with a relatively large radian, the formed interference fringes are denser, and the corresponding exposure is larger. The larger the exposure, the less the residue such as photoresist exists at a corresponding position. The more the etching during development, the larger the radian of an edge of the formed opening, and the larger the included angle between the side of the bank portion and the edge of the opening.

In an embodiment, due to the difference in the included angle between the side surface of the bank portion 102a and the bottom surface of the bank portion 102a, the bank portion 102a has different blocking effects for the light of a large viewing angle in the sub-pixels. For example, the greater the included angle between the side surface of the bank portion 102a and the bottom surface of the bank portion 102a, the more obvious the blocking effect on the light of a large viewing angle. In this case, the emission of the light of a large viewing angle may be reduced to alleviate the color deviation caused by the emission of the light of a large viewing angle, improving the display effect of the display panel. Combined with the sub-pixel including the protrusion portion in embodiments of the present application, as mentioned above, the included angle θ1 between the first edge of the main portion in the sub-pixel including the protrusion portion and the bottom surface and the included angle θ2 between the third edge of the protrusion portion and the bottom surface satisfy that θ2>θ1. That is, the included angle between the side surface of the bank portion corresponding to the edge of the protrusion portion and the bottom surface of the bank portion is relatively large. In this case, the bank portion corresponding to the edge of the protrusion portion can block relatively much light of a large viewing angle so as to alleviate the color deviation caused by the emission of the light of a large viewing angle, improving the display effect of the sub-pixel including the protrusion portion and thereby improving the display effect of the entire display panel.

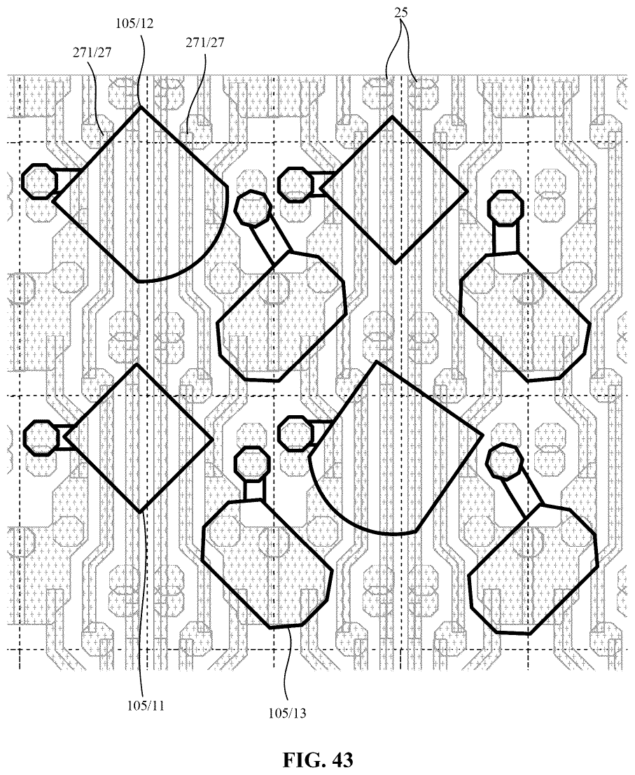

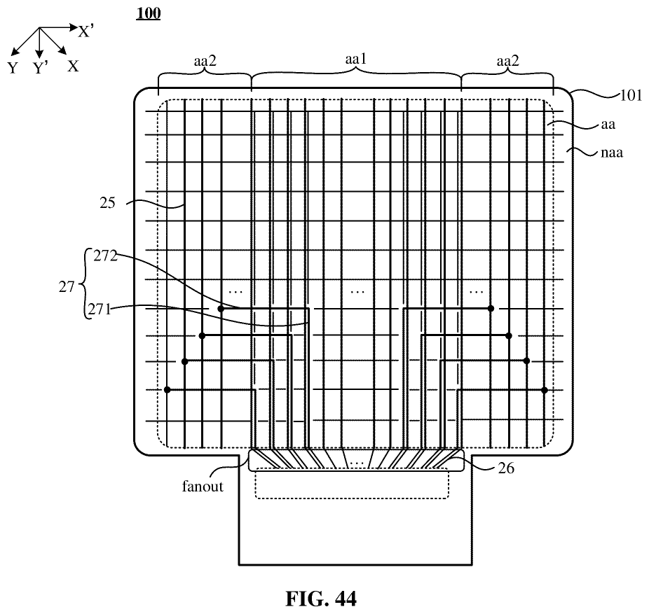

Optionally, FIG. 43 is a fourteenth structural diagram of a display panel according to an embodiment of the present application. FIG. 44 is a fifteenth structural diagram of a display panel according to an embodiment of the present application. Referring to FIGS. 43 and 44, the display panel 100 further includes a display region aa. The display region aa includes a plurality of data lines 25 arranged in the third direction X′ and extending in the fourth direction Y′. The third direction X′ intersects the fourth direction Y′. The third direction X′ intersects the first direction Y and the second direction X. The fourth direction Y′ intersects the first direction Y and the second direction X. The display region aa further includes a substrate 101 and a plurality of light-emitting elements 103 located on one side of the substrate. A light-emitting element 103 a first electrode 105. A first electrode 105 of a first sub-pixel 11 and a first electrode 105 of a second sub-pixel 12 each overlap two data lines 25 in the direction perpendicular to a plane where the substrate 101 is located.

In this embodiment, the display panel includes the display region aa and a non-display region naa. The display region aa is provided with a plurality of sub-pixels, which are at least the plurality of first sub-pixels 11, the plurality of second sub-pixels 12, and the plurality of third sub-pixels 13. The non-display region naa is provided with a driver circuit structure configured to drive the sub-pixels in the display region aa for display.

The display region aa includes the plurality of data lines 25 arranged in the third direction X′ and extending in the fourth direction Y′. The first electrode 105 of the first sub-pixel 11 and the first electrode 105 of the second sub-pixel 12 each overlap two data lines 25 in the direction perpendicular to the plane where the substrate 101 is located. One of the data lines 25 is configured to supply data signals to the first electrode 105 of the first sub-pixel 11 and the first electrode 105 of the second sub-pixel 12 that overlap the data line 25. The other of the data lines 25 is configured to supply data signals to a first electrode 105/13 of an adjacent third sub-pixel 13. The first electrode 105 of the first sub-pixel 11 and the first electrode 105 of the second sub-pixel 12 each overlap two data lines 25. In the first aspect, the arrangement of the two data lines 25 can provide a relatively flat arrangement environment for the first electrode 105 of the first sub-pixel 11 and the first electrode 105 of the second sub-pixel 12, guarantee that the arrangement surface of the first electrode 105 of the first sub-pixel 11 and the arrangement surface of the first electrode 105 of the second sub-pixel 12 are relatively flat, and guarantee that the first electrode 105 of the first sub-pixel 11 and the first electrode 105 of the second sub-pixel 12 that are formed subsequently are relatively flat, thereby improving the display effect of sub-pixels and avoiding the display problem caused by the light path difference due to an uneven first electrode 105. In the second aspect, the two data lines 25 are disposed under the first electrode 105 of the first sub-pixel 11 and the first electrode 105 of the second sub-pixel 12. Such an arrangement can guarantee that the data lines 25 are arranged to be relatively dense so as to leave more space in other positions, helping improve the light transmittance of the display panel and implementing the transparent display of the display panel. Alternatively, more imaging light is provided for an under-screen camera, guaranteeing the imaging effect of the under-screen camera. In the third aspect, the first electrode 105 of the first sub-pixel 11 and the first electrode 105 of the second sub-pixel 12 each overlap the two data lines 25, guaranteeing that the data lines 25 overlap each first electrode 105. This is equivalent to that each first electrode 105 can cover part of the data lines 25, preventing the data lines of a metal material from changing the transmission direction of light and also guaranteeing the display effect of the display panel 100.

In an embodiment, as shown in FIG. 43, the display region aa further includes other circuit structures, such as power signal lines 28 configured to supply power signals for sub-pixels and guarantee the normal light emission of sub-pixels. Moreover, as shown in FIG. 43, a power signal line 28 may include a relatively large signal portion 281. A first electrode 105/13 of a third sub-pixel 13 overlaps the signal portion 281 in the thickness direction of the display panel. In the first aspect, the signal portion 281 can provide a relatively flat arrangement environment for the first electrode 105/13 of the third sub-pixel 13, guarantee that the arrangement surface of the first electrode 105/13 of the third sub-pixel 13 is relatively flat, and guarantee that the first electrode 105/13 of the third sub-pixel 13 formed subsequently is relatively flat, thereby improving the display effect of sub-pixels and avoiding the display problem caused by the light path difference due to the uneven first electrode 105/13. In the second aspect, the signal portion 281 is arranged under the first electrode 105/13 of the third sub-pixel 13. Such an arrangement can leave more space in other positions, helping improve the light transmittance of the display panel and implementing the transparent display of the display panel. Alternatively, more imaging light is provided for the under-screen camera, guaranteeing the imaging effect of the under-screen camera. In the third aspect, the first electrode 105/13 of the third sub-pixel 11 overlaps the signal portion 281, guaranteeing that the first electrode 105 overlaps the signal portion 281. This is equivalent to that the first electrode 105 can cover part of the signal portion 281, preventing the power signal line 28 of a metal material from changing the transmission direction of light and also guaranteeing the display effect of the display panel 100.

On the basis of the preceding embodiments, with continued reference to FIG. 40, the display panel includes the non-display region naa. The non-display region naa includes a fan-out region fanout located on one side of the display region aa in the fourth direction Y′. The display region aa includes a first display region aa1 and a second display region aa2. The second display region aa2 is located on at least one side of the first display region aa1 in the third direction X′. The fan-out region fanout includes a plurality of fan-out wires 26. The first display region aa1 and the second display region aa2 each include multiple data lines 25. A data line 25 is connected to a fan-out wire 26. A data line 25 in the second display region aa2 is connected to a respective fan-out wire 26 through a connection wire 27. The connection wire 27 is located in the display region aa and includes a first connection line segment 271 extending in the fourth direction Y′ and a second connection line segment 272 extending in the third direction X′. The first electrode of a first sub-pixel 11 and the first electrode of a second sub-pixel 12 each overlap two first connection line segments 271 in the direction perpendicular to the plane where the substrate is located.

For example, as shown in FIG. 44, the display panel 10 includes the display region aa and the non-display region naa. The display region aa includes, for example, light-emitting elements (not shown) and data lines 25 connected to the light-emitting elements to implement the display function of the display panel 100. The non-display region naa includes a display controller, such as a drive chip (not shown), connected to the data lines and provides display signals for the data lines through the display controller so as to drive the display panel 100 to achieve the display function. The non-display region naa surrounds at least part of the display region aa based on the specific position of the display region aa and the specific position of the non-display region naa, which is not specifically limited in embodiments of the present application.

In an embodiment, referring to FIG. 44, the non-display region naa includes the fan-out region fanout. The fan-out region fanout includes the plurality of fan-out wires 26. The fan-out wires 26 are electrically connected to the plurality of data lines 25, guaranteeing the stable transmission of data signals.

For example, the display region aa includes the first display region aa1 and the second display region aa2. The second display region aa2 is located on two sides of the first display region aa1 in the third direction X′. Compared with the first display region aa1, the second display region aa2 is closer to a boundary of the display region aa. A data line 25 in the first display region aa1 may be electrically connected to a respective fan-out wire 26 directly. A data line 25 in the second display region aa2 is connected to a respective fan-out wire 26 through a connection wire 27. Such an arrangement can reduce the occupation space of the fan-out wires 26, thereby reducing the arrangement area of the fan-out region fanout, effectively reducing the ratio of the non-display region naa, increasing the ratio of the display region aa in the display panel 100, increasing the display area of the display panel 100, and improving user experience.

For example, a connection wire 27 includes a first connection line segment 271 and a second connection line segment 272. The first connection line segment 271 extends in the fourth direction Y′. The second connection line segment 272 extends in the third direction X′. The first connection line segment 271 is electrically connected to the second connection line segment 272 and a data line 25 in the second display region aa2. That is, it guarantees that the electrical connection between the data line 25 in the second display region aa2 and a fan-out wire 26 is implemented through the connection wire 27. In an embodiment, the first electrode 105/11 of the first sub-pixel 11 and the first electrode 105/12 of the second sub-pixel 12 each overlap two first connection line segments 271 in the direction perpendicular to the plane where the substrate is located. In the first aspect, the arrangement of the two first connection line segments 271 can provide a relatively flat arrangement environment for the first electrode 105 of the first sub-pixel 11 and the first electrode 105 of the second sub-pixel 12, guarantee that the arrangement surface of the first electrode 105 of the first sub-pixel 11 and the arrangement surface of the first electrode 105 of the second sub-pixel 12 are relatively flat, and guarantee that the first electrode 105 of the first sub-pixel 11 and the first electrode 105 of the second sub-pixel 12 that are formed subsequently are relatively flat, thereby improving the display effect of sub-pixels and avoiding the display problem caused by the light path difference due to an uneven first electrode 105. In the second aspect, the two first connection line segments 271 are disposed under the first electrode 105 of the first sub-pixel 11 and the first electrode 105 of the second sub-pixel 12. Such an arrangement can guarantee that the first connection line segments 271 are arranged to be relatively dense so as to leave more space in other positions, helping improve the light transmittance of the display panel and implementing the transparent display of the display panel. Alternatively, more imaging light is provided for the under-screen camera, guaranteeing the imaging effect of the under-screen camera. In the third aspect, the first electrode 105 of the first sub-pixel 11 and the first electrode 105 of the second sub-pixel 12 each overlap the two first connection line segments 271, guaranteeing that the first connection line segments 271 overlap each first electrode 105. This is equivalent to that each first electrode 105 can cover part of the first connection line segments 271, preventing the data lines of a metal material from changing the transmission direction of light and also guaranteeing the display effect of the display panel 100.

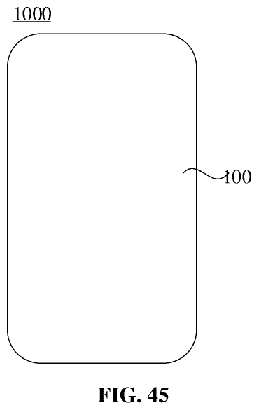

Based on the same inventive concept, embodiments of the present application further provide a display device. The display device includes any display panel provided in the preceding embodiments. Exemplarily, as shown in FIG. 45, the display device 1000 includes a display panel 100. Therefore, the display device also has the beneficial effects of the display panel described in the preceding embodiments, and for the same details, reference may be made to the description of the preceding display panel, and repetition will not be made herein.

The display device 1000 provided in embodiments of the present application may be the phone shown in FIG. 45 or may be any electronic product with a display function, including and not limited to: televisions, laptops, desktop displays, tablet computers, digital cameras, smart bracelets, smart glasses, in-vehicle displays, industry-controlling equipment, medical displays, touch interactive terminals, etc., which will not be specifically limited in embodiments of the present application.

It is to be noted that the above are only preferred embodiments of the present application and the principles used therein. It will be understood by those skilled in the art that the present application is not limited to the embodiments described herein. Those skilled in the art can make various apparent variations, adaptions, and substitutions without departing from the scope of the present application. Therefore, while the present application has been described in detail via the preceding embodiments, the present application is not limited to the preceding embodiments and may include more other equivalent embodiments without departing from the concept of the present application. The scope of the present application is determined by the scope of the appended claims.

What is claimed is:

1. A display panel, comprising a plurality of first sub-pixels, a plurality of second sub-pixels, and a plurality of third sub-pixels, wherein
multiple first sub-pixels among the plurality of first sub-pixels and multiple second sub-pixels among the plurality of second sub-pixels constitute a first virtual quadrangle, a center of one of the multiple first sub-pixels is located at a first vertex of the first virtual quadrangle, a center of one of the multiple second sub-pixels is located at a second vertex of the first virtual quadrangle, the first vertex and the second vertex alternate and are spaced apart, and one third sub-pixel among the plurality of third sub-pixels is located inside the first virtual quadrangle; and
multiple third sub-pixels among the plurality of third sub-pixels constitute a second virtual quadrangle, centers of the multiple third sub-pixels are each located at a vertex of the second virtual quadrangle, and one of the plurality of first sub-pixels or one of the plurality of second sub-pixels is located inside the second virtual quadrangle; wherein a first sub-pixel among the plurality of first sub-pixels or a second sub-pixel among the plurality of second sub-pixels comprises a main portion and a protrusion portion, and the protrusion portion is located on one side of the main portion in a first direction; and
a length of the protrusion portion is X1 in the first direction, and a length of the main portion and a length of the protrusion portion are each X2 in a second direction, wherein 0<X1<X2/2, and the second direction intersects the first direction.

2. The display panel according to claim 1, wherein 5%≤X1/X2≤30%.

3. The display panel according to claim 1, wherein the main portion comprises a first edge and a second edge, the first edge and the second edge extend in the first direction and are arranged in the second direction, the protrusion portion comprises a third edge, and the third edge is connected to a same side of the first edge and the second edge; and
the third edge comprises a first sub-segment and a second sub-segment, the first sub-segment is connected to the first edge, the second sub-segment is connected to the second edge, a maximum included angle between one side of the first sub-segment facing the second edge and the first edge is α1, and a maximum included angle between one side of the second sub-segment facing the first edge and the second edge is α2, wherein 100°≤α1≤150°, and 100°≤α2≤150°.

4. The display panel according to claim 3, wherein an end point on one side of the first sub-segment away from the second sub-segment, an end point on one side of the first sub-segment close to the second sub-segment, an end point on one side of the second sub-segment close to the first sub-segment, and an end point on one side of the second sub-segment away from the first sub-segment are located on a same virtual circle.

5. The display panel according to claim 4, wherein the virtual circle is a circumcircle of a sub-pixel comprising the protrusion portion.

6. The display panel according to claim 4, wherein the first sub-pixel comprises the protrusion portion, a partial region of the virtual circle is located inside the first sub-pixel, and a remaining region of the virtual circle is located outside the first sub-pixel; or
the second sub-pixel comprises the protrusion portion, a partial region of the virtual circle is located inside the second sub-pixel, and a remaining region of the virtual circle is located outside the second sub-pixel.

7. The display panel according to claim 4, wherein the first sub-segment and the second sub-segment are each arcuate, and the first sub-segment and the second sub-segment each coincide with a circumference of the virtual circle.

8. The display panel according to claim 4, wherein the third edge further comprises a third sub-segment, and the third sub-segment is connected to the first sub-segment and the second sub-segment; and
the third sub-segment is a straight line segment, a connection point between the third sub-segment and the first sub-segment is located on a circumference of the virtual circle, and a connection point between the third sub-segment and the second sub-segment is located on the circumference of the virtual circle.

9. The display panel according to claim 8, wherein at least one of the first sub-segment or the second sub-segment is arcuate.

10. The display panel according to claim 8, wherein at least one of the first sub-segment or the second sub-segment is a straight line segment.

11. The display panel according to claim 8, wherein the main portion further comprises a fourth edge opposite to the third edge, and the fourth edge is connected to a same side of the first edge and the second edge; and
a length of the third sub-segment is X3, and a length of the fourth edge is X4, wherein 0<X3≤X4/2.

12. The display panel according to claim 11, wherein 5%≤X3/X4≤40%.

13. The display panel according to claim 3, wherein a virtual shape of a sub-pixel including the protrusion portion constitutes a first virtual parallelogram; the first virtual parallelogram has a first virtual edge, a second virtual edge, and a third virtual edge; and
the third virtual edge is connected to a same side of the first virtual edge and the second virtual edge;
the first virtual edge partially coincides with the first edge;
the second virtual edge partially coincides with the second edge; and
an end point on one side of the first sub-segment close to the second sub-segment and an end point on one side of the second sub-segment close to the first sub-segment are each located on the third virtual edge.

14. The display panel according to claim 13, wherein the first sub-segment is connected to the second sub-segment, a connection point between the first sub-segment and the second sub-segment is located on the third virtual edge, and the third virtual edge is tangent to the third edge at the connection point.

15. The display panel according to claim 13, wherein a first tangent line of any point on the first sub-segment intersects the third virtual edge at a first intersection point, and an included angle between the third virtual edge located on one side of the first intersection point close to the first virtual edge and the first tangent line is α3, wherein θ°≤α3<90°; and
a second tangent line of any point on the second sub-segment intersects the third virtual edge at a second intersection point, and an included angle between the third virtual edge located on one side of the second intersection point close to the second virtual edge and the second tangent line is α4, wherein θ°≤α4<90°.

16. The display panel according to claim 3, wherein a virtual shape of a sub-pixel including the protrusion portion constitutes a first virtual parallelogram, the first virtual parallelogram comprises a first virtual axis, a center of the first virtual parallelogram is located on the first virtual axis, and the first virtual axis intersects the third edge; and
the first sub-segment and the second sub-segment are symmetric about the first virtual axis.

17. The display panel according to claim 16, wherein the third edge further comprises a third sub-segment, and the third sub-segment is connected to the first sub-segment and the second sub-segment; and
the third sub-segment intersects the first virtual axis, and a midpoint of the third sub-segment is located on the first virtual axis.

18. The display panel according to claim 16, further comprising a touch electrode located on a light emission side of sub-pixels, wherein
the touch electrode comprises a first touch grid line and a second touch grid line, an extension direction of the first touch grid line and an extension direction of the second touch grid line are each same as an extension direction of the first virtual axis, the first sub-segment and the first touch grid line are located on a same side of the first virtual axis, and the second sub-segment and the second touch grid line are located on a same side of the first virtual axis;
the first sub-segment comprises a first point, the second sub-segment comprises a second point, the first point and the second point are symmetric about the first virtual axis, the first touch grid line comprises a third point, the second touch grid line comprises a fourth point, and the third point and the fourth point are symmetric about the first virtual axis; and
a distance between the first point and the third point is a first distance, a distance between the second point and the fourth point is a second distance, and a difference between the first distance and the second distance is within a preset range.

19. The display panel according to claim 3, wherein a virtual shape of a sub-pixel including the protrusion portion constitutes a first virtual parallelogram, the first virtual parallelogram comprises a first virtual axis, a center of the first virtual parallelogram is located on the first virtual axis, and the first virtual axis intersects the third edge; and
the first sub-segment and the second sub-segment are asymmetric about the first virtual axis.

20. The display panel according to claim 19, wherein the third edge further comprises a third sub-segment, and the third sub-segment is connected to the first sub-segment and the second sub-segment; and
the third sub-segment intersects the first virtual axis, and a midpoint of the third sub-segment is not located on the first virtual axis.

21. The display panel according to claim 1, wherein area of the protrusion portion is S1, and area of the main portion is S2, wherein 1/40≤S1/S2≤½.

22. The display panel according to claim 1, wherein a center of the first virtual quadrangle does not coincide with a center of the one third sub-pixel located inside the first virtual quadrangle.

23. The display panel according to claim 22, wherein among two first sub-pixels corresponding to a same first virtual quadrangle or two second sub-pixels corresponding to a same first virtual quadrangle, one of the two first sub-pixels or one of the two second sub-pixels comprises a first protrusion portion and a first main portion, and the first protrusion portion is located on one side of the first main portion close to an intersection point of two diagonals in the first virtual quadrangle; and
a center of one of the plurality of third sub-pixels is located on one side of the intersection point of the two diagonals in the first virtual quadrangle and close to the first protrusion portion.

24. The display panel according to claim 1, wherein a center of the second virtual quadrangle does not coincide with a center of the one of the plurality of first sub-pixels located inside the second virtual quadrangle; or
the center of the second virtual quadrangle does not coincide with a center of the one of the plurality of second sub-pixels located inside the second virtual quadrangle.

25. The display panel according to claim 1, wherein the plurality of first sub-pixels and the plurality of second sub-pixels are arranged alternately in a third direction and a fourth direction, the plurality of first sub-pixels and the plurality of third sub-pixels are arranged alternately in the first direction and the second direction, the plurality of second sub-pixels and the plurality of third sub-pixels are arranged alternately in the first direction and the second direction, the third direction intersects the fourth direction, the third direction intersects the first direction and the second direction, and the fourth direction intersects the first direction and the second direction;
the first sub-pixel comprises the protrusion portion, the main portion comprises a first edge and a second edge, the first edge and the second edge extend in the first direction and are arranged in the second direction, the protrusion portion comprises a third edge, the third edge is connected to a same side of the first edge and the second edge, the first sub-pixel further comprises a fourth edge opposite to the third edge, and the fourth edge is connected to a same side of the first edge and the second edge;
the display panel comprises first sub-pixel groups; one of the first sub-pixel groups comprises a first first sub-pixel, a second first sub-pixel, a third first sub-pixel, and a fourth first sub-pixel; the first first sub-pixel and the second first sub-pixel are adjacent to each other and arranged in the third direction; the third first sub-pixel and the fourth first sub-pixel are adjacent to each other and arranged in the third direction; the first first sub-pixel and the third first sub-pixel are adjacent to each other and arranged in the first direction; the first first sub-pixel and the fourth first sub-pixel are adjacent to each other and arranged in the second direction; and the second first sub-pixel and the fourth first sub-pixel are adjacent to each other and arranged in the first direction; and
in a same first sub-pixel group, third edges and fourth edges of two first sub-pixels are arranged in the first direction, and protrusion directions of protrusion portions of the two first sub-pixels whose third edges and fourth edges are arranged in the first direction are opposite to each other; and third edges and fourths edge of two first sub-pixels are arranged in the second direction, and protrusion directions of protrusion portions of the two first sub-pixels whose third edges and fourth edges are arranged in the second direction are opposite to each other.

26. The display panel according to claim 25, wherein a third edge of the first first sub-pixel, a fourth edge of the first first sub-pixel, a third edge of the second first sub-pixel, and a fourth edge of the second first sub-pixel are arranged in the first direction; and a protrusion direction of a protrusion portion of the first first sub-pixel is opposite to a protrusion direction of a protrusion portion of the second first sub-pixel; and
a third edge of the third first sub-pixel, a fourth edge of the third first sub-pixel, a third edge of the fourth first sub-pixel, and a fourth edge of the fourth first sub-pixel are arranged in the second direction; and a protrusion direction of a protrusion portion of the third first sub-pixel is opposite to a protrusion direction of a protrusion portion of the fourth first sub-pixel.

27. The display panel according to claim 26, wherein in two first sub-pixel groups among the first sub-pixel groups and adjacent to each other in the fourth direction, protrusion directions of protrusion portions of two first sub-pixels adjacent to each other in the fourth direction are opposite to each other.

28. The display panel according to claim 25, wherein a third edge of the first first sub-pixel, a fourth edge of the first first sub-pixel, a third edge of the fourth first sub-pixel, and a fourth edge of the fourth first sub-pixel are arranged in the first direction; and a protrusion direction of a protrusion portion of the first first sub-pixel is opposite to a protrusion direction of a protrusion portion of the fourth first sub-pixel; and
a third edge of the second first sub-pixel, a fourth edge of the second first sub-pixel, a third edge of the third first sub-pixel, and a fourth edge of the third first sub-pixel are arranged in the second direction; and a protrusion direction of a protrusion portion of the second first sub-pixel is opposite to a protrusion direction of a protrusion portion of the third first sub-pixel.

29. The display panel according to claim 1, wherein the plurality of first sub-pixels and the plurality of second sub-pixels are arranged alternately in a third direction and a fourth direction, the third direction intersects the fourth direction, the third direction intersects the first direction and the second direction, the fourth direction intersects the first direction and the second direction, the plurality of first sub-pixels and the plurality of third sub-pixels are arranged alternately in the first direction and the second direction, and the plurality of second sub-pixels and the plurality of third sub-pixels are arranged alternately in the first direction and the second direction;
the first sub-pixel comprises the protrusion portion, the main portion comprises a first edge and a second edge, the first edge and the second edge extend in the first direction and are arranged in the second direction, the protrusion portion comprises a third edge, the third edge is connected to a same side of the first edge and the second edge, the first sub-pixel further comprises a fourth edge opposite to the third edge, and the fourth edge is connected to a same side of the first edge and the second edge;
the display panel comprises second sub-pixel groups, and one of the second sub-pixel groups comprises four first sub-pixel rows arranged in the fourth direction;
among the four first sub-pixel rows, third edges and fourth edges in two first sub-pixel rows are arranged in the first direction, and protrusion directions of protrusion portions in the two first sub-pixel rows in which the third edges and the fourth edges are arranged in the first direction are opposite to each other; and third edges and fourth edges in two first sub-pixel rows are arranged in the second direction, and protrusion directions of protrusion portions in the two first sub-pixel rows in which the third edges and the fourth edges are arranged in the second direction are opposite to each other; and
in a same first sub-pixel row, protrusion directions of protrusion portions of any two first sub-pixels are same.

30. The display panel according to claim 1, wherein the plurality of first sub-pixels and the plurality of second sub-pixels are arranged alternately in a third direction and a fourth direction, the third direction intersects the fourth direction, the third direction intersects the first direction and the second direction, the fourth direction intersects the first direction and the second direction, the plurality of first sub-pixels and the plurality of third sub-pixels are arranged alternately in the first direction and the second direction, and the plurality of second sub-pixels and the plurality of third sub-pixels are arranged alternately in the first direction and the second direction;
the second sub-pixel comprises the protrusion portion, the main portion comprises a first edge and a second edge, the first edge and the second edge extend in the first direction and are arranged in the second direction, the protrusion portion comprises a third edge, the third edge is connected to a same side of the first edge and the second edge, the second sub-pixel further comprises a fourth edge opposite to the third edge, and the fourth edge is connected to a same side of the first edge and the second edge;
the display panel comprises third sub-pixel groups; one of the third sub-pixel groups comprises a first second sub-pixel, a second second sub-pixel, a third second sub-pixel, and a fourth second sub-pixel; the first second sub-pixel and the second second sub-pixel are adjacent to each other and arranged in the third direction; the third second sub-pixel and the fourth second sub-pixel are adjacent to each other in the third direction; the first second sub-pixel and the third second sub-pixel are adjacent to each other and arranged in the first direction; the first second sub-pixel and the fourth second sub-pixel are adjacent to each other and arranged in the second direction; and the second second sub-pixel and the fourth second sub-pixel are adjacent to each other and arranged in the first direction; and
in a same third sub-pixel group among the third sub-pixels, third edges and fourth edges of two second sub-pixels are arranged in the first direction, and protrusion directions of protrusion portions of the two second sub-pixels whose third edges and fourth edges are arranged in the first direction are opposite to each other; and third edges and fourths edge of two second sub-pixels are arranged in the second direction, and protrusion directions of protrusion portions of the two second sub-pixels whose third edges and fourth edges are arranged in the second direction are opposite to each other.

31. The display panel according to claim 30, wherein a third edge of the first second sub-pixel, a fourth edge of the first second sub-pixel, a third edge of the second second sub-pixel, and a fourth edge of the second second sub-pixel are arranged in the first direction; and a protrusion direction of a protrusion portion of the first second sub-pixel is opposite to a protrusion direction of a protrusion portion of the second second sub-pixel; and
a third edge of the third second sub-pixel, a fourth edge of the third second sub-pixel, a third edge of the fourth second sub-pixel, and a fourth edge of the fourth second sub-pixel are arranged in the second direction; and a protrusion direction of a protrusion portion of the third second sub-pixel is opposite to a protrusion direction of a protrusion portion of the fourth second sub-pixel.

32. The display panel according to claim 31, wherein in two third sub-pixel groups among the third sub-pixel groups and adjacent to each other in the fourth direction, protrusion directions of protrusion portions of two third sub-pixels adjacent to each other in the fourth direction are opposite to each other.

33. The display panel according to claim 30, wherein a third edge of the first second sub-pixel, a fourth edge of the first second sub-pixel, a third edge of the fourth second sub-pixel, and a fourth edge of the fourth second sub-pixel are arranged in the first direction; and a protrusion direction of a protrusion portion of the first second sub-pixel is opposite to a protrusion direction of a protrusion portion of the fourth second sub-pixel; and
a third edge of the second second sub-pixel, a fourth edge of the second second sub-pixel, a third edge of the third second sub-pixel, and a fourth edge of the third second sub-pixel are arranged in the fourth direction; and a protrusion direction of a protrusion portion of the second second sub-pixel is opposite to a protrusion direction of a protrusion portion of the third second sub-pixel.

34. The display panel according to claim 1, wherein the plurality of first sub-pixels and the plurality of second sub-pixels are arranged alternately in a third direction and a fourth direction, the third direction intersects the fourth direction, the third direction intersects the first direction and the second direction, the fourth direction intersects the first direction and the second direction, the plurality of first sub-pixels and the plurality of third sub-pixels are arranged alternately in the first direction and the second direction, and the plurality of second sub-pixels and the plurality of third sub-pixels are arranged alternately in the first direction and the second direction;
the second sub-pixel comprises the protrusion portion, the main portion comprises a first edge and a second edge, the first edge and the second edge extend in the first direction and are arranged in the second direction, the protrusion portion comprises a third edge, the third edge is connected to a same side of the first edge and the second edge, the second sub-pixel further comprises a fourth edge opposite to the third edge, and the fourth edge is connected to a same side of the first edge and the second edge;
the display panel comprises four sub-pixel groups, and one of the four sub-pixel groups comprises four second sub-pixel rows arranged in the fourth direction;
among the four second sub-pixel rows, third edges and fourth edges in two second sub-pixel rows are arranged in the first direction, and protrusion directions of protrusion portions in the two second sub-pixel rows in which the third edges and the fourth edges are arranged in the first direction are opposite to each other; and third edges and fourth edges in two second sub-pixel rows are arranged in the second direction, and protrusion directions of protrusion portions in the two second sub-pixel rows in which the third edges and the fourth edges are arranged in the second direction are opposite to each other; and
in a same second sub-pixel row, protrusion directions of protrusion portions of any two second sub-pixels are same.

35. The display panel according to claim 1, wherein the plurality of first sub-pixels and the plurality of second sub-pixels are arranged alternately in a third direction and a fourth direction, the third direction intersects the fourth direction, the third direction intersects the first direction and the second direction, and the fourth direction intersects the first direction and the second direction; and
a line segment connecting a center of a first sub-pixel among the plurality of first sub-pixels and a center of a second sub-pixel the plurality of second sub-pixels passes through the protrusion portion, wherein the first sub-pixel and the second sub-pixel are adjacent to each other and arranged in at least one of the third direction or the fourth direction.

36. The display panel according to claim 35, wherein the display panel comprises a fifth first sub-pixel, a fifth second sub-pixel, and a sixth second sub-pixel; and the fifth second sub-pixel, the fifth first sub-pixel, and the sixth second sub-pixel are arranged in sequence in the third direction or the fourth direction; and
the fifth first sub-pixel comprises the protrusion portion, the protrusion portion protrudes towards one side of the fifth second sub-pixel, and a minimum distance between the fifth first sub-pixel and the fifth second sub-pixel is greater than a minimum distance between the fifth first sub-pixel and the sixth second sub-pixel.

37. The display panel according to claim 36, wherein the minimum distance between the fifth first sub-pixel and the fifth second sub-pixel is L1, and the minimum distance between the fifth first sub-pixel and the sixth second sub-pixel is L2, wherein 0.5 μm≤L1-L2≤6 μm.

38. The display panel according to claim 36, wherein the main portion comprises a first edge, a second edge, and a fourth edge; the first edge and the second edge extend in the first direction and are arranged in the second direction; the protrusion portion comprises a third edge; the third edge is connected to a same side of the first edge and the second edge;
and the fourth edge is connected to a same side of the first edge and the second edge;
a minimum distance connection line between the fifth first sub-pixel and the fifth second sub-pixel intersects the third edge at a third intersection point; and
the third edge comprises a protrusion high point, a distance between the protrusion high point and the fourth edge is greater than a distance between the third intersection point and the fourth edge, and the third intersection point is located on one side of the protrusion high point close to the first edge or the second edge.

39. The display panel according to claim 38, further comprising a first virtual line, wherein the first virtual line passes through the third intersection point and is parallel to the first edge; and
a smaller value of a distance between the first virtual line and the first edge and a distance between the first virtual line and the second edge is L3, and a larger value of the distance between the first virtual line and the first edge and the distance between the first virtual line and the second edge is L4, wherein 3%≤L3/L4≤30%.

40. The display panel according to claim 1, wherein the plurality of first sub-pixels and the plurality of second sub-pixels are arranged alternately in a third direction and a fourth direction, the third direction intersects the fourth direction, the third direction intersects the first direction and the second direction, and the fourth direction intersects the first direction and the second direction;
the display panel comprises a fifth first sub-pixel, a fifth second sub-pixel, and a sixth second sub-pixel; and the fifth second sub-pixel, the fifth first sub-pixel, and the sixth second sub-pixel are arranged in sequence in the third direction or the fourth direction;
the fifth first sub-pixel comprises the protrusion portion;
the display panel further comprises a second virtual line and a third virtual line, the second virtual line connects a center of the fifth second sub-pixel and a center of the sixth second sub-pixel, and the third virtual line passes through a center of the fifth first sub-pixel and is parallel to the second virtual line; and
an interval exists between the second virtual line and the third virtual line.

41. The display panel according to claim 1, wherein the first sub-pixel comprises the protrusion portion;
a third sub-pixel among the plurality of third sub-pixels comprises a fifth edge, and the fifth edge is located on one side of other edges of the third sub-pixel close to the protrusion portion; and
a minimum distance between the protrusion portion and the third sub-pixel is equal to a distance between the protrusion portion and the fifth edge.

42. The display panel according to claim 1, wherein the main portion comprises a first edge, a second edge, and a fourth edge; the first edge and the second edge extend in the first direction and are arranged in the second direction; the protrusion portion comprises a third edge; the third edge is connected to a same side of the first edge and the second edge;
and the fourth edge is connected to a same side of the first edge and the second edge;
the display panel comprises a sixth first sub-pixel, a seventh first sub-pixel, and a first third sub-pixel; and the sixth first sub-pixel, the first third sub-pixel, and the seventh first sub-pixel are arranged in sequence in the first direction or the second direction;
the first sub-pixel comprises the protrusion portion, a third edge of the sixth first sub-pixel and a fourth edge of the sixth first sub-pixel are arranged in the first direction, and a third edge of the seventh first sub-pixel and a fourth edge of the seventh first sub-pixel are arranged in the second direction;
the display panel further comprises a fourth virtual line and a fifth virtual line, the fourth virtual line connects a center of the sixth first sub-pixel and a center of the first third sub-pixel, and the fifth virtual line passes through a center of the seventh first sub-pixel and is parallel to the fourth virtual line; and
an interval exists between the fourth virtual line and the fifth virtual line.

43. The display panel according to claim 1, wherein the main portion comprises a first edge, a second edge, and a fourth edge; the first edge and the second edge extend in the first direction and are arranged in the second direction; the protrusion portion comprises a third edge; the third edge is connected to a same side of the first edge and the second edge;
and the fourth edge is connected to a same side of the first edge and the second edge;
the plurality of first sub-pixels comprise an eighth first sub-pixel and a ninth first sub-pixel, and the eighth first sub-pixel and the ninth first sub-pixel are arranged in the first direction or the second direction;
the first sub-pixel comprises the protrusion portion, a third edge of the eighth first sub-pixel and a fourth edge of the eighth first sub-pixel are arranged in the first direction, and a third edge of the ninth first sub-pixel and a fourth edge of the ninth first sub-pixel are arranged in the second direction;
the display panel further comprises a sixth virtual line and a seventh virtual line, a center of the eighth first sub-pixel is located on the sixth virtual line, a center of the ninth first sub-pixel is located on the seventh virtual line, the sixth virtual line is a central axis of the fourth edge of the eighth first sub-pixel, and the seventh virtual line is a central axis of the fourth edge of the ninth first sub-pixel; and
the sixth virtual line is orthogonal to the seventh virtual line.

44. The display panel according to claim 1, further comprising a plurality of support columns, wherein
a support column among the plurality of support columns overlaps at least one virtual edge of the first virtual quadrangle in a thickness direction of the display panel; and
the main portion comprises a first edge and a second edge, the first edge and the second edge extend in the first direction and are arranged in the second direction, the protrusion portion comprises a third edge, the third edge is connected to a same side of the first edge and the second edge, and one of the at least one virtual edge intersects the third edge of the first sub-pixel or the third edge of the second sub-pixel.

45. The display panel according to claim 44, wherein the first sub-pixel comprises the protrusion portion, and a minimum distance between the support column and the first sub-pixel is greater than a minimum distance between the support column and the second sub-pixel.

46. The display panel according to claim 45, wherein the first sub-pixel comprises the protrusion portion, and a minimum distance between the support column and the first sub-pixel is equal to a minimum distance between the support column and the second sub-pixel.

47. The display panel according to claim 1, further comprising a substrate, a pixel defining layer located on one side of the substrate, and a plurality of light-emitting elements, wherein
the pixel defining layer comprises a plurality of pixel openings; and one of the plurality of light-emitting elements comprises a first electrode, a second electrode, and a light emission layer located between the first electrode and the second electrode;
the plurality of light-emitting elements comprise the plurality of first sub-pixels, the plurality of second sub-pixels, and the plurality of third sub-pixels; and
in the first sub-pixel comprising the protrusion portion or second sub-pixel comprising the protrusion portion, a shape of a light emission layer is different from a shape of one of the plurality of pixel openings.

48. The display panel according to claim 1, further comprising a substrate, a pixel defining layer located on one side of the substrate, and a plurality of light-emitting elements, wherein
the pixel defining layer comprises a plurality of pixel openings; and one of the plurality of light-emitting elements comprises a first electrode, a second electrode, and a light emission layer located between the first electrode and the second electrode;
the plurality of light-emitting elements comprise the plurality of first sub-pixels, the plurality of second sub-pixels, and the plurality of third sub-pixels; and
in the first sub-pixel comprising the protrusion portion or second sub-pixel comprising the protrusion portion, a shape of a light emission layer is approximately same as a shape of one of the plurality of pixel openings.

49. The display panel according to claim 1, further comprising a substrate, a pixel defining layer located on one side of the substrate, and a plurality of light-emitting elements, wherein
the pixel defining layer comprises pixel openings and bank portions, and one of the plurality of light-emitting elements is disposed at one of the pixel openings; and
one of the bank portions comprises a side surface and a bottom surface on one side facing the substrate, and an included angle formed between the side surface and the bottom surface is an acute angle, wherein
the included angle differs according to positions.

50. The display panel according to claim 49, wherein the main portion comprises a first edge and a second edge, the first edge and the second edge extend in the first direction and are arranged in the second direction, the protrusion portion comprises a third edge, and the third edge is connected to a same side of the first edge and the second edge;
the included angle comprises a first included angle between the first edge and the bottom surface and a second included angle between the third edge and the bottom surface; and
the first included angle θ1 and the second included angle θ2 satisfy that θ2≥θ1.

51. The display panel according to claim 1, further comprising a display region, wherein the display region comprises a plurality of data lines arranged in a third direction and extending in a fourth direction, the third direction intersects the fourth direction, the third direction intersects the first direction and the second direction, and the fourth direction intersects the first direction and the second direction;
the display region further comprises a substrate and a plurality of light-emitting elements located on one side of the substrate, and one of the plurality of light-emitting elements comprises a first electrode; and
a first electrode of the first sub-pixel and a first electrode of the second sub-pixel each overlap two of the plurality of data lines in a direction perpendicular to a plane where the substrate is located.

52. The display panel according to claim 51, further comprising a non-display region, the non-display region comprises a fan-out region located on one side of the display region in the fourth direction, the display region comprises a first display region and a second display region, and the second display region is located on at least one side of the first display region in the third direction;
the fan-out region comprises a plurality of fan-out wires, and the first display region and the second display region each comprise multiple data lines among the plurality of data lines;
the plurality of data lines are connected to the plurality of fan-out wires, wherein the multiple data lines in the second display region are connected to the plurality of fan-out wires through connection wires;
a connection wire of the connection wires is located in the display region and comprises a first connection line segment extending in the fourth direction and a second connection line segment extending in the third direction; and
the first electrode of the first sub-pixel and the first electrode of the second sub-pixel each overlap two first connection line segments in the direction perpendicular to a plane where the substrate is located.

53. The display panel according to claim 3, wherein an interior angle in the first sub-pixel or the second sub-pixel and not connected to the third edge comprises a right angle or an arc angle; and
an arc radius corresponding to the arc angle is less than a radius of a virtual circle.

54. A display device, comprising a display panel, wherein the display panel comprises a plurality of first sub-pixels, a plurality of second sub-pixels, and a plurality of third sub-pixels, wherein
multiple first sub-pixels among the plurality of first sub-pixels and multiple second sub-pixels among the plurality of second sub-pixels constitute a first virtual quadrangle, a center of one of the multiple first sub-pixels is located at a first vertex of the first virtual quadrangle, a center of one of the multiple second sub-pixels is located at a second vertex of the first virtual quadrangle, the first vertex and the second vertex alternate and are spaced apart, and one third sub-pixel among the plurality of third sub-pixels is located inside the first virtual quadrangle; and
multiple third sub-pixels among the plurality of third sub-pixels constitute a second virtual quadrangle, centers of the multiple third sub-pixels are each located at a vertex of the second virtual quadrangle, and one of the plurality of first sub-pixels or one of the plurality of second sub-pixels is located inside the second virtual quadrangle; wherein a first sub-pixel among the plurality of first sub-pixels or a second sub-pixel among the plurality of second sub-pixels comprises a main portion and a protrusion portion, and the protrusion portion is located on one side of the main portion in a first direction; and a length of the protrusion portion is X1 in the first direction, and a length of the main portion and a length of the protrusion portion are each X2 in a second direction, wherein 0<X1<X2/2, and the second direction intersects the first direction.
